(19) United States
(12) Patent Application Publication
(10) Pub. No.: US 2007/0007621 A1
(43) Pub. Date: Jan. 11, 2007

(54) Fuse breakdown method adapted to semiconductor device

(75) Inventors: Masayoshi Omura, Hamamatsu-shi (JP); Yasuhiko Sekimoto, Hamamatsu-shi (JP)

Correspondence Address: DICKSTEIN SHAPIRO LLP, 1177 AVENUE OF THE AMERICAS (6TH AVENUE), NEW YORK, NY, 10036-2714, US

(73) Assignee: YAMAHA CORPORATION, Hamamatsu-shi (JP)

(21) Appl. No.: 11/390,413

(22) Filed: Mar. 28, 2006

(30) Foreign Application Priority Data
Mar. 30, 2005 (JP) P2005-099404
Mar. 31, 2005 (JP) P2005-101481
Mar. 31, 2005 (JP) P2005-103642

(51) Int. Cl. H01L 29/00; H01L 21/82

(52) U.S. Cl. 257/529; 438/132

(57) ABSTRACT

A plurality of pulses each having relatively low energy are consecutively applied to a subject fuse to cause breakdown, wherein the total energy of pulses is set in light of a prescribed breakdown threshold, which is calculated in advance. The subject fuse has a pair of terminals and an interconnection portion that is narrowly constricted in the middle so as to realize fuse breakdown with ease. A pulse generator generates pulses, which are repeatedly applied to the subject fuse by way of a transistor; then, it stops generating pulses upon detection of fuse breakdown. Side wall spacers are formed on side walls of fuses, which are processed in a tapered shape so as to reduce thermal stress applied to coating insulating films. In addition, pulse energy is appropriately determined so as to cause electro-migration in the subject fuse, which is thus increased in resistance without causing instantaneous meltdown or evaporation.

### BACKGROUND OF THE INVENTION

1. Field of the Invention

This invention relates to fuse breakdown methods using electric pulses applied to fuses incorporated in semiconductor devices.

The present application claims priority on Japanese Patent Application Nos. 2005-99404, 2005-101481, and 2005-103642, the contents of which are incorporated herein by reference.

2. Description of the Related Art

Relatively high power, which is higher than the operational power normally applied to electronic circuits, is needed to cause breakdown of fuses formed on semiconductor substrates. For example, MOSFETs are connected in series to fuses so as to cause high currents, causing meltdown and breakdown of fuses, wherein they must have large gate widths, which are several tens of times to several hundreds of times larger than conventional gate widths adapted to MOSFETs generally used for digital processing. However, MOSFETs having large gate widths increase the overall sizes thereof; and this is contradictory to high integration of circuitry.

Japanese Unexamined Patent Application Publication No. H10-189741 teaches the circuitry for meltdown and breakdown of fuses by use of collector currents of parasitic bipolar transistors formed on semiconductor substrates. Japanese Unexamined Patent Application Publication No. S63-299139 teaches the circuitry for meltdown and breakdown of fuses based on avalanche breakdown. Japanese Unexamined Patent Application Publication No. S59-105354 teaches the circuitry for meltdown and breakdown of fuses based on the latch-up phenomenon of parasitic thyristors.

Japanese Unexamined Patent Application Publication No. H11-203888 teaches the circuitry for meltdown and breakdown of fuses by use of laser beams, wherein due to deviations of incident positions of laser beams, fuses may not completely break down, causing minor currents to flow through fuses. Hence, after the irradiation with laser beams, an inspection is performed as to whether or not breakdown is completed; then, electric pulses are applied again to fuses that show incomplete breakdown, thus avoiding breakdown failure.

In order to produce high power causing breakdown of fuses used in semiconductor devices, it is necessary to produce high power causing high current based on operations of bipolar transistors having high current drive capacities, operations of parasitic bipolar circuits of CMOS circuits, and irreversible and destructive operations such as snapbacks of MOS transistors (e.g., electron avalanche breakdown). Japanese Patent Application Publication Nos. 2002-158289, H06-37254, and H07-307389 teach methods of meltdown and breakdown of fuses used in semiconductor devices.

In the aforementioned methods, electric energy is applied to each fuse to cause breakdown at once; however, it is difficult to stop applying electric energy instantaneously when each fuse breaks down. For this reason, a relatively long time is needed to apply electric energy to fuses.

Breakdown does not always occur in fuses in a stable manner irrespective of the aforementioned methods; hence, fuse breakdown methods using energy beams such as laser beams have recently formed the mainstream technology for breakdown of fuses used in redundant circuits incorporated in memories such as DRAMs. This is taught in Japanese Unexamined Patent Application Publication No. H11-203888, for example.

In the aforementioned method in which fuses break down with energy beams, it is necessary for fuses to completely break down with one-time irradiation of high electric energy. This allows fuses to break down when fuse materials are melted, scattered, and evaporated. However, another problem occurs in that melted substances are scattered in the surrounding areas of fuses and re-adhered to other electronic components of semiconductor devices.

Although fuses can break down with high current or high energy beam, when high electric current or high energy beam is applied to fuses, destruction may occur on both fuses and other components included in semiconductor circuits.

In addition, it is difficult to adequately control the electric energy applied to fuses irrespective of operations of parasitic bipolar circuits of CMOS circuits and irreversible or destructive operations such as snapbacks of MOS transistors. It may be possible to apply very high electric current beyond a prescribed amount of electric current causing breakdown of fuses. This in turn causes high energy scattering and makes peripheral circuits surrounding fuses become inoperable or destructive.

Although fuses break down with very high energy beams, fuse materials are physically altered because they are instantaneously melted or evaporated; and it is difficult to control such explosive variations of fuse materials. In other words, even when fuses break down with electric current and energy beam, fuse materials are melted, evaporated, and scattered due to rapid heating caused by energy applied thereto. This results in unwanted destruction of conduction circuits connected with fuses and insulating films surrounding fuses.

Other problems regarding electric circuitry such as short-circuiting of wiring occur when melted and scattered substances of fuse materials are adhered to peripheral circuits surrounding fuses. In particular, interlayer insulating films, passivation films, and protective resin films covering fuses may be easily destructed and scattered; cracks may be easily formed in semiconductor devices; and semiconductor devices may be easily deformed by being melted. This reduces the yield of manufacturing of semiconductor devices; hence, semiconductor devices are degraded in terms of reliability.

For this reason, it may be necessary to perform an additional manufacturing process in which interlayer insulating films, passivation films, and protective resin films covering fuses are removed in advance so as to expose fuses for the purpose of breakdown; thereafter, the films are formed again to cover fuses after breakdown in order to improve reliability.

When fuses melt down and break down with low energy emission so as not to cause physical destruction, thermal stresses are accumulated in insulating films, wiring, and peripheral circuits surrounding fuses due to rapid temperature increase and decrease caused by transmission and scattering of thermal energy. This results in variations of wiring resistance and affects reliability of the circuitry.

Fuses break down with electric energy produced using generally-known transistors, which are easy to control; however, large-size transistors are necessary to produce high current; and this increases the overall chip size and manufacturing cost. The relationship between resistance, current, and voltage with regard to breakdown of fuses can be assessed as follows:

A fuse current Ifuse realizing the fuse breakdown is defined using a fuse resistance Rfuse, a driving ability of a transistor (i.e., an internal resistance of a transistor, in other words, an ON-resistance Ron of a transistor having an opened channel), and drive voltage (or power voltage) Vdd in accordance with the following equation (1).

$$Ifuse = \frac{Vdd}{Rfuse + Ron} \qquad ( 1 )$$

In the aforementioned equation (1), the ON-resistance Ron depends on the driving ability of a transistor, wherein Ron decreases as the driving ability increases. The drive voltage Vdd increases so as to increase the fuse current Ifuse. However, the drive voltage Vdd is determined in advance in the semiconductor circuit designing stage, and the power consumption of LSI circuits generally tends to increase when the drive voltage Vdd becomes high; therefore, it is difficult to increase the drive voltage Vdd for the purpose of causing breakdown of fuses.

Because of the aforementioned reasons, it may be necessary to decrease the resistances Rfuse and Ron. The ON-resistance Ron is determined in advance in the transistor designing stage in response to a gate length Lg and a gate width Wg. In order to reduce the ON-resistance Ron, it is necessary to reduce the gate length Lg, which is determined by the prescribed rules regarding the design and manufacturing of LSI circuits, so that the minimum value of the gate length Lg is fixed in advance. This makes it necessary to increase the gate width Wg in order to reduce the ON-resistance Ron.

The fuse resistance Rfuse is defined using a sheet resistance pf, which depends upon fuse material and thickness, as well as a fuse width Wf and a fuse length Lf, both of which are determined in the design stage, in accordance with the following equation (2).

$$Rfuse = pf * \frac{Lf}{Wf} \qquad ( 2 )$$

The sheet resistance pf is determined upon the selection of the conductive material and thickness in the LSI manufacturing process and is therefore limited because polysilicon or polycide used for other layers is also applied to the formation of fuses. In order to allow fuses to break down with ease, the fuse width Wf is set to the minimum value defined by the prescribed design rules in the LSI design stage. This makes it possible for the fuse resistance Rfuse to vary in response to the fuse length Lf, wherein Rfuse becomes low as Lf becomes small.

The aforementioned relationship is represented by the following equation (3).
Ifuse=A*F(1/Lf,Wg) (3)

where “A” is a constant determined in the design and process.

In general, when fuses break down with electric current produced using transistors, the width Wg should be several tens of times to several hundreds of times larger than the width of the MOS transistors conventionally used for digital signal processing. That is, numerous transistors of large sizes are necessary for fuses to break down. This increases the overall sizes of the semiconductor chips and therefore pushes up the manufacturing cost. In addition, it may be impractical to use transistors of large sizes for redundant circuits of highly integrated semiconductor memory chips.

The fuse length Lf is limited by breakdown characteristics of fuses and therefore cannot be reduced so much. It is necessary for fuses to have a prescribed resistance R′fuse (i.e., in actuality, resistance of melted portions of fuses; R′fuse is substantially equal to or smaller than Rfuse) because fuses are melted due to the accumulation of Joule heat caused by the fuse current Ifuse. Heating value J′fuse is represented as follows:
J′fuse=(Ifus*R′fuse*T) (4)

where T indicates time counted between the timing of an electric current flowing through a fuse and the timing of the fuse to break down.

Therefore, as R′fuse decreases, Ifuse increases correspondingly; however, it is possible to reduce the total heating value J′fuse causing fuse breakdown. Due to such a reciprocal relationship, R′fuse (or Rfuse) is limited and cannot be reduced arbitrarily.

Due to the intervention of interlay insulating films formed on fuses, it is difficult to make fuses break down because interlayer insulating films absorb energy beams. For this reason, interlay insulating layers, passivation films, and protection resin films are removed from prescribed areas of fuses and their surrounding areas. However, this requires complex processes because semiconductor devices are temporarily extracted from manufacturing lines and are subjected to testing regarding circuit operations of memories and breakdown operations of fuses using energy beams and are then returned to manufacturing lines in which they are subjected to patterning and formation of upper layers. This pushes up the manufacturing cost due to the complexity of manufacturing processes. In addition, due to fine processing of semiconductor circuits, fuses are downsized correspondingly; and this makes it difficult to perform precise positioning with respect to energy beams relative to fuses. This increases time losses in adjusting precise positioning therebetween.

Recent technologies regarding fine processing of semiconductor elements and sophisticated design rules allow energy beams to become very small with respect to irradiation of fuses. In addition, various developments have been achieved with respect to optimization of sizes and shapes of fuses, optimization of fuse resistances suiting drive capacities of transistors, whereby pulse-like currents are appropriately produced within prescribed controllable ranges realized by transistors and are used to heat fuses over very short periods of time, thus making fuses break down. This may avoid the occurrence of physical destruction of interlayer insulating films, passivation films, and protection resin films during breakdown processing of fuses.

However, when a relatively large number of insulating films are applied onto fuses causing transmission of heat, caused by breakdown processing of fuses, therethrough, water-contained gas may be emitted in interlayer insulating films due to a degassing reaction caused by heat transmitted through insulating films; and this may degrade the reliability of LSI circuits. In addition, when thermal contraction occurs partially in such thick insulating films, interlayer insulating films may be slightly deformed, and cracks may occur in insulating films.

FIG. 1 of Japanese Unexamined Patent Application Publication No. H07-307389 shows the circuitry in which fuses and MOS transistors are connected in series and arranged in parallel, wherein a current drive ability for producing a breakdown current of a fuse is calculated in accordance with the following function.
I_{D}=μC_{OX}(W/L)×(½)×(V_{GS}−V_{T}) (5)
In the above, I_{D} denotes a drain current in a saturation region of a transistor; μ denotes carrier mobility; C_{OX} denotes a gate capacity of the transistor; W denotes a gate width; L denotes a gate length; V_{GS} denotes a gate-source voltage; and V_{T} denotes a threshold voltage.

When the saturated drain current I_{D} is known, it is possible to estimate the gate width of a transistor causing fuse breakdown in accordance with the aforementioned equation.

In order to produce very high electric energy causing fuse breakdown, it is necessary to greatly increase the dimensions (i.e., the gate width) of a transistor, which in turn increases the overall chip size. When applying very high electric energy, fuses may be instantaneously melted and evaporated so that breakdown occurs; at the same time, the peripheral areas of fuses may be affected. That is, conduction circuits connected to fuses and insulating films surrounding fuses are destroyed. In addition, melted substances are scattered causing short-circuit. Even when they are not destroyed, resistances may be varied due to thermal stress, thus degrading the reliability of semiconductor devices.

When trimming circuits and redundant circuits including fuses are formed in semiconductor integrated circuits, trimming can be performed in the middle of or after the manufacturing of semiconductor integrated circuits, thus realizing optimum characteristics.

A relatively small number of fuses used for circuit selection described above are used and are thus subjected to breakdown processing using energy beams. In order to make fuses completely break down with one-time irradiation of energy beams, very high energy is applied to fuses that are exposed in advance. Fuses completely break down when they are melted, scattered, and evaporated due to the application of very high energy; however, melted substances are scattered in surrounding areas of fuses and may be re-adhered to electronic circuits.

The breakdown method using energy beams is not realistic with respect to numerous fuses because it takes a long time to realize precise positioning of energy beams irradiated on fuses. After packaging, it is not possible to write information into fuses.

### SUMMARY OF THE INVENTION

It is an object of the invention to provide a method for breaking down a fuse with low electricity in a semiconductor device, wherein low-power electric pulses are applied to fuses several times so as to break down fuses.

In a first aspect of the present invention, there is provided a fuse breakdown method in which plural pulses are consecutively applied to a subject fuse, which is formed on a semiconductor substrate via an insulating layer, so as to cause breakdown, wherein the total energy applied to the subject fuse is set in light of a prescribed breakdown threshold, which is calculated in advance. The subject fuse is configured by a pair of terminals and an interconnection portion interconnecting the terminals. The interconnection portion is narrowly constricted with a triangular recess in the middle; it has at least one bent portion; or it has a spiral shape, for example.

Since energy per each pulse is reduced, it is possible to reduce a temperature increase due to electric energy causing fuse breakdown; hence, it is possible to remarkably reduce the influence applied to peripheral areas of fuses and insulating layers. This makes it possible to arrange plural fuses being partially overlapping in a vertical direction on the semiconductor substrate. Each fuse may have an interconnection portion that is narrowly constricted in the middle, enabling it to break down with ease. When the interconnection portion has at least one bent portion or a spiral shape, it is possible to increase the effective length of the fuse.

In a second aspect of the present invention, plural pulses each having relatively low energy are repeatedly applied to a fuse to break it down based on a migration phenomenon due to repeatedly applied thermal stress, whereby it is possible to reduce thermal damage applied to the periphery of the fuse. That is, although the heat caused by electric energy applied to the fuse is transmitted to the periphery, it may rapidly decrease in proportion to the temperature of the fuse and in inverse proportion to the cube of the transmission speed. By appropriately setting the number of pulses consecutively applied to the fuse, the fuse temperature may decrease in time intervals between pulses, thus reducing the amount of heat being transmitted to the periphery of the fuse.

In comparison to the conventional fuse breakdown method in which the fuse breaks down with a single pulse applied thereto, the fuse breakdown method of the present invention is advantageous in that the thermal stress (caused by heat transmission due to pulses) is reduced; hence, it is possible to cause the breakdown of the fuse whose peripheral circuits such as insulating films and wirings are not substantially affected by the thermal stress. This reduces variations of the wiring resistance and improves the reliability of the circuitry.

In addition, it is possible to introduce a breakdown detection circuit for detecting whether or not a fuse breaks down with multiple pulses, whereby it is possible to inhibit excessive pulses from being unnecessarily applied to the fuse, and it is therefore possible to reduce the overall processing time regarding the fuse breakdown program.

In a third aspect of the present invention, an insulating film is formed to cover side wall spacers of fuses so as to increase the distance with an upper layer coated thereon (i.e., a coating insulating film), wherein the coating insulating film formed in the periphery of fuses is removed so as to prevent high heat, which occurs when fuses break down, from being transmitted to the applied insulating film formed in other areas except fuses, thus suppressing degasification in the coating insulating film; hence, it is possible to prevent cracks from being formed in the coating insulating film and to prevent the coating insulating film from being unexpectedly deformed. This reliably improves the reliability of semiconductor devices in manufacturing.

Alternatively, an insulating film is formed to entirely cover fuses; then, side wall spacers are formed on the side walls of the fuses having reduced coverage in the insulating film. This increases the distance between the insulating film and an upper layer coated thereon (i.e., a coating insulating film), thus reducing thermal stress. In addition, an insulating film is further formed to entirely cover the fuses having the side wall spacers; then, side wall spacers are further formed on the side walls of the fuses having reduced coverage. This further increases the distance between the insulating film and the coating insulating film thereon, thus further reducing thermal stress.

Alternatively, an insulating film is formed to entirely cover fuses and is subjected to tapered processing by way of Ar etching, O₂ etching, or milling; hence, it is possible to increase the distance between the insulating film and the coating insulating film thereon, thus reducing thermal stress. It is possible to further form an insulating film covering the insulating film having tapered portions; hence, it is possible to further increase the distance between the insulating film and the coating insulating film thereon, thus further reducing thermal stress.

The heat of a fuse caused by electric energy applied thereto may be transmitted to the periphery of the fuse via the insulating film acting as a heat transmission medium, wherein the temperature of the transmitted heat rapidly decreases in proportion to the temperature of the fuse and in inverse proportion to the product between a volume regarding heat transmission (i.e., approximately, the cube of the distance) and specific heat. The coating insulating film is subjected to quenching heat treatment at a prescribed temperature of about 400° C. Hence, the quality of the coating insulating film may not be degraded due to relatively low heat of the fuse; hence, no cracking and no gasification may occur. For this reason, it is necessary that the coating insulating film be removed in advance from the periphery of the fuse subjected to transmission of high heat, or that it be distanced from the fuse, thus reducing heat transmitted to the coating insulating film.

It is possible to demonstrate the aforementioned advantage while securing planation of the surface of semiconductor integrated circuits by use of the coating insulating film by removing the coating insulating film from the fuse or by making the coating insulating film be distant from the fuse. Specifically, the coating insulating film formed above the fuse is subjected to etching back; side wall spacers are formed on the side walls of the applied insulating film; an insulating film, which may hardly expand or contract due to thermal stress, is applied; thus, it is possible to remarkably reduce thermal stress.

In a fourth aspect of the present invention, a pulse whose energy is lower than the breakdown energy but is sufficient to cause solid phase migration is repeatedly applied to a fuse, composed of a conductive material, which is thus increased in resistance due to accumulated thermal stress without causing instantaneous meltdown or evaporation of the fuse.

### BRIEF DESCRIPTION OF THE DRAWINGS

These and other objects, aspects, and embodiments of the present invention will be described in more detail with reference to the following drawings, in which:

FIG. 1 is a graph showing the relationships between numbers of pulses having different widths and breakdown ratios of fuses;

FIG. 2A is a graph showing waveforms regarding a pulse voltage and a potential causing fuse breakdown;

FIG. 2B is an equivalent circuit including a fuse and a breakdown circuit using a transistor;

FIG. 3 is a graph showing the relationships between effective times for fuse breakdown and breakdown ratios of fuses;

FIG. 4 is a flowchart showing a fuse breakdown method in accordance with a first embodiment of the present invention;

FIG. 5 is a graph showing the relationships between pulse currents and accumulated times for fuse breakdown;

FIG. 6 is a plan view showing a semiconductor device including a fuse and a MOS transistor;

FIG. 7 is a cross-sectional view taken along line A8-A8 in FIG. 6;

FIG. 8A is a cross-sectional view showing a first step for manufacturing a semiconductor device;

FIG. 8B is a cross-sectional view showing a second step for manufacturing the semiconductor device;

FIG. 8C is a cross-sectional view showing a third step for manufacturing the semiconductor device;

FIG. 8D is a cross-sectional view showing a fourth step for manufacturing the semiconductor device;

FIG. 8E is a cross-sectional view showing a fifth step for manufacturing the semiconductor device;

FIG. 9 is a cross-sectional view showing a variation of the semiconductor device shown in FIG. 7;

FIG. 10 is a cross-sectional view showing another variation of the semiconductor device shown in FIG. 7;

FIG. 11A is a plan view showing a first example of a fuse;

FIG. 11B is a plan view showing a second example of a fuse;

FIG. 11C is a plan view showing a third example of a fuse;

FIG. 11D is a plan view showing a fourth example of a fuse;

FIG. 11E is a plan view showing a fifth example of a fuse;

FIG. 11F is a plan view showing a sixth example of a fuse;

FIG. 11G is a plan view showing a seventh example of a fuse;

FIG. 12A is a plan view showing an eighth example of a fuse;

FIG. 12B is a plan view showing a ninth example of a fuse;

FIG. 12C is a plan view showing a tenth example of a fuse;

FIG. 12D is a plan view showing an eleventh example of a fuse;

FIG. 12E is a plan view showing a twelfth example of a fuse;

FIG. 13A is a plan view showing a thirteenth example of a fuse;

FIG. 13B is a plan view showing a fourteenth example of a fuse;

FIG. 13C is a plan view showing a fifteenth example of a fuse;

FIG. 14 is a graph showing the relationship between potential variations of a pulse and potential variations of a fuse

FIG. 15 is a graph showing experimental results regarding the relationships between breakdown ratios and breakdown times;

FIG. 16A is a flowchart showing a part of a fuse breakdown method in accordance with a second embodiment of the present invention;

FIG. 16B is a flowchart showing another part of the fuse breakdown method;

FIG. 17 is a graph showing the relationships between pulse currents and accumulated times for fuse breakdown;

FIG. 18 is a circuit diagram showing a first example of a fuse breakdown circuit;

FIG. 19 is a circuit diagram showing a second example of a fuse breakdown circuit;

FIG. 20 is a circuit diagram showing a third example of a fuse breakdown circuit;

FIG. 21 is a circuit diagram showing a fourth example of a fuse breakdown circuit;

FIG. 22 is a circuit diagram showing a fifth example of a fuse breakdown circuit;

FIG. 23 is a circuit diagram showing a sixth example of a fuse breakdown circuit;

FIG. 24 is a plan view diagrammatically showing the layout of elements of a semiconductor device realizing a CMOS integrated circuit;

FIG. 25A is a cross-sectional view taken along line A-A in FIG. 24 showing a first step of the manufacturing of the semiconductor device;

FIG. 25B is a cross-sectional view showing a second step of the manufacturing of the semiconductor device;

FIG. 25C is a cross-sectional view showing a third step of the manufacturing of the semiconductor device;

FIG. 25D is a cross-sectional view showing a fourth step of the manufacturing of the semiconductor device;

FIG. 25E is a cross-sectional view showing a fifth step of the manufacturing of the semiconductor device;

FIG. 25F is a cross-sectional view showing a sixth step of the manufacturing of the semiconductor device;

FIG. 26 is a cross-sectional view showing an example of the semiconductor device;

FIG. 27 is a cross-sectional view showing another example of the semiconductor device;

FIG. 28 is a plan view diagrammatically showing the layout of elements of a semiconductor device realizing a CMOS integrated circuit;

FIG. 29A is a cross-sectional view taken along line B-B in FIG. 28;

FIG. 29B is a cross-sectional view taken along line B-B in FIG. 28;

FIG. 30 is a cross-sectional view taken along line B-B in FIG. 28 showing a basic structure in which a fuse is formed in connection with a first insulating film, an SOG film, and a second insulating film;

FIG. 31 is a cross-sectional view taken along line B-B in FIG. 28 showing a first example of a fuse structure in which side wall spacers are formed on side walls of a fuse;

FIG. 32 is a cross-sectional view showing a second example of the fuse structure;

FIG. 33 is a cross-sectional view showing a third example of the fuse structure;

FIG. 34 is a cross-sectional view showing a fourth example of the fuse structure;

FIG. 35 is a cross-sectional view showing a fifth example of the fuse structure;

FIG. 36 is a cross-sectional view showing a sixth example of the fuse structure in which plural fuse arrays are formed using plural insulating films;

FIG. 37 is a circuit diagram showing a fuse breakdown circuit;

FIG. 38 is a plan view showing a semiconductor device including the fuse breakdown circuit of FIG. 37 in accordance with a fourth embodiment of the present invention;

FIG. 39 is a cross-sectional view taken along line C-C in FIG. 38;

FIG. 40 is a circuit diagram showing a memory circuit using fuses;

FIG. 41 is a truth table showing operation of a selector included in the memory circuit of FIG. 40.

FIG. 42 shows signal waveforms for explaining fuse breakdown operation; and

FIG. 43 shows signal waveforms for explaining determination of fuse breakdown/non-breakdown states.

### DESCRIPTION OF THE PREFERRED EMBODIMENTS

This invention will be described in further detail by way of examples with reference to the accompanying drawings.

### 1. First Embodiment

First, the basic principle regarding fuse breakdown will be described. A single pulse having high energy is necessary to cause fuse breakdown. Specifically, multiple pulses each having relatively low energy are repeatedly applied to fuses so as to cause thermal stress, by which fuses break down in accordance with the migration phenomenon of fuse materials.

Suppose that a breakdown threshold Eₜₕ is defined to represent energy per one pulse, which sufficiently causes fuse breakdown. It is required that when multiple pulses are used to cause fuse breakdown, their total energy Eₜₒₜₐₗ be higher than the breakdown threshold Eₜₕ. For example, when fuse breakdown occurs with a single pulse having energy of 5×10⁷ [J], it is necessary to apply two pulses each having energy of 2.5×10⁷ [J]. In order to cause fuse breakdown with n pulses (where n is an integer not less than “2”), each pulse has energy of 5×10⁷/n [J].

All the pulses do not necessarily have the same energy; hence, it is required that the total energy become higher than 5×10⁷ [J]. For example, when fuse breakdown occurs with two pulses, a first pulse has energy of 2×10⁷ [J], and a second pulse has energy of 3×10⁷ [J].

When fuse breakdown occurs with n pulses, each pulse has the same energy, which is reduced to 1/n of the breakdown threshold Eₜₕ. Thus, the scattering phenomenon may hardly occur due to fuse meltdown; hence, it is possible to reduce influences on insulating films and surrounding elements of fuses.

All of n pulses do not necessarily have the same energy, which is set to 1/n of the breakdown threshold Eₜₕ; hence, each pulse simply needs Eₜₕ/n or more. For example, when each pulse has 60% of the breakdown threshold Eₜₕ, fuse breakdown occurs with two pulses. When each pulse has 30% of the breakdown threshold Eₜₕ, fuse breakdown occurs with four pulses.

Energy of one pulse is the product of voltage, current, and a pulse width (or a time length); hence, when fuse breakdown occurs with multiple pulses, each pulse is reduced in voltage or current or is reduced in pulse width compared with a single pulse having the breakdown threshold Eₜₕ. Alternatively, each pulse is reduced in the current or voltage and in pulse width as well.

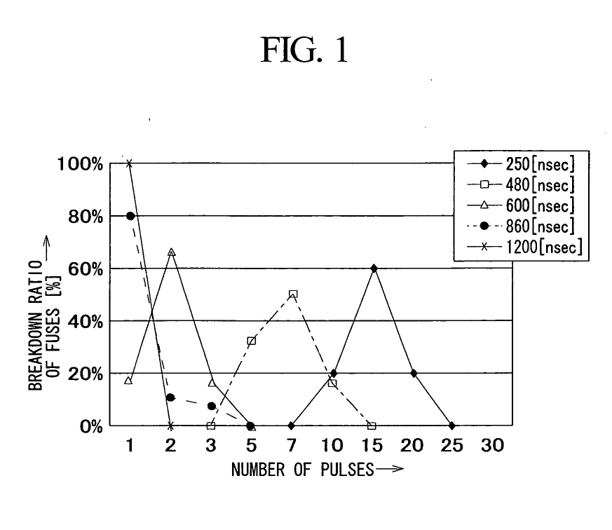

FIG. 1 shows the relationships between breakdown ratios of fuses and numbers of pulses having different time lengths (or pulse widths). Herein, energy per each pulse is changed by changing the pulse width thereof. In order to eliminate influence due to temperature increase upon application of a previous pulse, each pulse is applied to each fuse with a prescribed time interval, which allows each fuse to be completely cooled down and which ranges from several seconds to several tens of seconds.

In FIG. 1, the horizontal axis represents the number of pulses causing fuse breakdown, and the vertical axis represents the breakdown ratio of fuses that break down. In experiments, 5000 fuses are used, and each fuse has a two-layered structure composed of a polysilicon layer and a metal silicide layer, wherein each of pulses having different widths (i.e., 1200 ns, 860 ns, 600 ns, 480 ns, and 250 ns) is produced using the same voltage and current.

All the fuses each break down with a single pulse whose width is 1200 ns having energy E(1200). Of 5000 fuses, 4050 fuses each break down with a single pulse whose width is 860 ns having energy E(860), whereby the remaining 950 fuses each break down with two or three pulses having energy E(860). Dispersions of breakdown characteristics occur in experimental results because of dispersions of manufacturing factors such as widths and thickness of fuses, shapes and sizes of polysilicon grains and metal silicide grains forming fuses, shapes of side walls of fuses, and thickness of insulating films surrounding fuses.

In light of dispersions of breakdown characteristics of fuses, it is presumed that fuse breakdown occurs with a single pulse of 1200 ns with high reproducibility. Hence, the energy E(1200) substantially matches the breakdown threshold Eₜₕ.

Fifteen percent of fuses each break down with a single pulse of 600 ns having energy E(600); and approximately 70% of fuses each break down with two pulses of 600 ns. This is because the energy E(600) is a half of the energy E(1200); hence, the sum of the energy of two pulses becomes equal to the breakdown threshold Eₜₕ. In addition, approximately 85% of fuses each break down with two pulses, the total energy of which is equal to the breakdown threshold Eₜₕ. The remaining 15% of fuses each break down with three pulses. This may result from dispersions of manufacturing factors.

The total energy of three pulses of 480 ns having energy E(480) exceeds the breakdown threshold Eₜₕ. Theoretically, it is presumed that most fuses each break down with three pulses. In actuality, a relatively large number of fuses fail to break down with three pulses; seven pulses are needed to cause break down with respect to 80% or more fuses; and all fuses each completely break down with ten pulses. That is, the actual number of pulses causing complete fuse breakdown is larger than the predicted number of pulses, which is predicted on the basis of the breakdown threshold Eₜₕ with respect to the energy E(480). Similar results occur with respect to pulses of 250 ns having energy E(250).

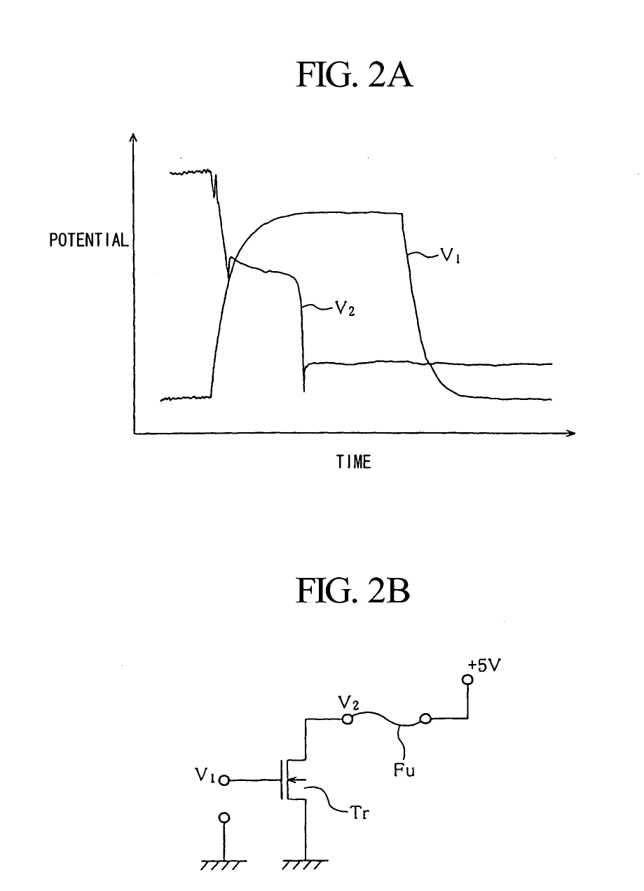

The reasons the actual number of pulses become larger than the predicted number of pulses will be described in detail with reference to FIGS. 2A and 2B.

FIG. 2B shows an equivalent circuit including a fuse and a breakdown circuit. A drive voltage of 5 V is applied to a first terminal of a fuse Fu, which is connected in series to an n-channel MOS transistor Tr whose source is grounded. A voltage V₁ is applied to the gate of the MOS transistor Tr. A potential V₂ appears at a connection point between the drain of the MOS transistor Tr and a second terminal of the fuse Fu. When a pulse having the voltage V₁ is applied to the gate of the MOS transistor Tr, the MOS transistor Tr is turned on so as to allow a current to flow through the fuse Fu. When energy accumulated in the fuse Fu exceeds the breakdown threshold Eₜₕ, the fuse Fu breaks down.

As shown in FIG. 2A, the voltage V₁ has a square waveform whose level increases with a certain time constant and is then sustained for a while. When a pulse increases in level (see the voltage V₁), a current starts to flow through the fuse Fu; hence, the potential V₂ rapidly drops due to a voltage drop caused by the fuse Fu and is then temporarily sustained at a prescribed level. When the fuse Fu breaks down, the potential V₂ rapidly drops to a ground potential.

When a pulse width is sufficiently long compared with a rise time, it is possible to neglect influence due to a leading portion. However, when the pulse width becomes short to reach 480 ns or 250 ns, it becomes difficult to neglect influence due to a leading portion. For example, when a pulse increases and decreases in level before reaching a constant level, a current flowing through the fuse Fu rapidly decreases before reaching a constant level. This increases the number of pulses causing fuse breakdown above the predicted number of pulses.

All fuses may each completely break down with fifteen to twenty pulses of 250 ns. This indicates that the energy E(250) substantially ranges from 1/15 to 1/20 of the breakdown threshold Eₜₕ. That is, although pulses of 250 ns are each one digit smaller in energy compared with the breakdown threshold Eₜₕ, it is possible to reliably cause fuse breakdown by increasing the number of pulses.

Each of pulses of 480 ns decreases in level before reaching a constant level. This indicates that both the pulse width and voltage are simultaneously reduced with respect to pulses of 480 ns. In other words, even though pulses are each reduced in voltage, it is possible to reliably cause fuse breakdown by increasing the number of pulses.

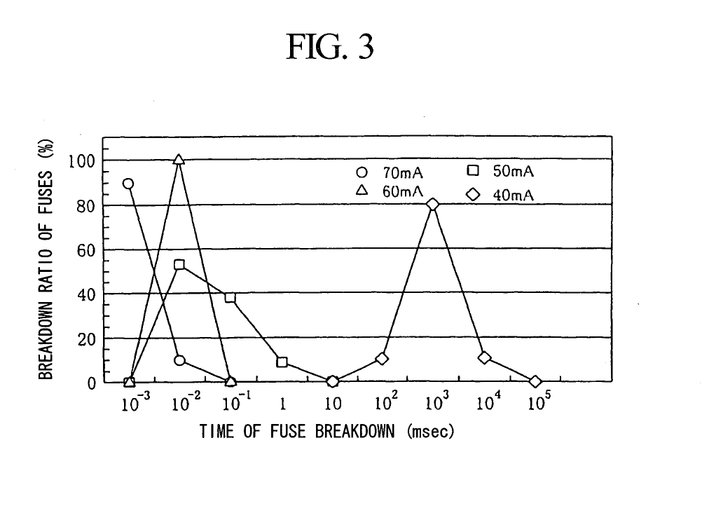

Other experiments are performed so as to determine effective times realizing fuse breakdown by changing currents flowing through fuses, and the results thereof will be described in detail with reference to FIG. 3, in which the horizontal axis represents the effective time realizing fuse breakdown in units of milli-seconds [ms], and the vertical axis represents the breakdown ratio of fuses [%]. The effective time realizing fuse breakdown is defined by the product of the pulse width and the number of pulses, wherein lines are drawn with respect to different currents, i.e., 70 mA, 60 mA, 50 mA, and 40 mA, each of which has the same pulse width of 1×10⁻³ ms.

The line drawn with respect to 70 mA shows that approximately 90% of fuses each needs 1000 ms to realize breakdown. As for pulses of 1200 ns produced by the current of 40 mA, it is predicted that the total number of pulses realizing fuse breakdown is “834”. In order to realize breakdown with respect to all fuses with the current of 40 mA, it may be necessary to set the effective time to 10000 ms. The effective time of 10000 ms can be realized by 40000 pulses of 250 ns.

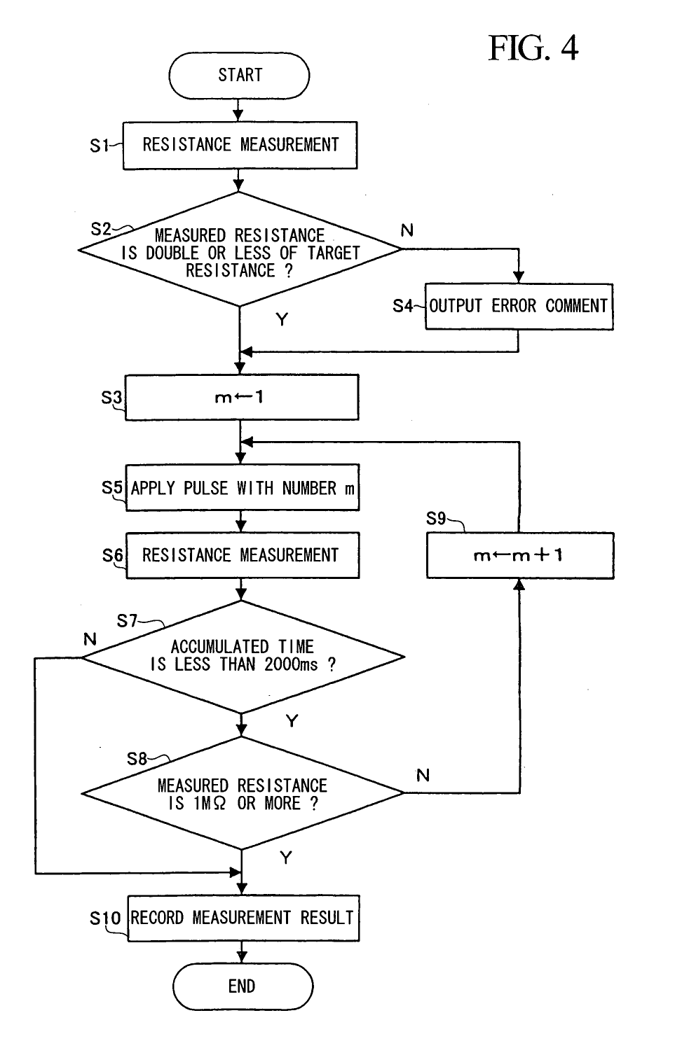

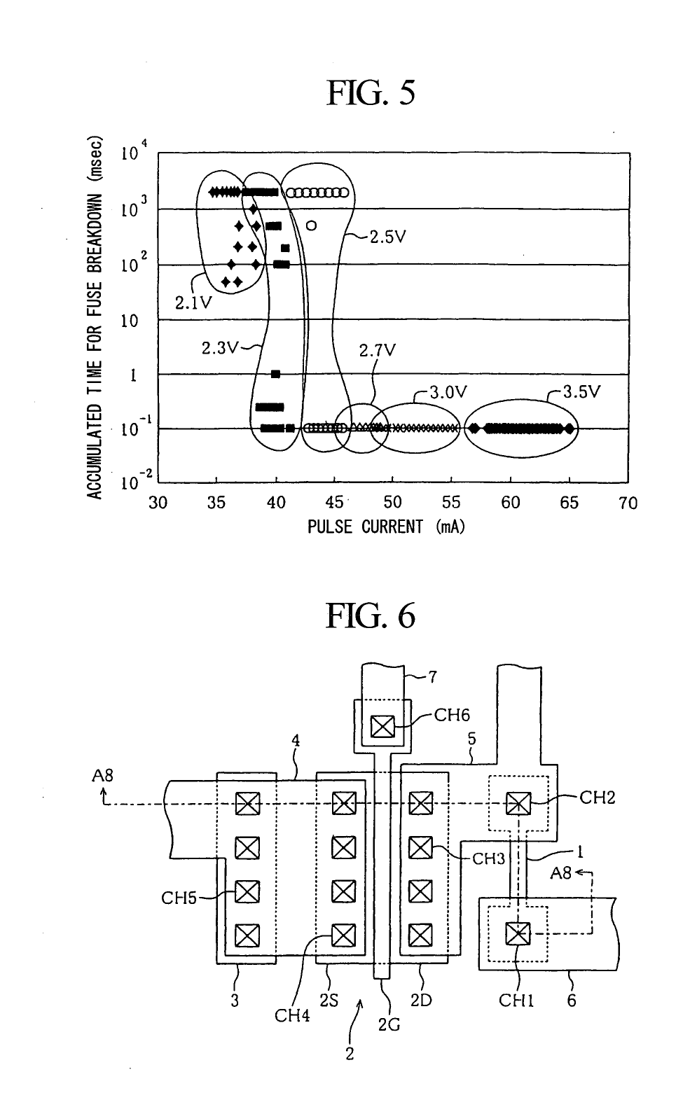

Next, a fuse breakdown method of the present embodiment will be described with reference to FIGS. 4 and 5 and Table 1. This method is performed by changing pulse widths over time.

FIG. 4 shows a flowchart showing the fuse breakdown method of the present embodiment. In step S1, initial resistance of a subject fuse to break down is measured by applying a pulse whose current is 1 mA or less and whose width is 1 ms or less. In step S2, the initial resistance is compared with target resistance with respect t the subject fuse. When the initial resistance is identical to or less than double the target resistance, the flow proceeds to step S3. When the initial resistance is greater than double the target resistance, the flow proceeds to step S4 in which an error comment is output; then, the flow proceeds to step S3. The reason a decision is made as to whether or not the initial resistance is less than or greater than double the target resistance is to avoid a reduction of the yield due to initial failure. Therefore, it is possible to set an arbitrary multiple of the target resistance instead of double.

In step S3, “1” is set to a variable m, which represents the number of pulses to be consecutively applied to the subject fuse. In step S5, m pulses are consecutively applied to the subject fuse.

Table 1 shows relationships between numbers of pulses having different widths and accumulated times of pulses.

TABLE 1

| Number of Pulses | Pulse Width (msec) | Accumulated Time (msec) |
|---|---|---|
| 1 | 0.10 | 0.10 |
| 2 | 0.15 | 0.25 |
| 3 | 0.25 | 0.50 |
| 4 | 0.50 | 1.0 |
| 5 | 1.0 | 2.0 |
| 6 | 3.0 | 5.0 |
| 7 | 5.0 | 10 |
| 8 | 10 | 20 |
| 9 | 30 | 50 |
| 10 | 50 | 100 |
| 11 | 100 | 200 |
| 12 | 300 | 500 |
| 13 | 500 | 1000 |
| 14 | 1000 | 2000 |

In the above, longer pulse widths are used for larger numbers of pulses. Since m=1 in step S3, a pulse whose width is 0.1 ms is applied to the subject fuse in step S5. In step S6, resistance of the subject fuse is measured in the aforementioned condition described with respect to step S1.

In step S7, a decision is made as to whether or not the accumulated time in which the subject fuse is exposed to electric energy is less than 2000 ms. The accumulated time can be easily calculated in light of the relationship between the variable m and the accumulated time shown in Table 1. When the accumulated time is equal to or greater than 2000 ms, the flow proceeds to step S10. When the accumulated time is less than 2000 ms, the flow proceeds to step S8 in which a decision is made as to whether or not the resistance of the subject fuse is equal to or greater than 1 MΩ. When the resistance of the subject fuse is equal to or greater than 1 MΩ, it is determined that the subject fuse breaks down; then, the flow proceeds to step S10. In step S10, the measurement result regarding the resistance of the subject fuse is recorded, thus completing the fuse breakdown method.

When the resistance of the subject fuse is less than 1 MΩ in step S8, in other words, when it is determined that the subject fuse does not break down, the flow proceeds to step S9 in which “1” is added to the variable m; thereafter, the flow proceeds to step S5 again.

As described above, until the accumulated time reaches 2000 ms or more, or until it is determined that the subject fuse breaks down, pulses are consecutively applied to the subject fuse so as to measure the resistance. As shown in Table 1, longer pulse widths are used for larger numbers of pulses.

The aforementioned fuse breakdown method is executed with respect to a large number of fuses, and the results thereof are shown in FIG. 5.

FIG. 5 shows the relationships between currents flowing through fuses and accumulated times for fuse breakdown, wherein the horizontal axis represents the pulse current measured in units of milli-seconds, and the vertical axis represents the accumulated time for fuse breakdown measured in units of milli-seconds. Various groups of subject fuses are classified in light of voltages of pulses, i.e., 2.1 V, 2.3 V, 2.5 V, 2.7 V, 3.0 V, and 3.5 V. Dispersions of pulse currents occurring in each group depend upon variations of initial resistances of subject fuses.

When the pulse current is 45 mA or more, each fuse breaks down with a single pulse of 0.1 ms. The accumulated time for fuse breakdown becomes longer as the pulse current becomes smaller. When the pulse current becomes smaller than 42 mA, the accumulated time for fuse breakdown becomes remarkably longer. In order to secure the longer accumulated time for fuse breakdown by use of pulses whose widths are made constant, it is necessary to greatly increase the number of pulses; and this in turn increases the processing time realizing fuse breakdown. For example, it needs the processing time of 4000 ms in order to achieve the accumulated time of 2000 ms by use of pulses of 0.25 ms, each of which is output with a time interval of 0.25 ms.

Table 1 does not show, but as the pulse width is gradually increased, the processing time reaches 2003.5 ms in order to achieve the accumulated time of 2000 ms. As the number of pulses consecutively applied to each subject fuse becomes large, it is possible to reduce the processing time by increasing the pulse width.

Of course, the pulse widths applicable to the present embodiment are not necessarily limited to ones shown in Table 1. For example, it is possible to set a pulse width of A×2^{m} adapted to each of m pulses; in general, the pulse width can be calculated as A×i^{m} (where A and i are integral constants arbitrarily selected). Alternatively, the pulse width can be calculated as A×mⁱ.

Alternatively, the time interval between consecutive pulses can be set constant, or the time interval can be increased as the pulse width becomes longer. However, when the time interval increases to match the pulse width, it becomes very difficult to reduce the processing time. For this reason, the time interval is set to a certain time in which each fuse is restored in temperature after being heated by a previous pulse applied thereto.

In step S8 shown in FIG. 4, a decision is made as to whether or not the subject fuse breaks down with reference to a prescribed resistance, which is set to 1 MΩ, however that can be set to another high resistance value realizing determination of fuse breakdown. For example, the resistance can be set to several hundreds of kilo-ohms (kΩ) or any other high impedance, which make it possible to determine fuse breakdown by a readout circuit. When a trimming circuit whose resistance ranges from several tens of ohms to several hundreds of ohms is adapted to a semiconductor device, for example, it is possible to determine fuse breakdown when the fuse resistance ranges from several kilo-ohms to several tens of kilo-ohms. Once fuse breakdown is detected, no pulse is applied to the subject fuse. This reliably prevents pulses from being unnecessarily applied to the subject fuse. Hence, it is possible to reduce the time for fuse breakdown.

Next, a semiconductor device incorporating a fuse and a breakdown circuit will be described, wherein the basic configuration is identical to the equivalent circuit shown in FIG. 2B, in which the drive voltage is not necessarily limited to 5 V. The current flowing through the fuse Fu depends on the resistance of the fuse Fu, the ON-resistance of the MOS transistor Tr that is turned on, and drive voltage. When the fuse Fu breaks down, no drain current flows irrespective of a pulse voltage applied to the gate of the MOS transistor Tr.

FIG. 2B shows a simple series circuit of the fuse Fu and the MOS transistor Tr. It is possible to provide a fuse array including plural sets of the aforementioned series circuit with a single semiconductor device. Alternatively, a single breakdown circuit can be adapted to plural fuses, wherein energy per each pulse applied to a single fuse is reduced, but it is possible to cause breakdown simultaneously on plural fuses by applying multiple pulses.

Alternatively, plural transistors are arranged for a single fuse so as to produce a relatively high breakdown current, wherein transistors can be configured as CMOS transistors or bipolar transistors. Latch circuits can be used to produce high gate voltages applied to transistors, thus increasing pulse widths of breakdown currents, which flow through transistors multiple times.

A pulse generator can be used to generate pulses flowing through fuses in synchronization with clock signals of semiconductor integrated circuits. In addition, a frequency divider can be used to convert frequencies of clock signals into frequency-divided signals, so that pulses are produced in synchronization with frequency-divided signals. Furthermore, a delay circuit can be used to delay pulses from clock signals.

A conduction detection circuit can be used to make a decision as to whether or not each fuse completely breaks down. Alternatively, it is possible to modify the circuitry such that in response to the feedback from the conduction detection circuit declaring that each fuse completely breaks down, no pulse is applied to each fuse. This control can be performed using programs.

FIG. 6 is a plan view showing a semiconductor device in which a fuse 1, a MOS transistor 2, and a p-well tap 3 are formed on a semiconductor substrate. The MOS transistor 2 includes a gate electrode 2G, a source region 2S, and a drain region 2D. One end of the fuse 1 is connected to a power line 6 (positioned in an upper layer) via a contact hole CH1. The other end of the fuse 1 and the drain region 2D are mutually connected with a contact hole CH2, an interconnection line 5 (positioned in an upper layer), and plural contact holes CH3.

The source region 2S and the well tap 3 are connected to a ground line 4 (positioned in an upper layer) via plural contact holes CH4 and plural contact holes CH5. In addition, the gate electrode 2G is connected to a wiring layer 7 (positioned in an upper layer) via a contact hole CH6.

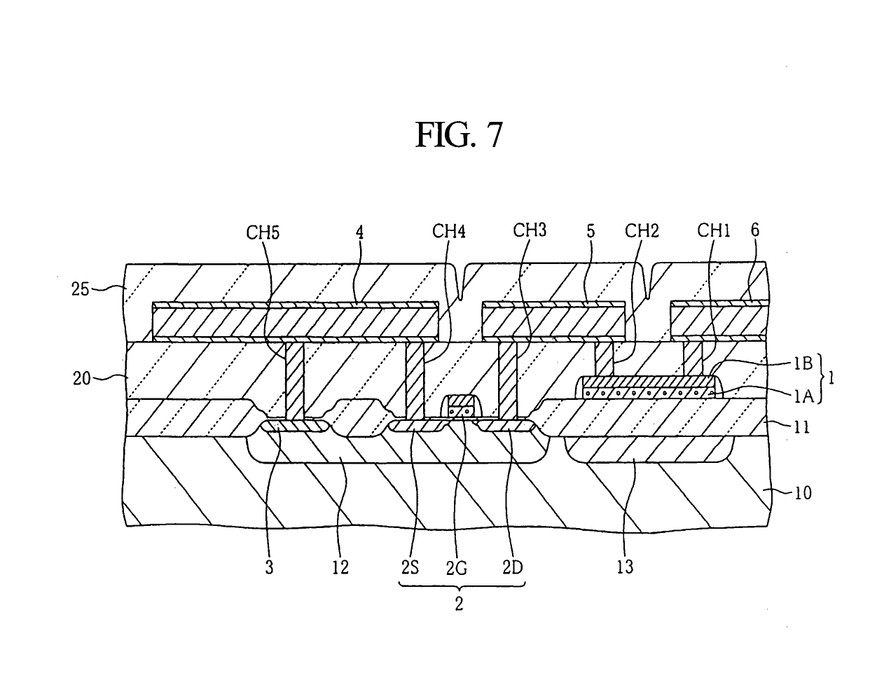

FIG. 7 is a cross-sectional view taken along line A8-A8 in FIG. 6. An insulating layer 11 is formed on the surface of a semiconductor substrate 10 composed of p-type silicon so as to partition plural active regions. A p-well 12 and an n-well 13 are formed on the surface of the semiconductor substrate 10. The p-well 12 includes two active regions. The n-well 13 is formed beneath the insulating layer 11.

A p-well tap 3 is formed on the surface of one active region in the p-well 12; and the aforementioned n-channel MOS transistor 2 having the source region 2S, drain region 2D, and gate electrode 2G is formed in another active region. The fuse 1 is formed on the insulating layer 11. Viewing in a normal direction perpendicular to the semiconductor substrate 10, the n-well 13 is formed to include the fuse 1 therein. Each of the gate electrode 2G and the fuse 1 has a two-layered structure including a polysilicon layer and a high-melting-point metal silicide layer.

An interlayer insulating layer 20 is formed to cover the fuse 1, the MOS transistor 2, and the p-well tap 3. The interlayer insulating layer 20 has a two-layered structure including a phosphorus silicate glass (PSG) layer and a boron phosphorus silicate glass (BPSG) layer, and the total thickness thereof ranges from 0.6 μM to 0.8 μm. The contact holes CH1 to CH5 are formed in the interlayer insulating layer 20. The contact holes CH1 and CH2 are formed at both ends of the fuse 1. Viewing in a normal direction perpendicular to the semiconductor substrate 10, the contact holes CH3, CH4, and CH5 are respectively positioned inside of the drain region 2D, source region 2S, and well tap 3. Conduction plugs each composed of tungsten are embedded in the contact holes CH1 to CH5 respectively. It is possible to form sticking layers composed of TiO and TiON in the contact holes CH1 to CH5.

The ground line 4, interconnection line 5, and power line 6 are formed above the interlayer insulating layer 20. These lines are each composed of Al, AlSi alloy, AlSiCu alloy, and the like. Alternatively, they can be each composed of Cu, CuCr alloy, CuPd alloy, and the like. It is possible to form barrier layers composed of Ti, TiN, and TiON beneath the aforementioned lines. Or, it is possible to additionally form cap layers composed of Ti and TiN above the aforementioned lines.

The ground line 4 is connected to the source region 2S via the conduction plug in the contact hole CH4 and is also connected to the well tap 3 via the conduction plug in the contact hole CH5. The interconnection line 5 interconnects one terminal of the fuse 1 and the drain region 2D via the conduction plugs in the contact holes CH2 and CH3. The power line 6 is connected to the other terminal of the fuse 1 via the conduction plug in the contact hole CH1. A protection layer 25 covers the ground line 4, interconnection line 5, and power line 6. The protection layer 25 has a two-layered structure including a silicon oxide layer and a silicon nitride layer, and the thickness thereof ranges from 0.8 μm to 1.4 μm, for example.

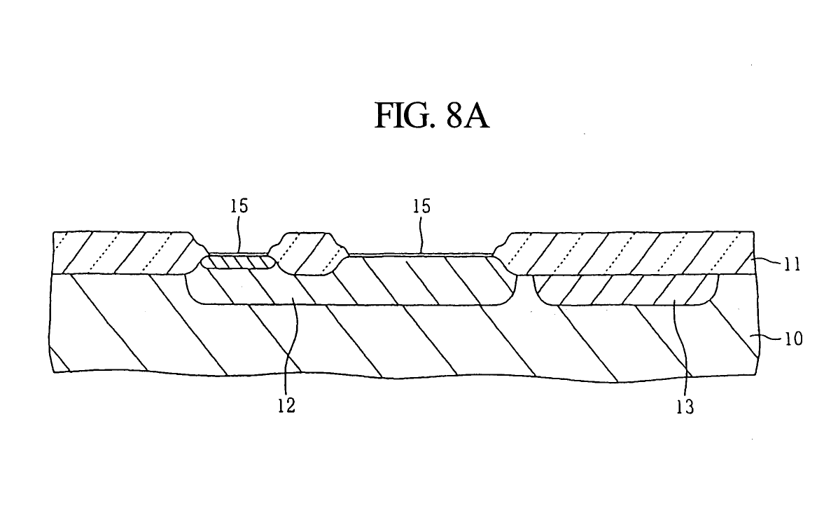

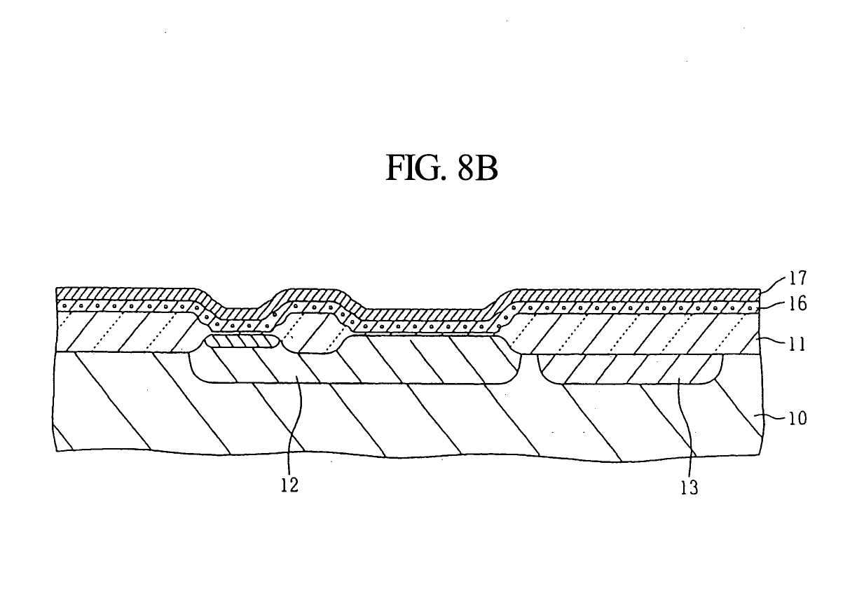

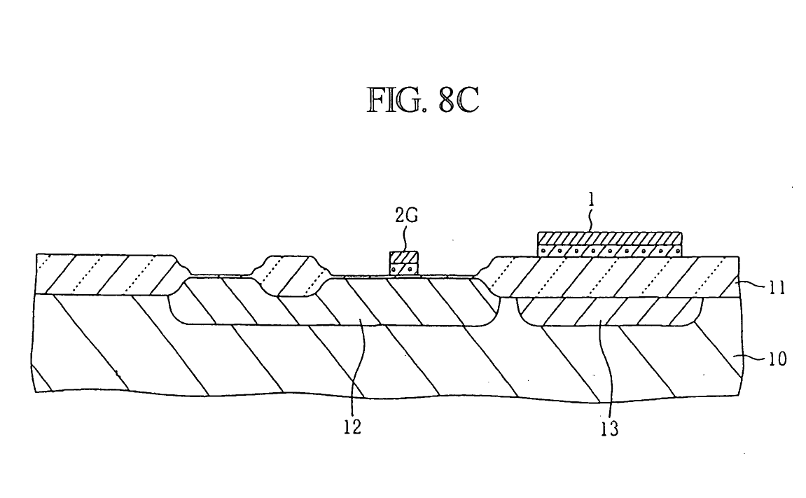

A manufacturing method of the aforementioned semiconductor device will be described with reference to FIGS. 8A to 8E.

As shown in FIG. 8A, the insulating layer 11 of 500 nm thickness composed of silicon oxide is formed in a selected region of the semiconductor substrate 10 composed of p-type silicon in accordance with the LOCOS method or the STI (shallow trench isolation) method. Ion implantation is performed to form the p-well 12 and n-well 13. An anti-oxidation mask used for the formation of the insulating layer 11 is removed so that the surface of the semiconductor substrate 10 is exposed with respect to an active region. A silicon oxide layer 15 is formed on the surface of the active region by way of thermal oxidation. Incidentally, the silicon oxide layer 15 formed in the active region used for the formation of a MOS transistor serves as a gate insulating layer.

Instead of the oxide silicon layer 15, it is possible to use a two-layered structure consisting of a silicon oxide layer and a silicon nitride layer, a two-layered structure consisting of a tantalum oxide layer and a silicon oxide layer, or a three-layered structure in which a silicon nitride layer is inserted between two silicon oxide layers. Herein, the silicon nitride layer can be replaced with the silicon oxide layer. The silicon nitride layer is formed in such a way that a silicon oxide layer formed by thermal oxidation is subjected to heat treatment using N₂ gas or NOx gas and is thus subjected to nitrification. Alternatively, the silicon nitride layer can be formed by way of plasma-excitation CVD using tetra-ethyl-ortho-silicate (TEOS), oxygen (O₂), ozone (O₃), and NOx or by way of chemical vapor deposition (CVD) using ECR plasma. In addition, only the surface of the silicon nitride layer is subjected to thermal oxidation in the oxide atmosphere so as to form a three-layered structure in which a silicon nitride layer is inserted between two silicon oxide layers.

As shown in FIG. 8B, a polysilicon layer 16 is formed on the surface of the semiconductor substrate 10 by way of the CVD using silane (SiH₄) and nitrogen (N₂) under the following conditions.

Flow ratio between silane and nitrogen: 20:80.

Gas flow: 200 sccm.

Pressure: 30 Pa.

Substrate temperature: 600° C.

It is possible to realize deposition of amorphous silicon by setting the substrate temperature below the aforementioned value. Alternatively, the substrate is heated after the deposition of amorphous silicon and is thus subjected to polycrystal processing. Of course, it is possible to directly use an amorphous silicon layer. The thickness of the polysilicon layer 16 appropriately ranges from 20 nm to 1000 nm, preferably, from 80 nm to 200 nm. Phosphorus (P) material is uniformly diffused into the polysilicon layer 16 so as to realize impurities concentration of 1×10²⁰ cm⁻³ at the prescribed temperature ranging from 800° C. to 900° C., for example. It is preferable that, before diffusion, a natural oxide layer formed on the surface of the polysilicon layer 16 be removed by use of buffered hydrofluoric acid.

A high-melting-point metal silicide layer 17 composed of tungsten silicide (WSix) is formed on the polysilicon layer 16 by way of sputtering or CVD, wherein the thickness thereof ranges from 25 nm to 500 nm, preferably, from 80 nm to 200 nm. The high-melting-point metal silicide layer 17 can be formed using MoSix, TiSix, and TaSix instead of WSix. Instead of the high-melting-point metal silicide layer 17, it is possible to form a metal layer composed of high-melting-point metals such as Mo, Ti, Ta, and W, transition metals such as Co, Cr, Hf, Ir, Nb, Pt, Zr, and Ni, and alloys including high-melting-point metals and transition metals, for example.

Rapid thermal annealing (RTA) is performed for ten seconds at 1100° C. so as to realize low resistances with respect to the polysilicon layer 16 and the high-melting-point metal silicide layer 17. This heat treatment reliably avoids the occurrence of interface separation between the polysilicon layer 16 and the high-melting-point metal layer 17. The annealing time ranges from 1 second to 120 seconds, preferably, from 5 seconds to 30 seconds. The annealing temperature ranges from 800° C. to 1150° C., preferably, from 900° C. to 1100° C. Instead of the RTA, it is possible to perform heat treatment using an electric furnace in a prescribed time ranging from 5 minutes to 90 minutes, preferably, from 15 minutes to 30 minutes.

As shown in FIG. 8C, the polysilicon layer 16 and the high-melting-point metal silicide layer 17 are subjected to patterning, thus forming the gate electrode 2G and the fuse 1, each of which has a two-layered structure. Etching is performed on two layers by means of an ECR plasma etching device using etching gas, which is a mixture of chlorine (Cl₂) and oxygen (O₂).

As shown in FIG. 8D, phosphorus ion is implanted into both sides of the surface of the semiconductor substrate 10 with respect to the gate electrode 2G serving as a mask, thus forming low-density regions 2Sa and 2Da in accordance with the low-density drain (LDD) structure. Boron ion is implanted onto the surface of the active region of the p-well 12, thus forming the p-well tap 3. Implantation of boron ion into the p-well tap 3 is performed simultaneously with the ion implantation into low-density regions according to the LDD structure with respect to a p-channel MOS transistor (not shown).

As shown in FIG. 8E, side wall spacers 18 composed of silicon oxide are formed on both sides of the gate electrode 2G and both sides of the fuse 1. Implantation of phosphorus ion is performed onto the surface of the semiconductor substrate on both sides of a mask corresponding to the gate electrode 2G and its side wall spacers 18, thus forming high-density regions of source and drain. Thus, it is possible to form the source region 2S and the drain region 2D in accordance with the LDD structure.

When boron ion is implanted into the high-density regions of source and drain of the p-channel MOS transistor, boron ion is implanted into the p-well tap 3 as well. After completion of the ion implantation, active annealing is performed.

Then, well-known steps are performed so as to form the interlayer insulating layer, contact holes, conduction plugs in contact holes, and lines and wiring. Thus, it is possible to obtain the semiconductor device shown in FIG. 7.

It is possible to additionally perform self-alignment processing on the semiconductor device shown in FIG. 8E so as to form metal silicide layers on the source regions 2S, drain region 2D, and p-well tap 3. In this case, the high-melting-point silicide layer is exposed above the gate electrode 2G and the fuse 1; hence, a silicide reaction may not progress thereon. For this reason, it is possible to modify the manufacturing method such that in the step of FIG. 8B, the high-melting-point metal silicide layer 17 is not formed, and after completion of the ion implantation into the source and drain regions in the step of FIG. 8E, self-alignment processing is performed so as to form the high-melting-point metal silicide layer on the gate electrode 2G and the fuse 1.

The n-well 13 formed beneath the fuse 1 reduces the parasitic capacity between the fuse 1 and the semiconductor substrate 10.

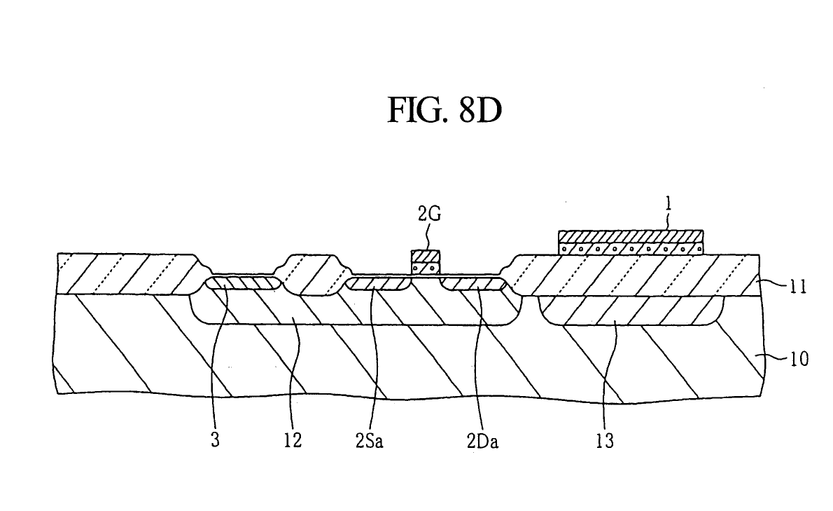

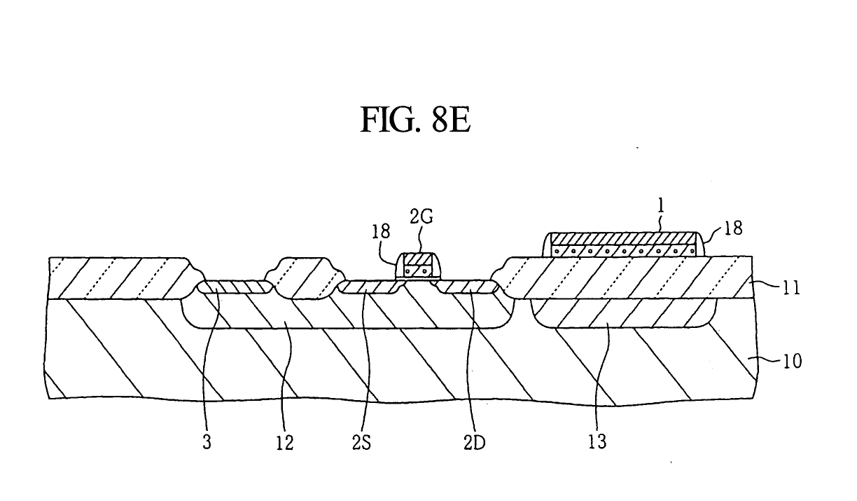

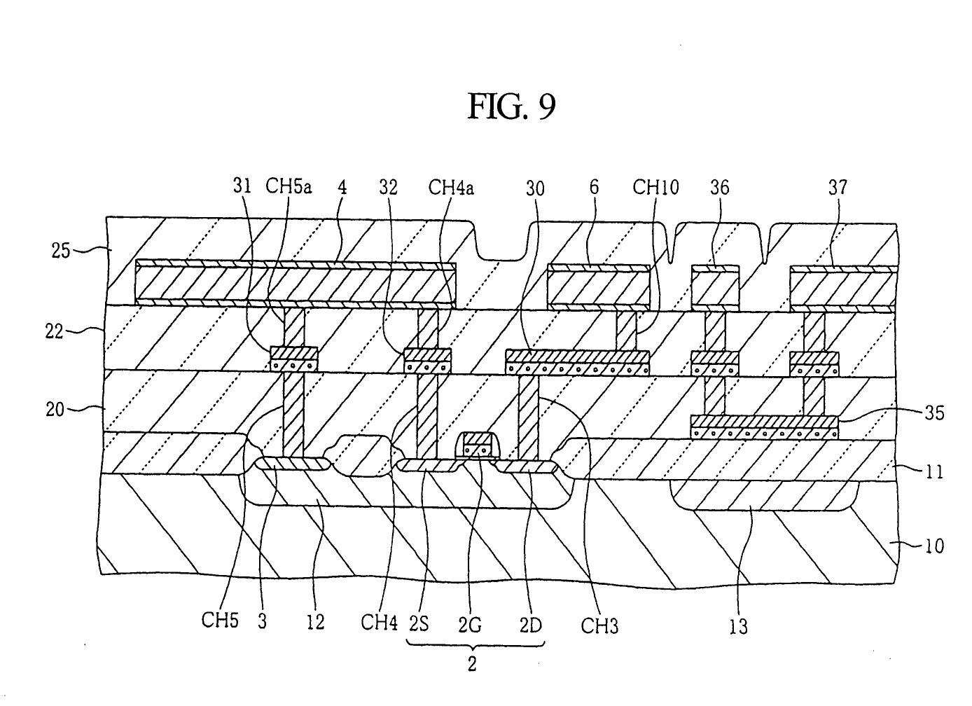

FIG. 9 shows a semiconductor device that is a variation of the semiconductor device shown in FIG. 7 in which the fuse 1 connected to the MOS transistor 2 is formed in contact with the surface of the insulating layer 11. In the semiconductor device shown in FIG. 9, a fuse 30 (corresponding to the fuse 1) is formed on the first interlayer insulating layer 20. One terminal of the fuse 30 is connected to the drain region 2D of the MOS transistor 2 via a conduction plug embedded in the contact hole CH3 running through the first interlayer insulating layer 20. A second interlayer insulating layer 22 covers the fuse 30.

The ground line 4 and power line 6 are formed on the second interlayer insulating layer 22. The p-well tap 3 is connected to the ground line 4 via a conduction plug embedded in the contact hole CH5 running through the first interlayer insulating layer 20, an intermediate conduction member 31 formed on the first interlayer insulating layer 20, and a conduction plug embedded in a contact hole CH5a running through the second interlayer insulating layer 22. The source region 2S of the MOS transistor 2 is connected to the ground line 4 via a conduction plug embedded in the contact hole CH4 running through the first interlayer insulating layer 20, an intermediate conduction member 32 formed on the first interlayer insulating layer 20, and a conduction plug embedded in a contact hole CH4a running through the second interlayer insulating layer 22.

The other terminal of the fuse 1, which is not connected with the MOS transistor 2, is connected to the power line 6 via a conduction plug embedded in a contact hole CH10 running through the second interlayer insulating layer 22.

A fuse 35 is formed in contact with the surface of the insulating layer 11. Opposite ends of the fuse 35 are respectively connected to wirings 36 and 37 formed on the second interlayer insulating layer 22. A protection layer 25 is formed to cover the ground line 4, power line 6, and wirings 36 and 37.

Each of the fuse 30 and the intermediate members 31 and 32 formed on the surface of the first interlayer insulating layer 20 has a two-layered structure including a polysilicon layer and a high-melting-point metal silicide layer. The following description is given with respect to the method of forming the aforementioned two-layered structure.

First, a polysilicon layer is formed in accordance with the CVD method; and impurities such as phosphorus are diffused into the polysilicon layer. A high-melting-point metal silicide layer is formed on the polysilicon layer in accordance with the CVD method. After completion of the formation of the two-layered structure, rapid thermal annealing (RTA) is performed for ten seconds at 850° C. Herein, the heat treatment is performed at a prescribed temperature ranging from 500° C. to 1000° C., preferably, from 700° C. to 950° C. The upper limit of the temperature for performing the heat treatment is determined such that substantially no change occurs in the distribution regarding impurities into the source and drain regions of the MOS transistor 2, and substantially no change occurs in the surface shape of the first interlayer insulating layer 20 due to reflow. In addition, the heat treatment is performed for a prescribed time ranging from 1 second to 120 seconds, preferably, from 5 seconds to 30 seconds.

Instead of the rapid thermal annealing (RTA), it is possible to perform heat treatment using an electric furnace for a prescribed time ranging from 5 minutes to 90 minutes, preferably, from 10 minutes to 30 minutes. After completion of the heat treatment, the high-melting-point metal silicide layer and the polysilicon layer are subjected to patterning, thus exposing the fuse 30 and the intermediate conduction members 31 and 32.

Of course, it is possible to form the intermediate conduction members 31 and 32 by use of a single polysilicon layer. In this case, resistors formed using the single polysilicon layer can be arranged on the first interlayer insulating layer 20.

The aforementioned fuse breakdown method can be adapted to the semiconductor device of FIG. 9, in which multiple pulses are applied to fuses to break down. Herein, relatively low influence occurs in the surrounding area due to the meltdown of the fuse 30. This allows the fuse 30 to be positioned in proximity to the MOS transistor 2. In other words, the active region of the MOS transistor 2 can be positioned to partially overlap with the fuse 30 on the surface of the semiconductor substrate 10. This contributes to a reduction of the size of the fuse and its circuitry.

FIG. 10 is a cross-sectional view showing the structure of a semiconductor device in which, similar to the semiconductor device shown in FIG. 7, the insulating layer 11 is formed to partially cover the semiconductor substrate 10, wherein the MOS transistor 2 is formed in the active region surrounded by the insulating layer 11. Plural fuses 40 are formed in contact with the surface of the insulating layer 11 so as to form a fuse array. A first interlayer insulating layer 41 covers the fuses 40 and the MOS transistor 2.

Plural fuses 42 are formed on the first interlayer insulating layer 41 so as to form a fuse array and are covered with a second interlayer insulating layer 43. Plural fuses 44 are formed on the second interlayer insulating layer 43 and are covered with a third interlayer insulating layer 45. Wirings 50 are formed on the third interlayer insulating layer 45 and are covered with a protective layer 51.

FIG. 10 shows that plural fuses are arranged in connection with plural wiring layers, wherein each fuse has a two-layered structure including a polysilicon layer and a high-melting-point silicide layer or a simple structure having a single polysilicon layer.

The aforementioned fuse breakdown method is adapted to the semiconductor device of FIG. 10 so that influence on elements surrounding each fuse can be reduced when each one fuse breaks down. This allows lower fuses and upper fuses to partially overlap in a vertical direction on the surface of the semiconductor substrate 10.

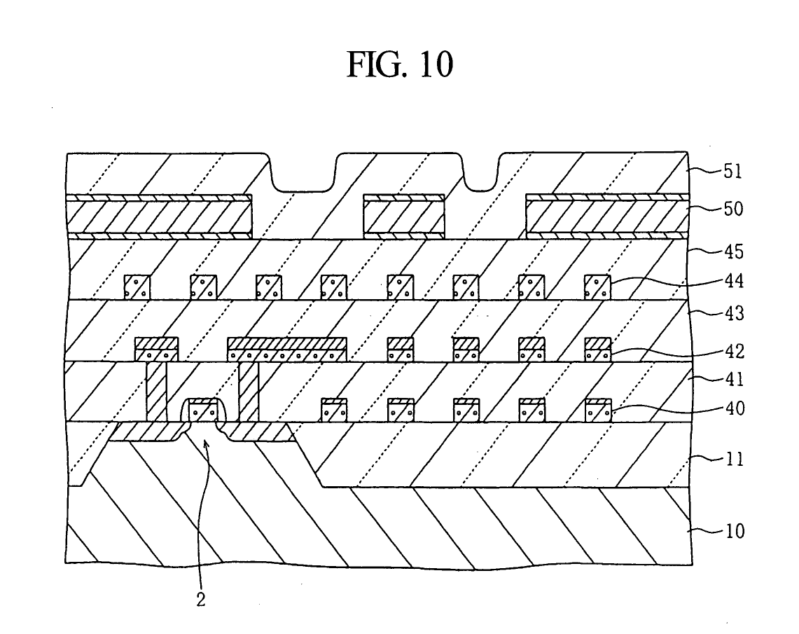

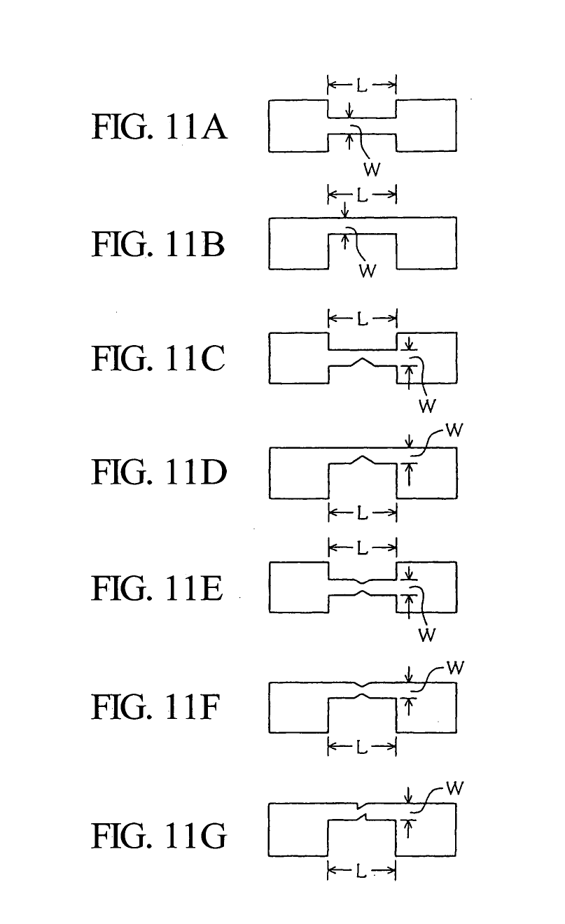

FIGS. 11A to 11G show various examples of fuses, each of which has a pair of terminals each having a square shape and an interconnection portion having a width W and a length L.

Specifically, FIG. 11A shows a first example of a fuse in which the interconnection portion interconnects the center portions of the terminals. FIG. 11B shows a second example of a fuse in which the interconnection portion interconnects the top portions of the terminals.

FIG. 11C shows a third example of a fuse in which the interconnection portion, one side of which is narrowly constricted with an isosceles-triangular recess having a right angle in the middle, interconnects the center portions of the terminals. FIG. 11D shows a fourth example of a fuse in which the interconnection portion, which is narrowly constricted with an isosceles-triangular recess having a right angle in the middle, interconnects the top portions of the terminals.

FIG. 11E shows a fifth example of a fuse in which the interconnection portion, both sides of which are each narrowly constricted with an isosceles-triangular recess having a right angle in the middle, interconnects the center portions of the terminals. FIG. 11F shows a sixth example of a fuse in which the interconnection portion, both sides of which are each narrowly constricted with an isosceles-triangular recess having a right angle in the middle, interconnects the top portions of the terminals.

FIG. 11G shows a seventh example of a fuse in which the interconnection portion, both sides of which are each narrowly constricted with a triangular recess having an acute angle in the middle, interconnects the top portions of the terminals. Herein, triangular recesses respectively formed in opposite sides of the interconnection portion are formed in proximity to and in parallel with each other.

The narrowed portion of the interconnection portion makes it easy for each fuse to break down with relatively small energy.

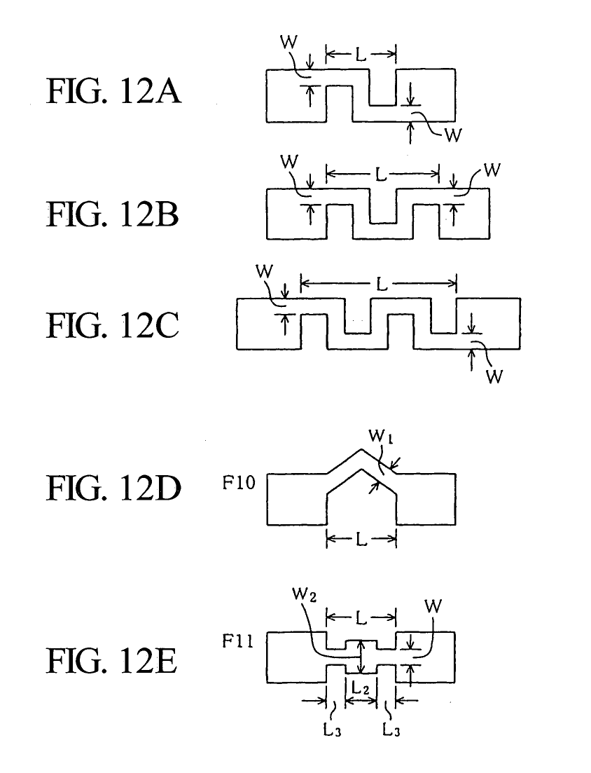

FIGS. 12A to 12C show other types of fuses, each of which includes a pair of terminals each having a square shape and an interconnection portion (having a width W and a length L) that is bent at some portions at a right angle.

Specifically, FIG. 12A shows an eighth example of a fuse in which the interconnection portion has two bent areas so as to interconnect the top portion of one terminal and the lower portion of the other terminal. FIG. 122B shows a ninth example of a fuse in which the interconnection portion has four bent areas so as to interconnect the top portions of the terminals. FIG. 12C shows a tenth example of a fuse in which the interconnection portion has six bent areas so as to interconnect the top portion of one terminal and the lower portion of the other terminal.

FIGS. 12D and 12E show other types of fuses, each of which includes a pair of terminals each having a square shape and an interconnection portion having a length L.

Specifically, FIG. 12D shows an eleventh example of a fuse in which the interconnection portion (having a width W₁), which is bent upwardly with an angle of 45° in the middle, interconnects the top portions of the terminals. FIG. 12E shows a twelfth example of a fuse in which the interconnection portion, which is expanded widely with a rectangular portion (having a width W₂ larger than the width W and a length L₂ shorter than the length L) in the middle, interconnects center portions of terminals.

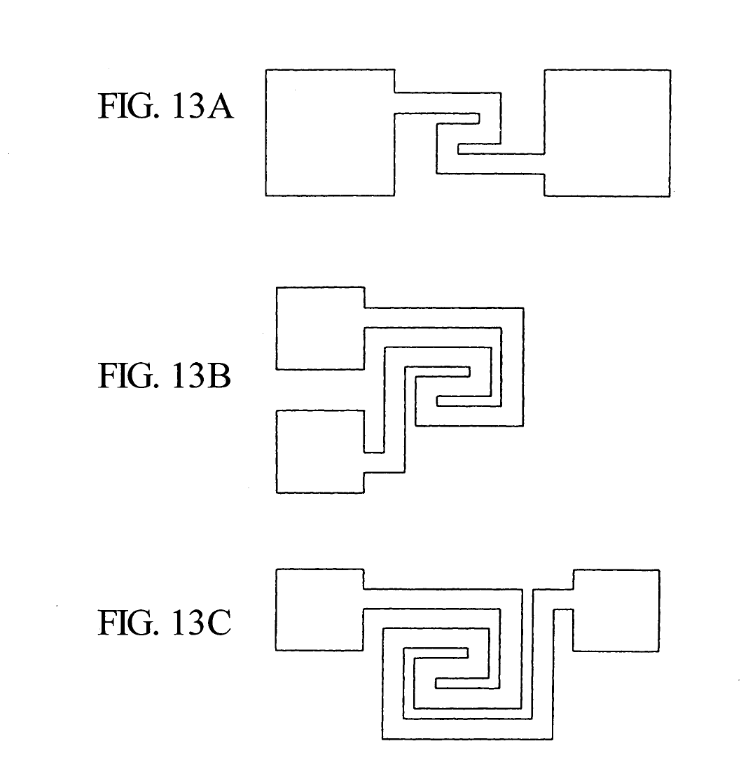

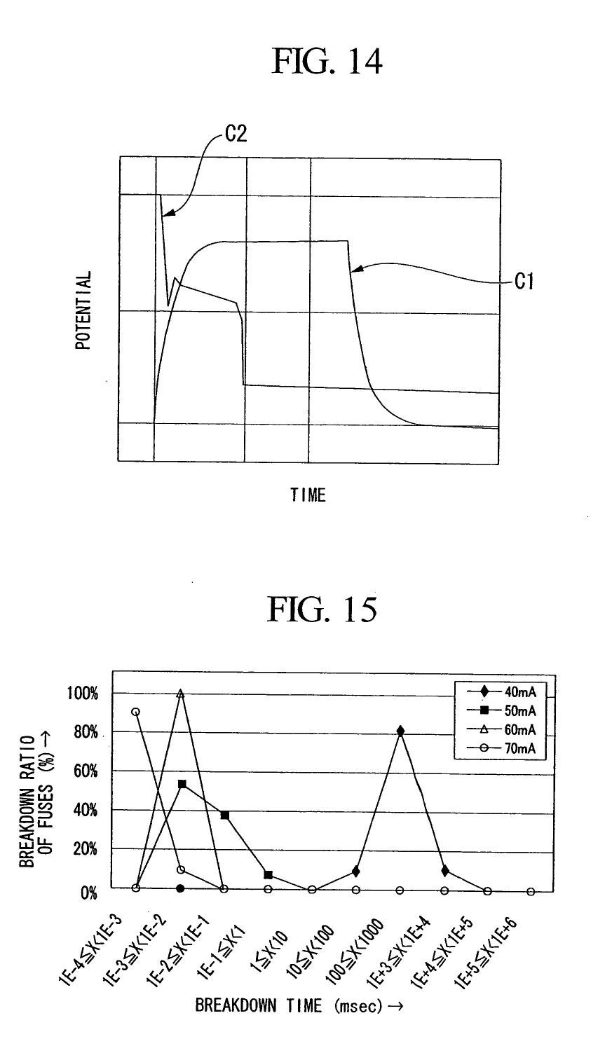

FIG. 13A shows a thirteenth example of a fuse in which an interconnection portion having a zigzag shape interconnects an upper portion of one terminal and a lower portion of the other terminals. FIG. 13B shows a fourteenth example of a fuse in which an interconnection portion having a spiral shape interconnects center portions of terminals arranged adjacent to each other. FIG. 13C shows a fifteenth example of a fuse in which an interconnection portion having a zigzag and spiral shape interconnects upper portions of terminals arranged opposite to each other.

### 2. Second Embodiment

Similar to the first embodiment, the second embodiment is designed based on the principle in which each fuse breaks down with multiple pulses each having relatively low power.

The total energy E′ of pulses applied to a fuse must be equal to or greater than the minimum energy E sufficient to cause breakdown with a single pulse; hence, E′≧E. Suppose that fuse breakdown occurs with a single pulse having breakdown energy of E=5.0E−7 [J]. If fuse breakdown occurs with two electric pulses, the total energy, i.e., E′(1+2), is equal to or higher than E; hence, E′(1+2)≧5.0E−7 [J].

If the breakdown energy E is uniformly divided by “2” to produce two pulses, each pulse has energy E/2 that is equal to or higher than 2.5E−7 [J]. That is, each pulse requires a half the breakdown energy. It is not necessarily required that first-pulse energy E′(1) be equal to second-pulse energy E′(2); that is, one of them can be set to be higher than the other; hence, E≧E′(1)≧E′(2) or E≧E′(2)≧E′(1)). The sum of the first-pulse energy and second-pulse energy, represented as E′(1+2), should be equal to or lower than E; hence, E≦E′(1+2).

When the breakdown energy is uniformly divided by “n” to produce n pulses, each pulse has energy that is equal to or higher than (5.0E−7)/n, whereby it is possible to reduce energy per each pulse (represented as E′(1), E′(2), . . . , E′(n)), that is, E′(1), E′(2), . . . , E′(n)≦E; and the total energy E′(1+2+ . . . +n) is equal to or higher than E; hence, E′(1+2+ . . . +n)≧E.

Each pulse whose energy is reduced to 1/n of the breakdown energy E is not high enough to cause melting and scattering of fuse materials; hence, it is possible to prevent physical destruction from occurring in the periphery of a fuse. This is because E′(1+2+ . . . +n)≧E, and the lastly applied pulse E′(n) which is substantially equal to E/n may finally cause fuse breakdown.

In the above, “n” is not necessarily set to an integer and is therefore set to any value as long as each fuse reliably breaks down with multiple pulses where E′(1+2+ . . . +n)≧E.

For example, when each pulse has 80% of the breakdown energy E=5.0E−7 [J] (where n=1.25), first-pulse energy E′(0)=4.0E−7 [J] does not cause breakdown; however, the sum of the first-pulse energy and second-pulse energy, i.e., E′(1+2)=8.0E−7 [J], exceeds the breakdown energy E=5.0E−7 [J]; hence, each fuse completely breaks down with first and second pulses consecutively applied thereto. Similarly, when each pulse has 30% of the breakdown energy E=5.0E−7 [J] (where n=3.333), the sum of energy of three pulses is calculated as E′(1+2+3)−4.5E−7 [J], which is insufficient to cause breakdown; however, the sum of energy of four pulses is calculated as E′(1+2+3+4)=6.0E−7 [J], so that each fuse completely breaks down with four pulses consecutively applied thereto.

In actuality, fuses may not completely break down with multiple pulses whose numbers are theoretically determined in an ideal condition; hence, dispersions may occur in the distribution regarding numbers of pulses causing fuse breakdown; however, the aforementioned calculation may be useful in determining numbers of pulses causing fuse breakdown.

Three methods (A), (B), and (C) are provided to establish the aforementioned relationship E′(1+2+ . . . +n)≧E by accumulating E′(1), E′(2), . . . , E′(n) in consideration of the relationship of E=W*s=V*A*s (where E represents energy; W represents electric power; V represents voltage; A represents current; and s represents time), wherein the method (A) is to reduce a time length (or a width) s with respect to each pulse, the method (B) is to reduce the current A or the voltage V with respect to each pulse, and the method (C) is the combination of the methods (A) and (B).

Incidentally, the method (C) refers to the setting of energy for each pulse in terms of the breakdown, wherein time is divided by “n”, and current (or voltage) is divided by “m” so that energy is divided by n*m and is therefore reduced to 1/(n*m). For the sake of convenience, the following description is made under the presumption of n=n*m.
(A) The time length (or time) is divided by “n” so as to establish relationships of s≧s′(1), s′(2), . . . , s′(n) and s≦s′(1)+s′(2)+ . . . +s′(n) with respect to pulses. This indicates E′(1)=E*s′(1)/s, E′(2)=E*s′(2)/s, . . . , E′(n)=E*s′(n)/s with respect to pulses; hence, E′(1), E′(2), . . . , E′(n)≦E, and E′(1+2+ . . . +n)≧E.
(B) The current is divided by “n” so as to establish relationships of A≧A′(1), A′(2), . . . , A′(n) and A≦A′(1)+A′(2)+ . . . +A′(n) with respect to pulses. This indicates E′(I)=E*A′(1)/A, E′(2)=E*A′(2)/A, . . . , E′(n)=E*A′(n)/A with respect to pulses; hence, E′(1), E′(2), . . . , E′(n)≦E, and E′(1+2+ . . . +n)≧E. The voltage can be similarly divided because V=A*R (where R represents fuse resistance, which is presumed to be constant).
(C) The method (C) is the combination of the methods (A) and (B). That is, both the time length and the current (or voltage) are uniformly divided by “n” so as to establish the aforementioned relationships of s≧s′(1), s′(2), . . . , s′(n) and s≦s′(1)+s′(2)+ . . . +s′(n) and the aforementioned relationships of A≧A′(1), A′(2), . . . , A′(n) and A≦A′(1)+A′(2)+ . . . +A′(n) with respect to pulses. This indicates E′(1)=E*s′(1)/s*A′(1)/A, E′(2)=E*s′(2)/s*A′(2)/A, . . . , E′(n)=E*s′(n)/s*A′(n)/A with respect to pulses; hence, E′(1), E′(2), . . . , E′(n)≦E, and E′(1+2+ . . . +n)≧E.

### (1) EXAMPLE A

FIG. 1 shows experimental results with regard to breakdown ratios of fuses in comparison with numbers of pulses causing fuse breakdown, each of which breaks down with “n” pulses realized by dividing the time length by “n”. FIG. 1 shows that as the time length of each pulse becomes short, the number of pulses causing breakdown increases; however, it is possible to cause breakdown with a prescribed number of pulses each having a reduced time length. That is, it proves that each fuse completely breaks down with multiple pulses applied thereto.

Through further analysis on the experimental results shown in FIG. 1, it is acknowledged that any types of fuses each completely break down with a single pulse whose time length is set to 1200 ns having energy E(1200).

A single pulse whose time length is 860 ns applies a fuse with energy E(860)=E(1200)*860/1200, approximately, E(860)=0.717*E(1200). This indicates that the sum of two pulses each having energy E(860) may meet the relationship E′(1+2)≧E. In actuality, approximately 80% of fuses each break down with a single pulse having energy E(860). FIG. 1 shows that within the remaining 20% of fuses, only 10% of fuses each break down with two pulses, and only 8% of fuses each break down with three pulses.

The aforementioned phenomenon occurs due to various manufacturing factors such as dimensions and thickness of fuses, shapes and sizes of grains, variations of side wall shapes in etching, thickness and temperature of insulating films surrounding fuses, positions of chips on wafers, positions of wafers in lots, differences of dates for processing lots, differences of processing devices, and the like. This causes dispersions of manufacturing factors regarding fuses in terms of breakability.

It is presumed that the minimum energy of a pulse causing breakdown may be set to E(860) in an ideal condition; however, due to dispersions of manufacturing factors of fuses in terms of breakability, the minimum required energy for reliably causing breakdown may be set to E(1200).

Experiments have been performed in order to determine the timings of applying pulses to fuses, wherein each pulse is applied to each fuse with a prescribed time interval ranging from several seconds to several tens of seconds, which secures that each fuse reliably cools down after it is heated with a previously applied pulse.

If pulses are consecutively applied to each fuse before its heat is dissipated, heat is accumulated in each fuse due to consecutively applied pulses, so that each fuse breaks down with ease. To avoid such an error resulting, experiments have been performed such that the time interval between a pulse (m−1) and a pulse m is arbitrarily set up, where 2≦m≦n.

According to the distribution of breakdown ratios shown in FIG. 1, it is acknowledged that variations of fuses can be found in a line drawn with respect to pulses each having a relatively short time length realizing energy E(600). FIG. 1 shows that the line regarding pulses having energy E(600), which correspond to a half of the time length of each pulse having energy E(1200), indicates a highest percentage, i.e., 70% or less, at “2” (see the horizontal axis of FIG. 1) among five lines drawn in FIG. 1. This indicates that the aforementioned relationship of E′(1+2)≧E is established. It seems that the number of fuses, each of which breaks down with two pulses having energy E(600), becomes the highest. It is presumed that if no variations occur in dimensions and manufacturing factors, all fuses may each break down with two pulses having energy E(600).

The line regarding energy E(480) of pulses, each having a shorter time length, is broad in distribution, wherein no fuse remains without breaking down. This guarantees that all fuses each reliably break down by increasing the number of pulses applied thereto. The energy E(480) is lower than the energy E(1200) by a factor 0.4 (=480/1200), a reciprocal number of which is 2.5. That is, upon the application of three pulses having energy E(480), it is possible to establish the aforementioned relationship of E′(1+2+ . . . +n)≧E; in other words, it is presumed that each fuse completely breaks down with three pulses consecutively applied thereto.

FIG. 1 shows that a peak of the distribution regarding the breakdown ratio appears at “7” in the horizontal axis, indicating seven pulses consecutively applied to each fuse. This number quite differs from the presumed number, i.e., “3”, because each pulse does not have a completely rectangular waveform due to delay of the leading edge thereof, which may be caused by conductance and inductance included in power circuitry, test circuitry, internal circuitry of LSI devices, wirings, and the like.

In FIG. 14, a curve C1 represents variations of the potential of a pulse causing fuse breakdown, and a curve C2 represents variations of the potential of a fuse that breaks down with the pulse applied thereto.

The curve C1 has substantially a rectangular waveform in which the potential of a pulse rapidly increases to reach a prescribed constant level at a leading edge and then suddenly decreases at a trailing edge. It shows that the leading edge of a pulse may become dull. In actuality, the leading edge of a pulse becomes further dull due to a small capacitance included in the circuitry used for the purpose of noise elimination.

The curve C2 shows that a current is forced to flow through a fuse at the leading edge of a pulse so as to cause a rapid decrease of the potential; then, the potential remains constant for a while; thereafter, the potential suddenly drops to 0 [V] when the fuse breaks down; thereafter, the potential remains at substantially zero.

Due to the dull leading edge of a pulse causing fuse breakdown, the pulse whose time length is set to 480 ns or 250 ns must decrease in potential before the breakdown potential remains constant for a while. The experimental results shown in FIG. 1 are produced in light of the aforementioned disadvantage in which a current flowing through a fuse reaches the constant breakdown potential.

The aforementioned prediction indicates that each fuse may completely break down with three pulses having energy E(480) based on the relationship of E′(1+2+ . . . +n)≧E. However, experimental results of FIG. 1 quite differ from the prediction, wherein a peak appears at “7” in the horizontal axis with respect to the line regarding E(480).

This may show that each fuse completely breaks down with multiple pulses each having 1/7 of the energy E(1200); in other words, each fuse completely breaks down with seven pulses having energy E(480).

Each of pulses whose time lengths are set to 250 ns has energy E(250), which is reduced compared with the energy (1200) by a factor 0.21=250/1200, a reciprocate number of which is 4.8. This indicates that each fuse completely breaks down with five pulses having the energy E(250). However, FIG. 1 shows that a peak in the distribution of breakdown ratios appears at “15” in the horizontal axis with respect to a line regarding E(250).

It can be assumed based on the experimental results shown in FIG. 1 that each pulse having the energy E(250) may actually have 1/15 of the energy E(1200). That is, each fuse completely breaks down with multiple pulses each having 1/15 of the energy E(1200); in other words, each fuse completely breaks down with fifteen pulses having the energy E(250).

### (2) EXAMPLE B

The aforementioned results may indicate that the method (C), in which the current or voltage is divided by “n”, works well with regard to fuse breakdown. As described above, the energy of a pulse applied to a fuse is reduced by dividing the overall time length, and it is also reduced by dividing the current or voltage.

The minimum required energy reliably causing breakdown is set to E(1200). This may indicate that each pulse having the energy E(480) may have 1/2.5 of the energy E(1200) to be applied to each fuse. The experimental results of FIG. 1 show that each pulse of energy E(480) actually has 1/7 of the energy E(1200) because it is weakened due to a decrease of current or voltage; hence, each fuse completely breaks down with multiple pulses each having low energy. Similarly, it is calculated that each pulse having the energy E(250) may have 1/4.8 of the energy E(1200); in actuality, however, each pulse of energy E(250) has 1/15 of the energy E(1200) because it is weakened due to a decrease of current or voltage; hence, each fuse completely breaks down with multiple pulses each having very low energy.

Incidentally, pulse waveform can be arbitrarily selected; hence, it is possible to use a rectangular waveform, a sine waveform, and an alternating waveform of two phases or three phases, for example.

### (3) EXAMPLE C

FIG. 15, which substantially matches FIG. 3, shows the relationships between breakdown ratios of fuses and breakdown times with respect to various current values regarding pulses applied to fuses, wherein the breakdown time is the product of the pulse width and the number of pulses. According to the line drawn with respect to the current of 70 mA, approximately 90% of fuses each break down with a single pulse; and the remaining 10% of fuses each break down with two pulses. FIG. 3 clearly shows that all fuses completely break down even though the breakdown time becomes longer as the current becomes smaller from 60 mA to 50 mA to 40 mA. Energy of each pulse can be reduced by reducing the current (or voltage because of the relationship of V=A*R, in which fuse resistance R is constant); hence, it is possible to arbitrarily set the number of pulses consecutively applied to each fuse.

Based on experimental results shown in FIG. 15, complete fuse breakdown occurs with 834 pulses, each of which has a pulse width of 1200 ns, in light of breakdown time of 1000 ms and breakdown current of 40 mA. In light of the longest breakdown time of 10000 ms in FIG. 15, complete fuse breakdown occurs with 40000 pulses, each of which has a pulse width of 250 ns.

The number of pulses allowing fuse breakdown must be two or more and is not limited; however, FIG. 15 may show that the number of pulses ranges from “1” to “40000”.

In accordance with the aforementioned relationships regarding the sum of energy of pulses, it is necessary to establish the relationship of E′(1), E′(2), . . . , E′(n)≦E; however, it is not always necessary to set each of E′(1), E′(2), . . . , and E′(n) to be substantially equal to E/n. In short, the aforementioned experimental results show that each of n pulses does not necessarily have the same energy.

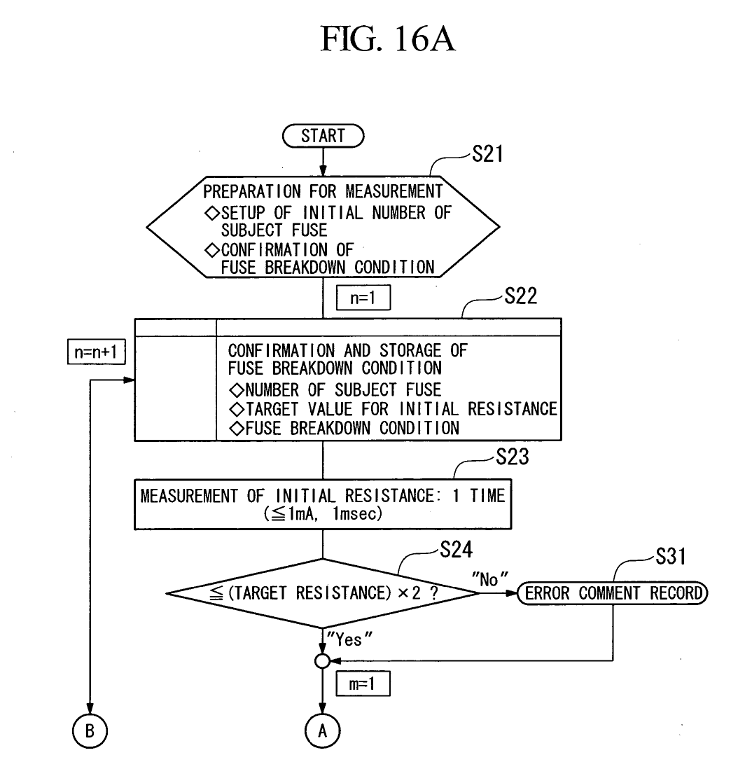

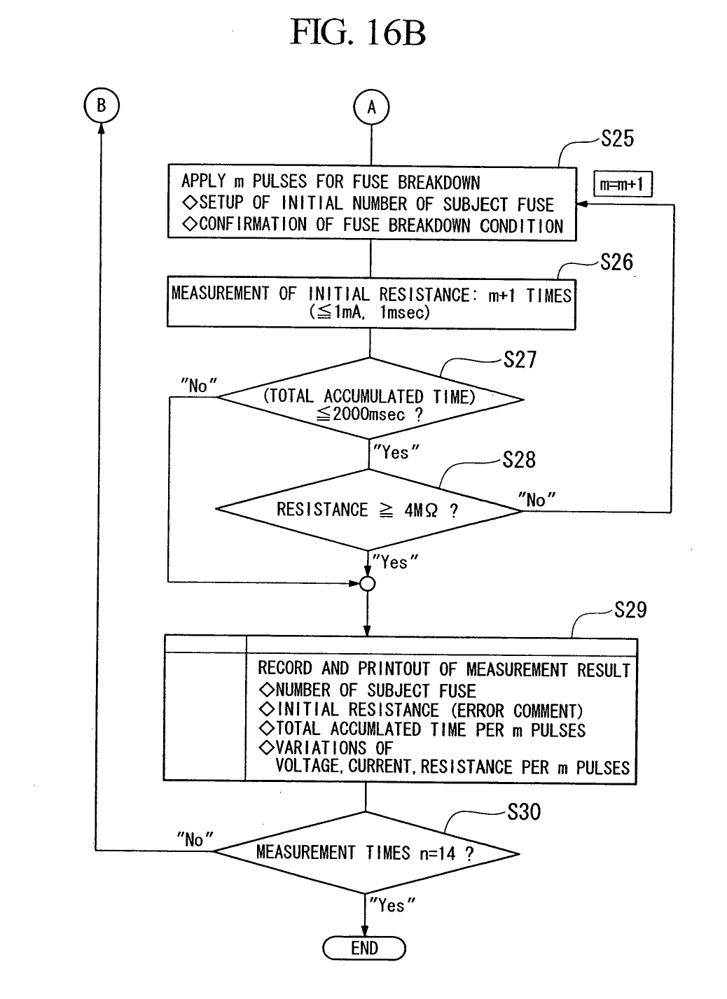

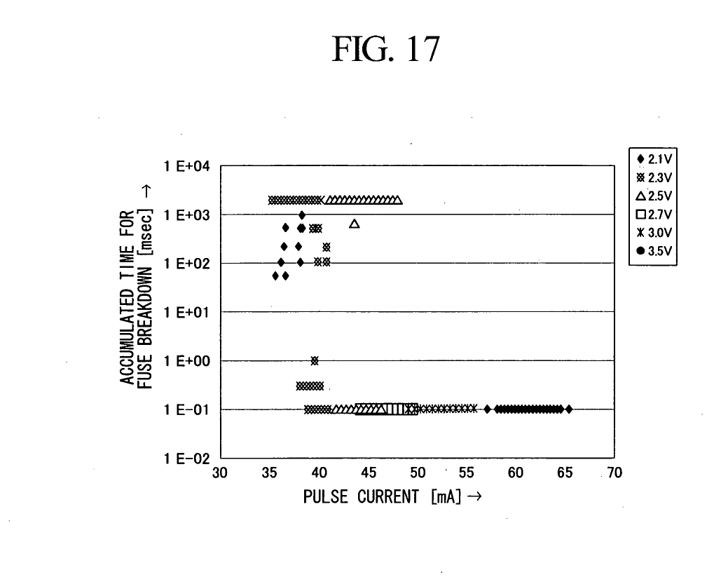

Next, a fuse breakdown method according to the present embodiment will be described with reference to a flowchart shown in FIGS. 16A and 16B, in which pulses are consecutively applied to a subject fuse with regard to prescribed breakdown times T, i.e., T(1)=0.10 ms, T(2)=0.15 ms, T(3)=0.25 ms, T(4)=0.50 ms, T(5)=11.0 ms, T(6)=3.0 ms, T(7)=5.0 ms, T(8)=10 ms, T(9)=30 ms, T(10)=5.0 ms, T(11)=100 ms, T(12)=3.0 ms, T(13)=500 ms, and T(14)=1000 ms.

The fuse breakdown method of the present embodiment is designed to change pulse widths in a series manner. That is, breakdown conditions of a subject fuse are set up in step S41; they are confirmed and stored in memory in step S22; an initial resistance of the subject fuse is measured in step S43; then, pulses are repeatedly applied to the subject fuse while measuring its resistance until breakdown (see steps S44 to S50). Results produced by the fuse breakdown method are shown in FIG. 17.

Even when pulse widths are changed in a series manner, it is confirmed from FIG. 17 that fuses reliably break down with multiple pulses. With respect to the pulse current of 45 mA or more, most fuses each break down with pulses within a short time of 0.1 ms or less; hence, it may be unnecessary to increase pulse widths in a series manner. In contrast, the aforementioned method in which pulse widths are increased in a series manner adequately works to realize fuse breakdown with respect to smaller pulse currents.

In short, with respect to a relatively great number “n” for dividing pulses, FIG. 15 shows that 40000 pulses of 250 ns are needed to realize the accumulated breakdown time of 10000 ms, and the accumulated breakdown time may be further increased to 20000 ms by use of pulses of 250 ns each emitted per cycle of 500 ns, for example. In other words, time intervals between pulses can be reduced by increasing pulse widths in a series manner. When each time interval is set to 250 ns, the accumulated time using sixteen pulses is 10000 ms; and this indicates that the total time is calculated as 10000+(0.250*16)=14000 ms; hence, it is possible to save 6000 ms in total.

The aforementioned method in which the next pulse width is increased compared with the previous pulse width within pulses consecutively applied to the subject fuse has advantages as follows:

Generally speaking, fuse resistance tends to increase over time due to heat caused by pulses. For this reason, due to the increase of fuse resistance, electric power per each pulse tends to decrease as the number of pulses increases in the prescribed condition in which pulses are produced using the constant voltage (e.g., Vdd=5.0V).

A constant current source may be advantageous in that, because of the constant current flowing through the subject fuse, energy per each pulse may not decrease irrespective of the increase of fuse resistance. However, it is possible to reliably cause fuse breakdown by adopting a method in which pulse widths are sequentially increased in response to the increase of the fuse resistance so as to secure constant energy per each pulse.

For example, pulse widths (each denoted by Tp) are sequentially and uniformly increased by factors of 2, 2.5, 4, and 5; hence, Tp=A*n (where A denotes an arbitrarily selected constant). Factors can be freely determined. For example, pulse widths are sequentially increased in an exponential manner; hence, Tp=A*n^{x} (where x denotes an arbitrarily selected constant such as 2 and 2.5). Alternatively, pulse widths are sequentially increased in digits; hence, Tp=10ⁿ, Tp=Aⁿ, or Tp=n*Aⁿ (where n denotes an integer arbitrarily selected).

In addition, a time interval Tint between consecutive pulses can be fixed constant; or Tint=B (where B denotes an arbitrarily selected constant). Furthermore, the time interval Tint can be set identical to the pulse width Tp; hence, Tint=Tp. Alternatively, the time interval Tint can be changed in response to the pulse width Tp as described above.

The relationship between the pulse width Tp and the time interval Tint can be determined in accordance with Table 1, which is described before in conjunction with the first embodiment.

Next, fuse breakdown circuits using pulses will be described in detail.

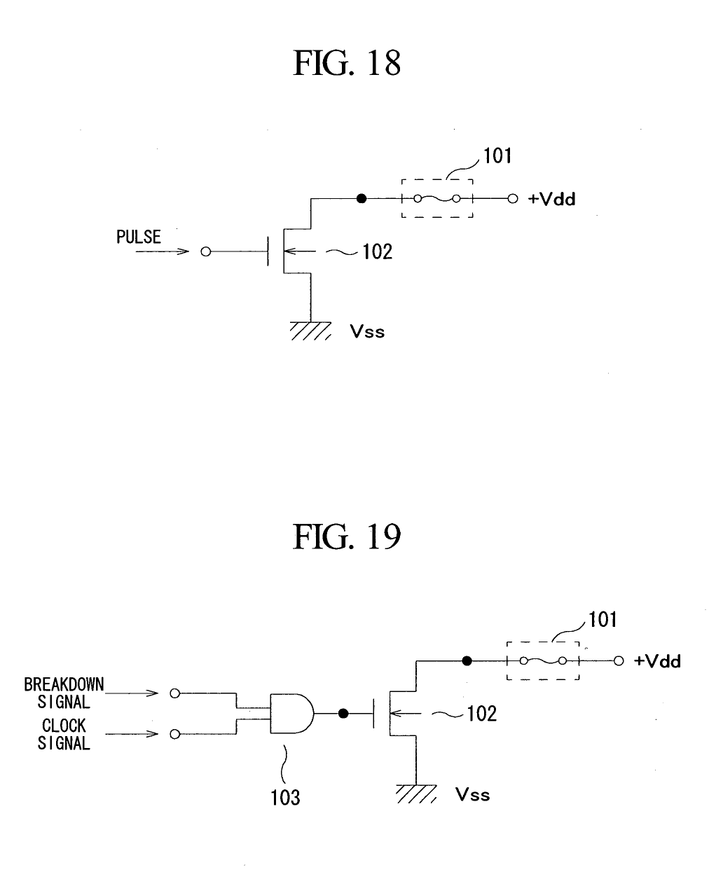

FIG. 18 shows a first example of a fuse breakdown circuit, in which a breakdown signal having pulses is continuously applied to the gate of a transistor 102 until the occurrence of fuse breakdown, so that the transistor 102 turns on so as to make pulses flow through a fuse 101 by way of the drain thereof. Pulses consecutively flow through the fuse 101 to cause breakdown.

The aforementioned breakdown signal is generated using a pulse generator (not shown), which generates pulses having prescribed widths with prescribed time intervals therebetween and transmits them via an AND circuit, for example.

According to the aforementioned equation (1), the fuse current Ifuse depends upon the fuse resistance Rfuse, on-resistance Ron, and drive voltage Vdd. In addition, the fuse current Ifuse is defined in the aforementioned equation (3), which indicates that as the driving ability of the transistor 102 becomes high, the on-resistance Ron decreases. That is, in order to increase the fuse current Ifuse, it is necessary to decrease the on-resistance Ron, which is however determined in advance in the design stage of the transistor 102 and depends upon the gate size and gate width.

Once fuse breakdown occurs, the transistor 102 cannot make the drain current flow through the fuse 101 irrespective of the breakdown signal applied thereto.

The fuse breakdown circuit of FIG. 18 contains a single fuse 101; however, it is possible to provide plural fuses so as to form a fuse array. In this case, a single transistor can be arranged for plural fuses. Alternatively, plural transistors can be arranged for plural fuses respectively, wherein their gates receive selection signals so as to realize the selection of the fuses.

The transistor 102 is not necessarily configured as a MOSFET. That is, plural transistors can be used to increase the breakdown current. In addition, the transistor 102 can be configured as a CMOS transistor. Alternatively, a latch circuit can be introduced to produce plural breakdown currents. Of course, it is possible to use a bipolar transistor having a high current driveability.

A pulse generator (not shown) can be introduced to generate pulses applied to the fuse 101 in synchronization with system clock signals. Herein, the clock frequency can be increased or decreased by use of a frequency divider. In addition, a delay circuit can be additionally introduced to adjust the synchronization in timing.

In short, it is possible to use any types of electric circuits, each of which is capable of applying consecutive pulses to the fuse 101. In addition, it is possible to use a breakdown detection circuit for detecting breakdown and non-breakdown states with respect to the fuse 101 or a circuit for detecting the serial number of the lastly applied pulse realizing breakdown of the fuse 101. Hence, the fuse breakdown circuit can be modified to feed back the output signal of the breakdown detection circuit so as to stop applying pulses when the breakdown state is detected. This function can be realized in the form of programs.

FIG. 19 shows a second example of a fuse breakdown circuit, which includes an AND circuit 103 having two input terminals in addition to the fuse 101 and the transistor 102. The output terminal of the AND circuit 163 is connected to the gate of the transistor 102.

The fuse breakdown circuit of FIG. 19 allows a clock signal (including pulses) to be continuously applied to the gate of the transistor 102 during an ON period (or a high-level period) of a breakdown signal; hence, pulses are correspondingly applied to the fuse 101 to break down.

For example, it is possible to introduce a breakdown detection circuit for detecting breakdown and non-breakdown states of the fuse 101 or a circuit for detecting the serial number of the lastly applied pulse realizing breakdown. The output signal of the aforementioned circuit is fed back as the breakdown signal whose level becomes high until the fuse breakdown and then becomes low after the fuse breakdown. This allows pulses to be consecutively applied to the fuse 101 until the breakdown.

The AND circuit 103 can be replaced with logic circuits or combinations of logic circuits such as inverters, NAND circuits, OR circuits, and NOR circuits so as to modify pulses applied to the gate of the transistor 102. In addition, it is possible to introduce a programmable circuit that produces various types of breakdown signals, thus applying pulses to the fuse 101 in complex patterns.

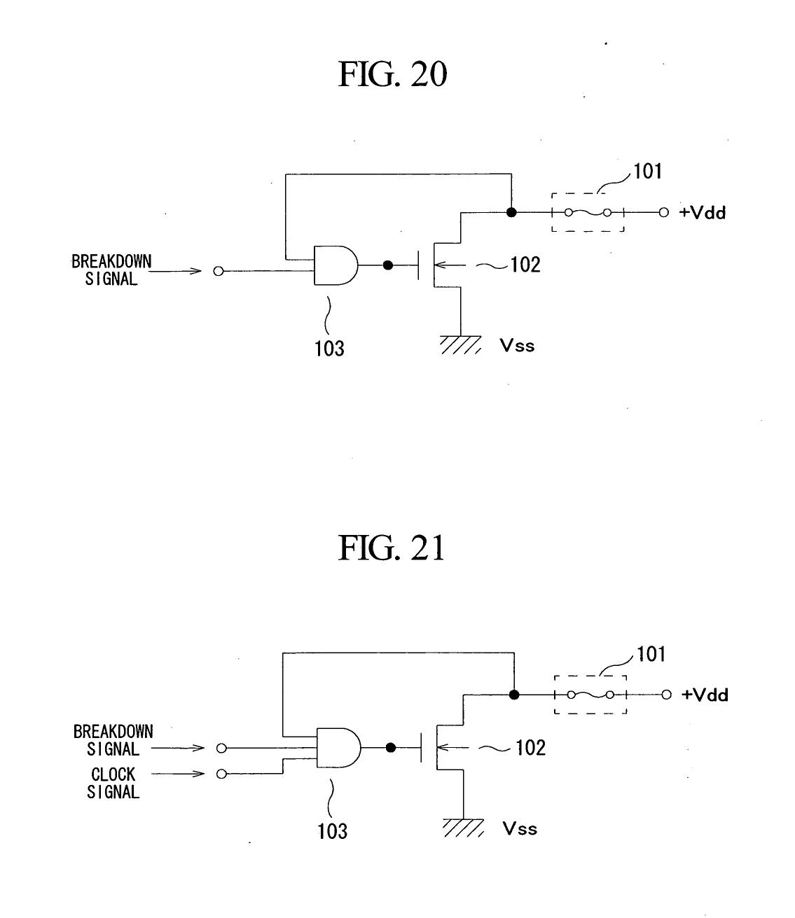

FIG. 20 shows a third example of a fuse breakdown circuit, which is configured similar to the fuse breakdown circuit of FIG. 19, wherein the first input terminal of the AND circuit 103 receives a breakdown signal, and the drain current of the transistor 102 is fed back to the second input terminal of the AND circuit 103, and the output signal of the AND circuit 103 is applied to the gate of the transistor 102. It is possible to introduce a pulse generator (not shown) for generating pulses as the breakdown signal input to the AND circuit 103.

In the above, the potential at a connection point between the fuse 101 and the drain of the transistor 102 becomes high until the fuse 101 breaks down. During such a high-level period, pulses included in the breakdown signal are consecutively applied to the gate of the transistor 102 via the AND circuit 103; hence, the corresponding pulses are repeatedly applied to the fuse 101 from the drain of the transistor 102. When the fuse 101 breaks down, the potential at the connection point between the fuse 101 and the drain of the transistor 102 becomes low. Such a low potential is fed back to the second input terminal of the AND circuit 103. This makes the output signal of the AND circuit 103 low irrespective of the breakdown signal; hence, the gate of the transistor 102 is compulsively set to be low.

The fuse breakdown circuit of FIG. 20 is advantageous because it does not need the breakdown detection circuit for detecting breakdown and non-breakdown states of the fuse 101. That is, the fuse breakdown circuit can be simplified in configuration; hence, it is possible to reduce the overall chip size. In addition, the transistor 102 is not required to perform complex operations in which it is turned on only in the non-breakdown state of the fuse 101 and is not necessarily turned on in the breakdown state of the fuse 101. This eliminates unnecessary power consumption for charging a MOSFET having a large gate area as the transistor 102.

The fuse breakdown circuit of FIG. 20 is designed such that the potential, which becomes high and low in the non-breakdown and breakdown states, is directly fed back to the second input terminal of the AND circuit 103. It is possible to additionally introduce a stabilization circuit for stabilizing the potential or a potential detection circuit for detecting the potential, via which the potential is fed back to the AND circuit 103. In addition, it is possible to feed back the potential to the pulse generator for generating pulses forming the breakdown signal; hence, the breakdown signal is stopped in response to the low potential, for example.

In the above, the AND circuit 103 can be replaced with logic circuits or combinations of logic circuits such as inverters, NAND circuits, OR circuits, and NOR circuits so as to modify pulses applied to the gate of the transistor. In addition, it is possible to introduce a programmable circuit that produces various types of breakdown signals, thus applying pulses to the fuse 101 in complex patterns.

FIG. 21 shows a fourth example of a fuse breakdown circuit in which the AND circuit 103 having three input terminals is adapted to the gate of the transistor 102.

Similar to the foregoing fuse breakdown circuits, the potential between the fuse 101 and the drain of the transistor 102 remains high until the fuse 1 breaks down. During such a high potential period, the AND circuit 103 supplies pulses to the gate of the transistor 102 based on the breakdown signal and clock signal; hence, the corresponding pulses are repeatedly applied to the fuse 101 from the drain of the transistor 102; thus, the fuse 101 finally breaks down.

When the fuse 101 breaks down, the potential becomes low and is fed back to one input terminal of the AND circuit 103 so that the output signal of the AND circuit 103 supplied to the gate of the transistor 102 is sustained low irrespective of the breakdown signal.

In the above, the AND circuit 103 can be replaced with logic circuits or combinations of logic circuits such as inverters, NAND circuits, OR circuits, and NOR circuits so as to modify pulses applied to the gate of the transistor. In addition, it is possible to introduce a programmable circuit that produces various types of breakdown signals, thus applying pulses to the fuse 101 in complex patterns.

Pulses are not necessarily applied to the fuse 101 in synchronization with the clock signal, which can be replaced with the system clock signal. It is possible to introduce a frequency divider to increase or decrease the clock frequency; or it is possible to introduce a delay circuit for adjusting synchronization in timing. The potential that becomes high and low in response to the non-breakdown and breakdown states is not necessarily directly fed back to the AND circuit 103. That is, it is possible to introduce a stabilization circuit for stabilizing the potential in response to the breakdown and non-breakdown states or a potential detection circuit for detecting the potential, via which the potential is fed back to the AND circuit 103, the operation of which is thus stabilized. Alternatively, the potential can be fed back to the pulse generator for generating pulses forming the breakdown signal, which is thus stopped in the breakdown state.

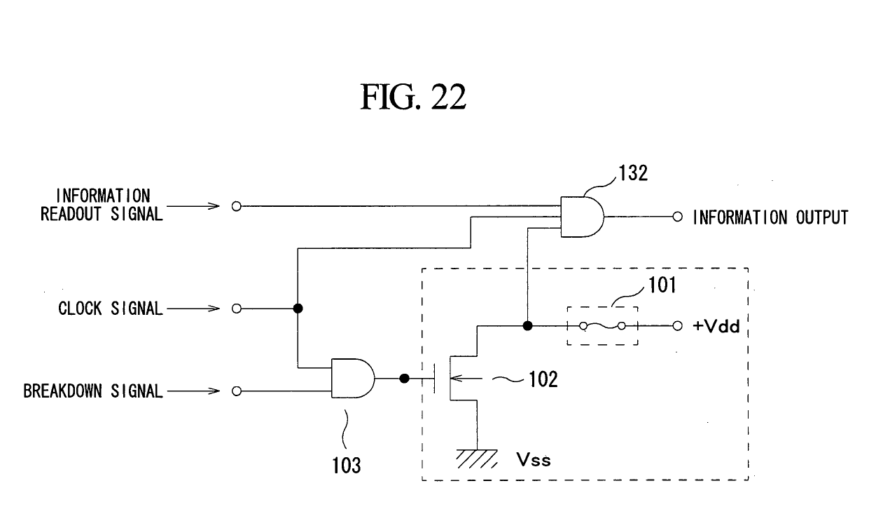

FIG. 22 shows a fifth example of a fuse breakdown circuit, in which the fuse 101 breaks down with multiple pulses and which has a memory function allowing information regarding the breakdown of the fuse 101 to be read out. Compared with the fuse breakdown circuit of FIG. 21, the fuse breakdown circuit of FIG. 22 further includes an AND circuit 132 for inputting an information readout signal, a clock signal, and a potential appearing between the fuse 101 and the drain of the transistor 102.

Before the breakdown of the fuse 101, the fuse 101 is applied with a drive voltage Vdd, so that a high potential is applied to the AND circuit 132. When an information readout signal having a high level is applied to the AND circuit 132, the AND circuit 132 outputs an information signal of a high level in synchronization with the clock signal of a high level.

When the fuse 101 breaks down, a low potential is applied to the AND circuit 132, which in turns outputs an information signal of a low level even when both of the information readout signal and clock signal become high.

Since the fuse breakdown circuit of FIG. 22 allows breakdown information regarding the fuse 101 to be read out, feedback regarding the breakdown state is not necessarily adapted to the AND circuit 103. Of course, it is possible to modify the fuse breakdown circuit of FIG. 22 to include the feedback regarding the breakdown state.

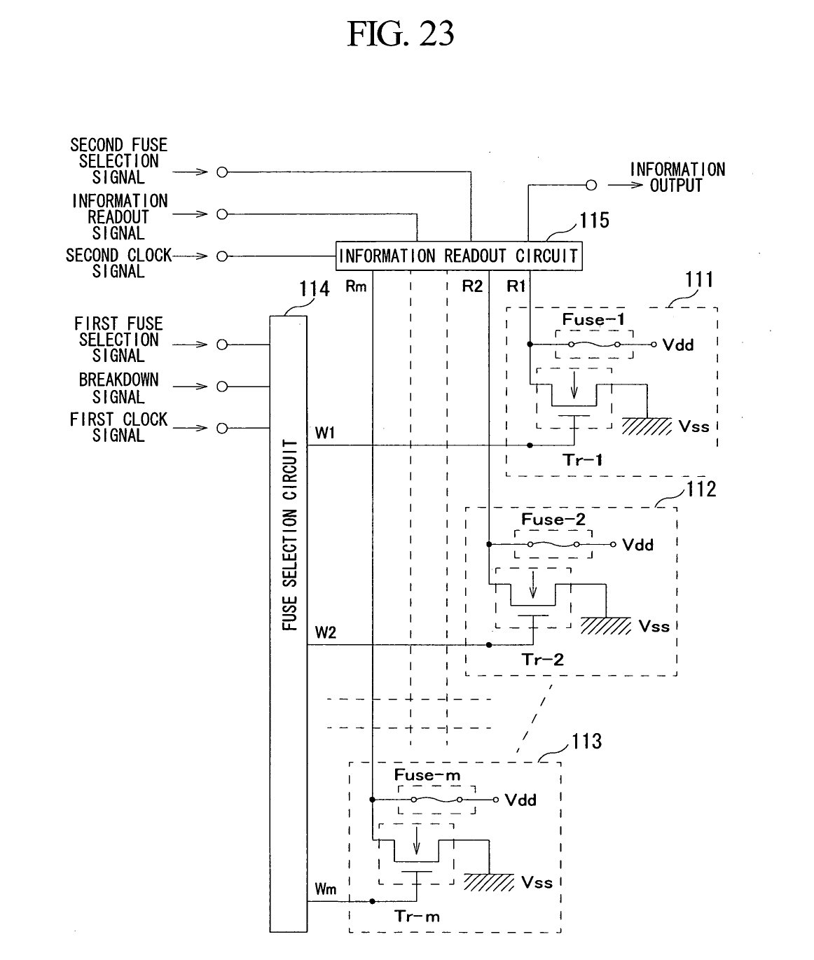

FIG. 23 shows a sixth example of a fuse breakdown circuit in which a fuse array is constituted using “m” fuse circuits (e.g., fuse circuits 111, 112, and 113 including fuses Fuse-1, Fuse-2, and Fuse-m as well as transistors Tr-1, Tr-2, and Tr-m), which are arranged in a matrix form and are adequately selected by means of a fuse selection circuit 114; and an information readout circuit 115 reads breakdown information with regard to each one fuse circuit selected from among the m fuse circuits. Herein, the fuse array includes m fuses denoted by Fuse-1, Fuse-2, . . . , and Fuse-m. This allows n pulses to be simultaneously applied to each of the fuses Fuse-1, Fuse-2, . . . , Fuse-m. If m≦n, it is possible to reduce the load of the power circuitry because of small electric energy required for causing fuse breakdown; hence, the circuit design can be made with ease. The total time for applying pulses to fuses can be reduced to 1/m in comparison with the conventional circuitry in which pluses are independently applied to fuses.

When m=n/5, the amount of electric energy can be reduced to ⅕ of the electric energy required for the simple circuitry because the m fuses simultaneously break down with pulses. Hence, it is possible to reduce the load of the power system, and it is possible to make plural fuses simultaneously break down; therefore, the total time loss can be reduced to 1/m in comparison with the conventional circuitry.

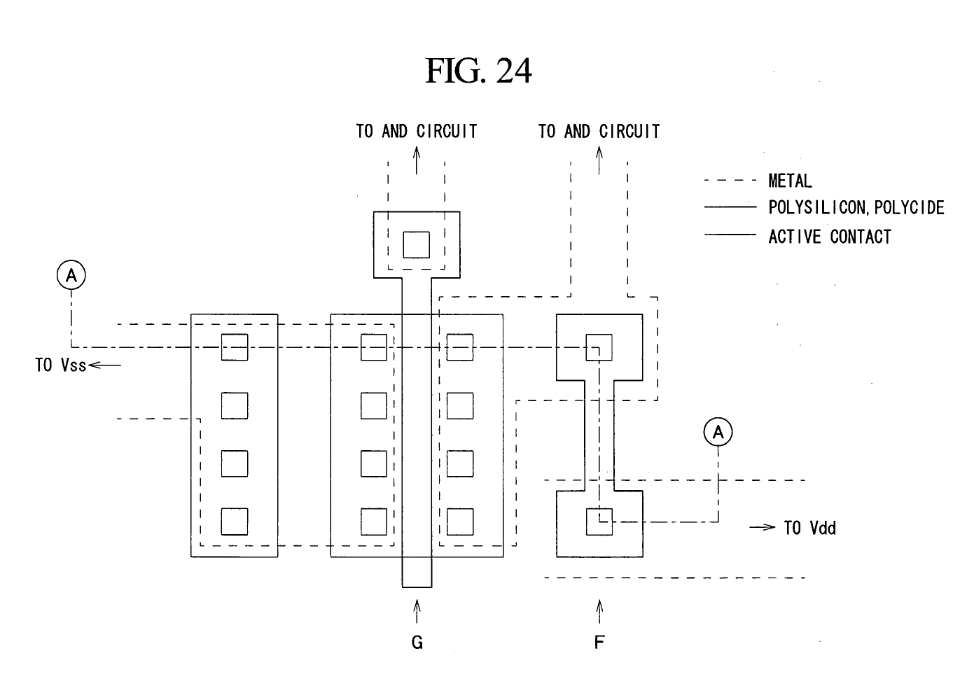

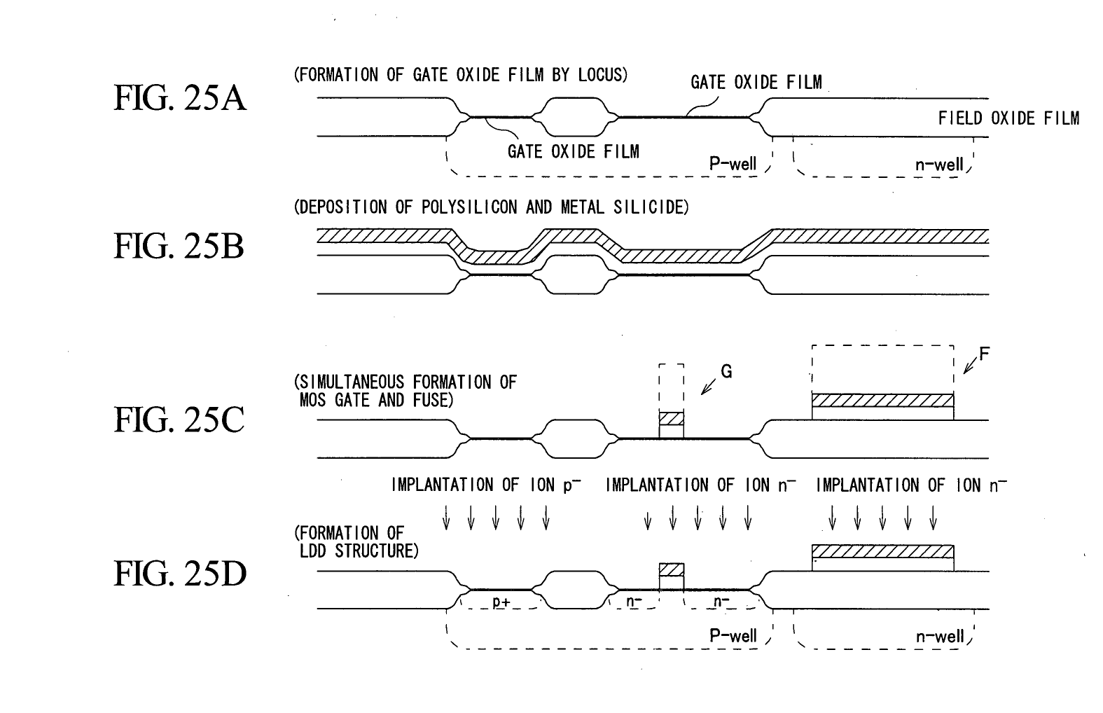

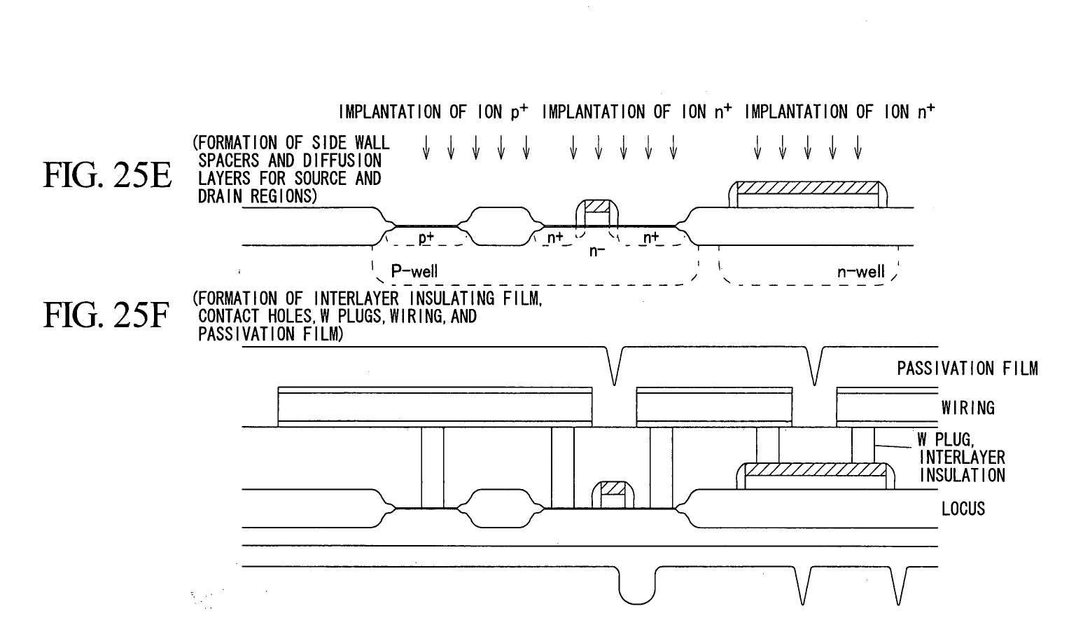

Next, a manufacturing method for a semiconductor device including a fuse and its associated circuit will be described with reference to FIG. 24 and FIGS. 25A-25E.

FIG. 24 is a plan view showing a CMOS integrated circuit including a fuse and its associated circuit. The CMOS integrated circuit includes active regions, a gate electrode G of a MOSFET, a fuse F, contact holes, and wiring, all of which are formed on the surface of a semiconductor substrate.

FIGS. 25A to 25E are cross-sectional views each taken along line A-A in FIG. 24, wherein six steps are sequentially performed to produce the structure of the CMOS integrated circuit of FIG. 24.

As shown in FIG. 25A, the LOCOS method is performed for form field oxidation films and gate oxide films each having the prescribed thickness on the surface of a semiconductor substrate, wherein a p-well is formed in connection with a MOSFET region, and an n-well is formed in connection with a fuse.

For example, a mask (not shown) of 15 nm thickness composed of SiN is formed to cover the overall surface of the semiconductor substrate, which is previously covered with a thermal oxide thin film of 50 nm thickness. The mask is removed from selected areas but still remains in an active region used for the formation of a MOSFET. The mask prevents oxide films from being formed on the surface of the semiconductor substrate. High-temperature thermal oxidation is performed to oxidize the selected areas, from which the mask is removed, so as to form a “thick” field oxide film of 500 nm thickness. When the mask is removed after the formation of the field oxide film, substantially no oxide film is formed in the active region, which is covered with the mask composed of SiN, but a thin oxide film may remain in the active region.

Next, dilute hydrofluoric acid is applied so as to remove the thin oxide film from the active region used for the formation of a MOSFET; then, heat treatment is performed again so as to form a “thin” gate oxide film.

As for the gate oxide film, it is possible to employ a single-layered structure using a silicon oxide film, a double-layered structure using a silicon oxide film and a silicon nitride film by use of prescribed materials having high dielectric constants, or a double-layered structure using a tantalum oxide film and a silicon oxide film, for example. It is possible to employ a three-layered structure in which a silicon nitride film is inserted between two silicon oxide films, wherein the silicon nitride film can be replaced with a silicon oxide nitride film.

The silicon nitride film can be formed by performing thermal nitrification on the previously formed oxide film in nitrogen gas or in a mixed gas of nitrogen gas including NOx. In the case of the three-layered structure in which a silicon nitride film is inserted between two silicon oxide films, the silicon nitride film (or silicon oxide nitride film) is formed using a mixed gas including NOx, tetra-ethyl-ortho-silicate (TEOS), oxygen (O₂), or ozone (O₃) by way of the plasma-excitation CVD method or by way of the CVD method using electron cyclotron resonance (ECR) plasma.

Then, nitride films formed by way of the thermal nitrification and CVD method are subjected to thermal oxidation in the oxide atmosphere, thus producing the three-layered structure in which a silicon nitride film is inserted into two silicon oxide films. Incidentally, it is possible to arbitrarily select materials and thickness for the formation of gate insulating films having high dielectric constants.

As shown in FIG. 25A, it is necessary to form in advance a well whose conduction type is opposite to the conduction type of the semiconductor substrate with respect to the formation of the fuse F; for example, an n-well is formed in a p-type semiconductor substrate. Due to the formation of an n-well, even when heating of the fuse F to break down causes damage to the semiconductor substrate, it is possible to prevent unwanted leakage currents from flowing in the semiconductor substrate. In addition, the fuse F and the field oxidation film may serve as capacitive dielectric films, which in turn form very small capacitance with the semiconductor substrate. Due to the formation of an n-well, it is possible to avoid the unwanted movement of charges toward the semiconductor substrate below the fuse F. On the contrary, a p-well effectively works with respect to an n-type semiconductor substrate.

FIG. 25A shows the formation of an n-channel MOSFET in the active region. For the sake of simplification, FIG. 25A does not show the formation of a p-channel MOSFET. Of course, the manufacturing method of the present embodiment can be easily applied to the formation of a p-channel MOSFET or the formation of other types of complementary MOSFETs (or CMOS circuits).

Both of an n-channel MOSFET and a p-channel MOSFET can be included in the configuration of the CMOS circuit, in which wells having two conduction types are formed in advance before the formation of field oxide films on the semiconductor substrate. In the case of a p-type silicon substrate, for example, an n-well is formed with respect to the formation of a p-channel MOSFET.

The gate electrodes of the n-channel MOSFET and p-channel MOSFET can be formed by way of the same process before poly-cide etching. In order to individually form MOSFETs of two conduction types, it is necessary to use different types of ion impurities with respect to the LDD formation regarding low density regions and with respect to the ion implantation regarding the formation of high density regions for sources and drains as well.

In order to realize a desired threshold voltage, it is possible to introduce impurities of prescribed density into channel regions after the active region is defined in the first step shown in FIG. 25A. Alternatively, it is possible to introduce appropriate impurities into a prescribed region corresponding to the gate electrode of the n-channel MOSFET or the gate electrode of the p-channel MOSFET, thus changing the work function with respect to the gate electrode. Ion implantation is generally adapted to realize the introduction of the aforementioned impurities.

As shown in FIG. 25B, after the formation of a first polysilicon layer, it is possible to introduce appropriate impurities into the prescribed region (corresponding to the gate electrode of the n-channel MOSFET or the gate electrode of the p-channel MOSFET).

In the above, field oxide films are formed on the silicon substrate by way of the LOCOS method, which can be changed to another isolation method such as the STI (shallow trench isolation) method with respect to the formation of the active region. In this case, field oxide films can be formed by way of various methods adapted to the formation of insulating films other than the thermal oxidation method.

The semiconductor substrate is not necessarily limited to the silicon substrate; hence, it can be formed using IV-IV compounds including SiGe and GaAs. Active elements are not necessarily limited to MOSFETs; hence, it is possible to use active elements of HEMT types, bipolar types, and SIT types, for example.

FIG. 25B shows a polysilicon deposition process in which a polysilicon layer is deposited on the overall surface of the semiconductor substrate by way of the CVD method. The polysilicon layer is formed using a mixed gas of SiH₄ (20%) and N₂ (80%) at a flow velocity of 200 sccm, under a pressure of 30 Pa, and at a temperature of 600° C. When the temperature of the semiconductor substrate is greatly reduced below the aforementioned temperature, amorphous silicon grows instead of polysilicon. However, by heating the semiconductor substrate, amorphous silicon is crystallized and is converted into polysilicon. Hence, it is possible to selectively use either amorphous silicon or polysilicon.

The thickness of the polysilicon layer ranges from 20 nm to 1000 nm, preferably, from 80 nm to 200 nm.

Subsequently, an impurities diffusion process is performed so as to uniformly diffuse phosphorus on the polysilicon layer with a prescribed impurities density of about 1020 cm⁻³ at a prescribed diffusion temperature ranging from 800° C. to 900° C. The impurities diffusion process may unexpectedly form a high-density phosphorus-doped silicon oxide film, which is removed using buffered hydrofluoric acid, thus realizing cleaning of the surface of the polysilicon layer.

Next, a high-melting-point metal silicide layer, a metal layer, or a metal alloy layer is deposited on the polysilicon layer.

In the deposition process of the high-melting-point metal silicide, for example, a high-melting-point metal silicide such as tungsten silicide (WSix) is selected and is deposited so as to cover the polysilicon layer and its associated portion (e.g., a dielectric film) in a conformal manner by way of the sputtering or the CVD method.

Sputtering is performed using WSix target, the composition of which can be arbitrarily determined. According to the property of silicide, “x” is set within a range of 1.5≦x≦3.5, preferably, within a range of 2.0≦x≦3.0. For example, in the case of WSi2.7 (i.e., x=2.7), sputtering is performed using a DC magnetron sputtering device under prescribed deposition conditions, i.e., pressure of 3 mTorr, Ar gas flow of 30 sccm, substrate temperature of 200° C., and power of 1150 W. Thickness of deposition ranges from 25 nm to 500 nm, preferably, from 80 nm to 200 nm.

The CVD method is performed using a mixed gas of tungsten hexafluoride (WF₆) and silane (SiH₄) so as to realize deposition of WSi₂ in accordance with the following chemical formula.
WF₆+2SiH₄→WSi₂+6HF+H₂

The high-melting-point metal silicide layer is formed using MoSix, TiSix, and TaSix. Herein, a sputtering target is formed using a metal silicide whose composition is arbitrarily determined. A high-melting-point metal silicide can be replaced with a prescribed metal or a prescribed metal alloy by use of high-melting-point metals such as Mo, Ti, Ta, and W and by use of transition metals such as Co, Cr, Hf, Ir, Nb, Pt, Zr, and Ni.

The aforementioned layer can be subjected to heat treatment so as to cause reaction with the polysilicon layer, thus forming a metal silicide by way of the silicide process.

After completion of deposition of the high-melting-point metal silicide layer, heat treatment is performed before the formation of an interlayer insulating film, thus reducing resistances of fuses and polycide gate electrodes including high-melting-point metal silicide. The aforementioned heat treatment prevents the metal silicide and polysilicon layer from unexpectedly separating from each other due to heat treatment subsequently applied to the metal silicide, e.g., due to quenching heat treatment performed after the formation of interlayer insulating films.

The heat treatment can be realized using a diffusion furnace or by way of rapid thermal annealing (RTA) at a prescribed temperature ranging from 800° C. to 1150° C., preferably, from 900° C. to 1000° C. As for the diffusion furnace, the heat treatment is performed in a prescribed time period ranging from 5 minutes to 90 minutes, preferably, from 15 minutes to 30 minutes. As for RTA, the heat treatment is performed in a prescribed time period ranging from 1 second to 120 seconds, preferably, from 5 seconds to 30 seconds. In the present embodiment, RTA is performed for 10 seconds at 1100° C.

Incidentally, the heat treatment is performed after the patterning of gate electrodes or simultaneously with the formation of side spacers.

After completion of the heat treatment, it is possible to form an anti-reflection film, which may be needed for the processing of fine gate electrodes and fuses. Of course, the anti-reflection film is not necessarily required and is therefore not illustrated in the drawings.

Specifically, TiN or TiOxN (where a ratio x set for the oxygen element ranges from 5 atm % to 30 atm %, preferably, from 10 atm % to 15 atm %) is subjected to deposition so as to form an anti-reflection film whose thickness ranges from 10 nm to 100 nm, preferably, from 30 nm to 60 nm. That is, reactive sputtering using Ti target is performed in a sputtering gas (i.e., a mixed gas of Ar, N₂, and O₂) by use of a DC magnetron sputtering device. The anti-reflection film reduces reflection light on gate electrodes and silicide elements on surfaces of fuses. It is possible to perform photolithography. The anti-reflection film can be formed before the aforementioned heat treatment; hence, the anti-reflection film is removed after completion of the processing of fine gate electrodes and fuses, then, the heat treatment is performed.

As shown in FIG. 25C, a part of the dielectric film, which still remains irrespective of the patterning, is used as a mask so as to perform patterning on first and second polysilicon layers and metals (or metal silicide elements), thus forming gate electrodes.

In the above, a photoresist is applied onto the surface of the high-melting-point metal silicide layer; thereafter, the photoresist is subjected to selective exposure and is then removed, thus leaving a prescribed photoresist pattern covering a prescribed area corresponding to the gate electrode G of the MOSFET and the fuse (as well as the wiring M, not shown). The photoresist pattern is used as an etching mask so as to perform polycide etching by use of an ECR plasma etching device (manufactured by Sumitomo Metal Industry Co. in Japan) under the following conditions.

Etching gas: Ci+O₂ gas.

Gas flow: 25 sccm, and 11 sccm.

Pressure: about 2 mTorr.

RF power: 40 W.

RF frequency: 13.56 MHz.

Microwave power: 1400 W.

Microwave frequency: 2.45 GHz.

Electrode temperature: 15° C. to 20° C.

As a result, the high-melting-point metal silicide layer and polysilicon layer, which are not masked by the photoresist pattern, are subjected to selective etching, so that the gate electrode G of the MOSFET, the fuse F, and the wiring M are simultaneously formed.

After polycide and polysilicon etching, the photoresist pattern is removed from the high-melting-point metal silicide layer. As shown in FIG. 25C, a metal silicide layer is formed on the polysilicon layer in the prescribed area covering the gate electrode G, the fuse F, and the wiring M, thus realizing a specific structure providing a polycide layer and a polycide electrode.

Next, as shown in FIG. 25D, the gate electrode G of the MOSFET, which still remains irrespective of the aforementioned patterning, is used as a mask so as to form a diffusion layer having an LDD structure in the active region.

In the active region, the gate electrode G having the polycide layer is used as a mask so as to form an LDD structure in a self-alignment manner by way of n-type ion implantation. FIG. 25D shows the LDD structure for the n-channel MOSFET; of course, the LDD structure can be similarly formed with respect to the p-channel MOSFET. This allows n-type ion and p-type ion to be independently implanted into different regions by using a resist mask in the photolithography.

The p-type ion implantation should not be performed with respect to areas regarding various elements and wiring other than the active region in which the p-channel MOSFET is formed. This is because n-type ion (e.g., phosphorus) is previously doped into the gate electrode G of the MOSFET and the polycide layer of the fuse F so that their sheet resistances may be altered due to the implantation of p-type ion (e.g., boron).

FIG. 25D does not specifically show that n-type ion implantation is performed on the front side of a wafer without using a mask; hence, n-type ion is implanted onto the fuse F. This may reduce the resistance of the fuse F so as to make it easy for the fuse F to break down. The p-type ion implantation is performed using a resist pattern, in which an opening corresponding to the active region used for the formation of the p-channel MOS transistor is formed by way of photolithography, so as not to implant p-type ion into other areas.

As described above, the p-type ion implantation is performed in a limited manner by use of the resist pattern serving as a mask. Hence, the p-type ion implantation is performed with respect to the LDD structure of the p-channel MOSFET in such a way that n-type ion previously implanted thereto is canceled out by p-type ion newly implanted thereto.

Next, as shown in FIG. 25E, high-density diffusion layers are formed with respect to the source and drain regions in such a way that side wall spacers are formed to complete the formation of the LDD structure in a self-alignment manner, then, patterning and ion implantation are performed with respect to the MOSFET in accordance with the aforementioned process shown in FIG. 25D.

The side wall spacers are formed by way of the CVD method realizing deposition of insulating films and the reactive ion etching (RIE). When etching back is performed on CVD-implemented layers realizing the LDD structure in order to form the side wall spacers, the surface of the polysilicon layer realizing resistance may be slightly cut out so as to cause variations of resistance.

The aforementioned drawback can be solved by appropriately selecting the material and thickness of the anti-reflection film, whereby the anti-reflection film can be used as a protection film bearing etching so as to realize desired resistance with high accuracy. The anti-reflection film serving as the protection film can be removed by way of selective etching after the formation of the side wall spacers. The anti-reflection film is not necessarily removed because the thickness thereof is very small compared with the thickness of the silicide layer. Even though the anti-reflection film partially remains without being removed, substantially no problem occurs in the manufacturing process.

In the case of the CMOS circuit configuration, p-type ion implantation is performed to form the high-density diffusion layers for the source and drain regions, wherein it is necessary to prevent p-type ion from being implanted into other areas by way of resist patterning. This is because high-density ion implantation may greatly affect the sheet resistance of the silicide layer.

It is possible to introduce a silicide process using a metal silicide before or after the ion implantation used for the formation of the high-density diffusion layers for the source and drain regions shown in FIG. 25E. In this case, it is possible to introduce a modified silicide process without substantially changing a polycide film forming process shown in FIG. 25D. In addition, it is possible to form a silicide film having reduced thickness on the polycide film; and it is possible to simply perform the normal silicide process realizing polysilicon formation.

When the modified silicide process is adapted to the polycide film forming process shown in FIG. 25D, reactive films composed of prescribed materials such as TiSix and CoSix, which depend on prescribed metals (e.g., Ti, Co, Ni, and TiCo alloy) used in the modified silicide process, are formed on the diffusion layers or the polycide film. Herein, the reactive films may not grow adequately or may be greatly reduced in thickness because of the very small supply of Si from the silicide layer, which is previously formed thereunder. For this reason, the polycide film used for the fuse may cause small variations of the sheet resistance and therefore does not substantially alter the breakdown characteristics of the fuse applied with pulses.

The silicide process is advantageous in that the MOS transistor can be improved in the driving ability thereof due to the reduced sheet resistance of the diffusion layer, thus producing a high energy pulse, which is applied to the fuse, without changing the dimensions thereof.

When the normal silicide process is adapted to the polycide film forming process shown in FIG. 25D so as to realize only the polysilicon formation (without the silicide formation), reactive films composed of silicide materials such as TiSix and CoSix are formed on the diffusion layers and the polycide film. This establishes the polycide structure in which the silicide film is deposited on the polysilicon film, wherein metals formed on the polysilicon film may absorb Si therefrom so as to cause reaction, thus forming a silicide film. For this reason, small variations may occur in the thickness and sheet resistance in the silicide film compared with the silicide film formed by the normal process shown in FIG. 25B.

By adjusting the thickness before reaction and by adjusting the reaction temperature, it is possible to adjust the sheet resistance of the silicide film used for the fuse. Variations of the sheet resistance can be absorbed by adjusting the driving ability of the transistor and by adjusting the pulse energy in response to the fuse resistance.

FIG. 25F shows the formation of an interlayer insulating film, contact holes, W plugs, and metal wirings.

Subsequent to the process of FIG. 25E regarding the formation of side wall spacers and diffusion layers, a known manufacturing process regarding the CMOS integrated circuit is performed to sequentially form the interlayer insulating film, contact holes, W plugs (realized by embedding contact holes), and metal wirings; lastly, a passivation film is formed so as to protect electric circuits formed on the surface of a semiconductor device.

Specifically, prescribed materials such as phosphorus silicate glass (PSG) and boron phosphorus silicate glass (BPSG) are sequentially deposited to cover the MOS transistor and fuse, thus forming the interlayer insulating film whose thickness ranges from 0.6 μm to 0.8 μm. Then, photolithography and dry etching are performed to form contact holes at prescribed positions corresponding to the diffusion layers of the source and drain regions, the gate electrode of the MOS transistor, the fuse, and the polycide wiring (not shown).

An adhesion layer composed of TiN or TiON/Ti is formed to cover the interior portions of the contact holes and the interlayer insulating film by way of the sputtering or CVD method. Specifically, the adhesion layer is formed in such a way that a Ti film whose thickness ranges from 5 nm to 50 nm (preferably, 20 nm) is formed, and then a TiN film whose thickness ranges from 50 nm to 200 nm (preferably, 100 nm) is deposited on the Ti film. The TiN film can be replaced with a TiOxN film (where the value x for the oxygen element ranges from 5 atm % to 30 atm %, preferably, from 10 atm % to 15 atm %).

The deposition of the Ti film is realized by the sputtering performed under the following conditions.

Substrate temperature: 150° C.

Ar flow: 30 sccm.

Pressure: 3 mTorr.

Sputtering power: 1150 W.

It is preferable to use collimate sputtering or long-slow sputtering in the deposition of the Ti film, whereby it is possible to form a Ti film having a sufficiently large thickness in the bottom of a fine contact hole. The CVD method can be applied to form a Ti film having an ideal coating factor.

The adhesion layer is not necessarily composed of the aforementioned materials. That is, it can be composed of a high-melting-point metal alloy such as TiW, a metal silicide, a combination of a metal silicide and a metal nitride such as TiN, and a combination of a high-melting-point metal and its nitride (e.g., boride).

After completion of the formation of the adhesion layer, it is possible to perform high-speed heat treatment (e.g., rapid thermal annealing (RTA)) for a prescribed time ranging from 10 seconds to 60 seconds at a prescribed substrate temperature ranging from 500° C. to 800° C. in a nitrogen atmosphere in order to improve the anti-heat resistance and barrier ability of the adhesion layer.

Then, conduction layers composed of W plugs are formed to cover the interior portions of the contact holes and the adhesion layer by way of the CVD method. The thickness of the conduction layer is determined such that each contact hole is filled with a conduction material. That is, the thickness of the conduction layer is set to a half or more of the diameter of the contact hole filled with the conduction material. For example, when the diameter of the contact hole is about 0.50 μm, the thickness of the conduction layer is set to be 1.2 times to 2.0 times larger than the radius and therefore ranges from 300 nm to 500 nm; preferably, it is set to be 1.4 times to 1.6 times larger than the radius and therefore ranges from 350 nm to 400 nm. As the thickness of the conduction layer is smaller, etching back (and a device therefor) may bear a smaller load.

The conduction material is selected from among prescribed metals having high-evaporation-pressure compounds such as WF₆. For example, tungsten deposition can be realized under the following conditions by way of the CVD method.

Substrate temperature: 450° C.

Gas flow: WF₆/H₂/Ar, and the composition thereof is 40/400/2250 sccm.

Pressure: 10 kPa.

The conduction material is subjected to anisotropic etching back so that the conduction material remains only in the contact holes. Specifically, the anisotropic etching back is realized by way of dry etching, i.e., reactive ion etching (RIE), so that the adhesion layer is exposed from the conduction layer under the following conditions.

Gas flow: SF₆/Ar, the composition thereof is 30-140/40-140 sccm (preferably, 110/90 sccm).

High-frequency power: 450 W.

Pressure: 32 Pa.

The completion of tungsten etching is detected by monitoring the intensity of emitted light F+ (whose wavelength is 704 μm), in other words, by detecting an increase of the intensity of the emitted light F+ whose differential becomes large. The aforementioned etching can be performed until the adhesion layer is removed from the interlayer insulating film, which is thus exposed.

Thereafter, a wiring layer is formed to cover the adhesion layer and the contact holes and W plugs by way of sputtering, the CVD method, or plating. In addition, the wiring layer is heated under vacuum conditions so as to perform reflow processing as necessary.

The wiring layer composed of Al—Si or an Al alloy including Al—S and Cu is subjected to sputtering under the following conditions so as to realize a prescribed thickness ranging from 100 nm to 1000 nm (preferably, 500 nm).

Substrate temperature: 200° C.

Ar flow: 33 sccm.

Pressure: 2 mTorr.

Sputtering power: 9000 W.

After completion of the formation of the wiring layer, the semiconductor substrate is held under vacuum conditions and is heated at a prescribed temperature ranging from 400° C. to 550° C. so as to perform reflow processing. The wiring layer can be composed of Cu or a Cu alloy (e.g., Cu—Cr, Cu—Zr, and Cu—Pd) instead of Al or an Al alloy, wherein the sputtering target is changed to Cu or the Cu alloy. Before the formation of the wiring layer composed of Cu and the like, a conductive barrier layer is formed to directly cover the adhesion layer and the contact holes and W plugs (hereinafter, referred to as contact plugs); then, the wiring layer is formed on the conductive barrier layer, for example.

The barrier layer may block the constituent element (e.g., Al) of the wiring layer from being diffused, thus improving the anti-leak characteristics in joining. The barrier layer may serve as the adhesion layer, which is used for the formation of the wiring layer by way of the CVD method; hence, it is possible to further improve the reliability.

Similar to the adhesion layer, the barrier layer can be formed by sequentially depositing a Ti layer and a TiN layer (or a TiON layer) by way of sputtering. The barrier layer is not necessarily composed of the aforementioned materials; hence, it is possible to use a high-melting-point metal such as TiW, a metal silicide, a combination of a metal silicide and a metal nitride such as TiN, and a combination of a high-melting-point metal such as tantalum and tantalum nitride and a nitride (or a boride).

After completion of the formation of the barrier layer, in order to improve the anti-heat resistance and barrier characteristics of the barrier layer, it is possible to perform high-speed heat treatment (e.g., RTA) for 10 seconds to 60 seconds at a prescribed temperature ranging from 500° C. to 800° C. in a nitrogen atmosphere. Incidentally, it is possible to form a conductive cap layer on the wiring layer irrespective of the formation of the barrier layer. The cap layer can be formed by sequentially depositing a Ti layer of 7 nm thickness and a TiN layer of 40 nm thickness.

The cap layer has various functions in which it stops the light reflection during photolithography, it stops the oxidation of the wiring layer, and it stops the diffusion of the constituent element (e.g., Al) of the wiring layer, for example.

The wiring layer is subjected to patterning by way of photolithography and dry etching and is thus connected to the contact plugs and connection terminals (not shown). Both the barrier layer and the cap layer are subjected to patterning together with the wiring layer, thus forming wiring patterns.

Instead, a damascene method is performed to form via plugs and wiring above fuses; or a dual damascene method is performed to simultaneously form them. The processing regarding contacts and wirings is irrelevant to characteristics of fuses.

Thereafter, a passivation film serving as a surface protection film is formed to cover all the layers described above by way of the CVD method. Specifically, the passivation film whose thickness ranges from 0.8 μm to 1.4 μm, preferably, 1.1 μm, is formed by sequentially depositing an NSG film or a SiO₂ film whose thickness ranges from 50 nm to 200 nm, preferably, 100 nm, and a SiN film or a SiON film whose thickness ranges from 600 nm to 1200 nm, preferably, 1000 nm. Then, a Hall process is performed with respect to pads, which correspond to connection terminals for establishing connection with an external device, and scribing lines defining divisions of chips on the passivation film are formed by way of photolithography and dry etching. Thus, it is possible to completely produce an analog MOS integrated circuit.

As described above, the present embodiment provides a semiconductor device having a polycide structure in which a metal silicide having a prescribed thickness is deposited on a polysilicon layer, which matches the thickness and material of a gate electrode of a MOS transistor.

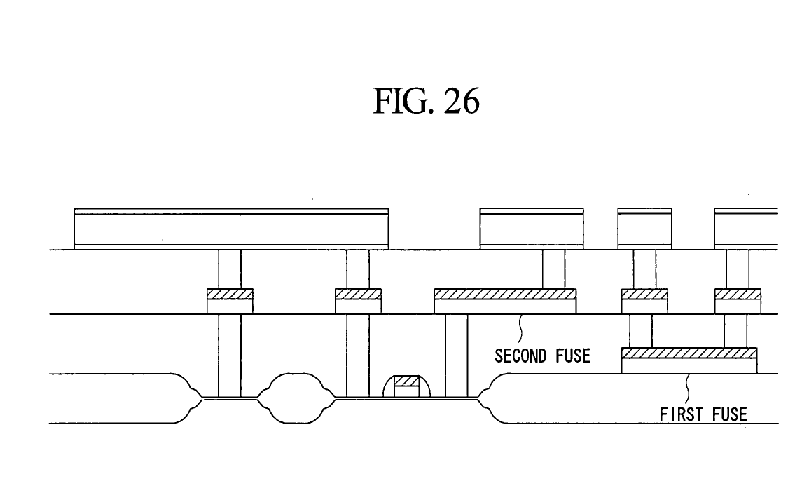

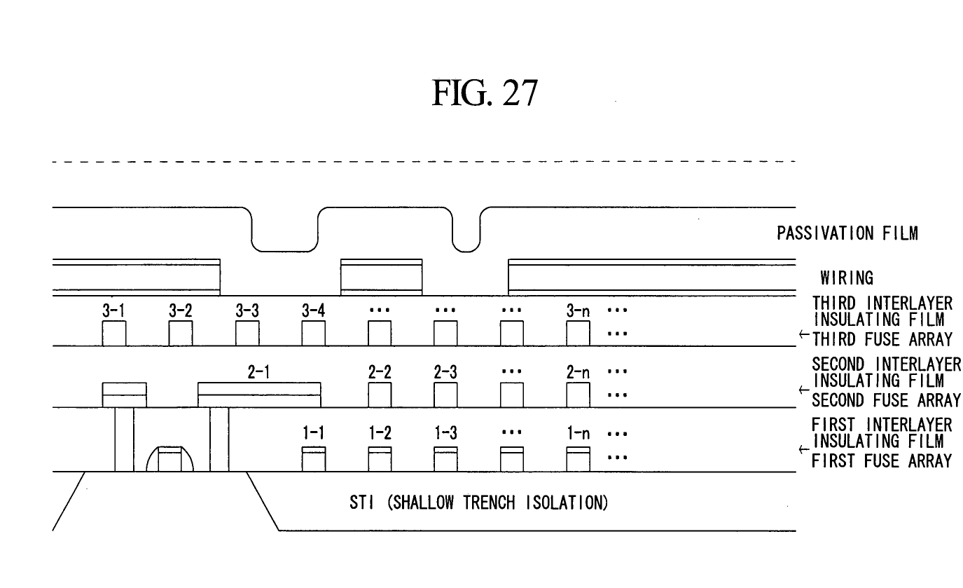

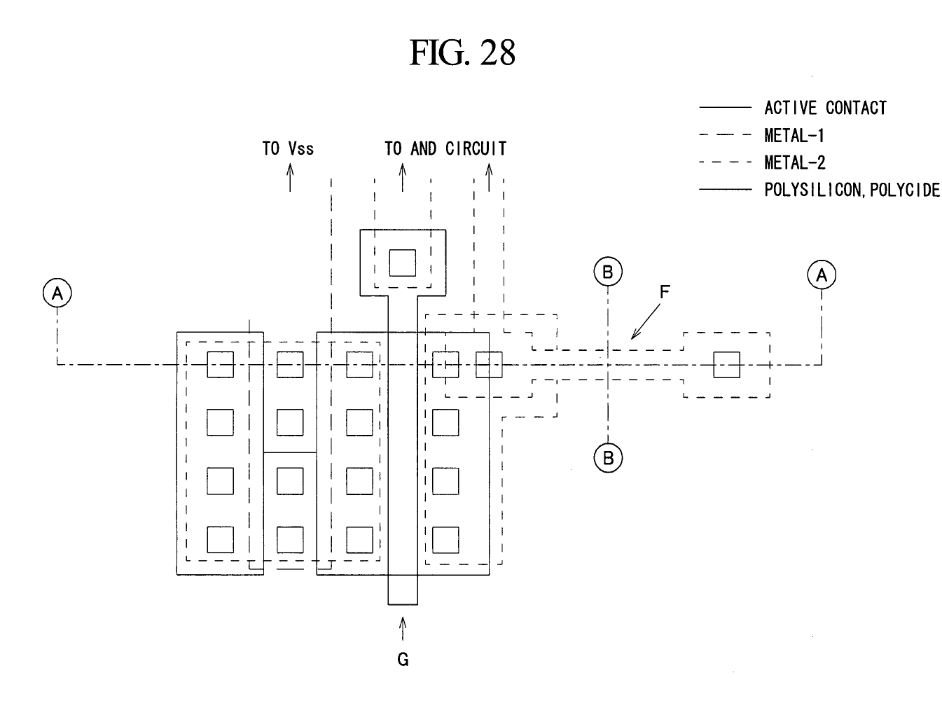

FIG. 26 shows that fuses are each formed using a second polysilicon layer or a second polycide layer having a double-layered structure consisting of a second polysilicon layer and a second metal silicide layer. In this case, the manufacturing method shown in FIGS. 25A to 25F is partially modified so that the heat treatment temperature and impurities implantation are slightly changed in relation to the formation and patterning of the interlayer insulating film.

That is, a second high-melting-point metal silicide film is deposited, then, heat treatment is performed before the formation of a second interlayer insulating film, wherein the range of temperature must be limited in order to reduce resistances of polycide gate electrodes using a high-melting-point metal silicide and resistances of fuses.

The heat treatment can be performed using a diffusion furnace or by way of RTA at a prescribed temperature ranging from 500° C. to 1000° C., preferably, from 700° C. to 950° C. When a diffusion furnace is used, heat treatment is performed in a prescribed time period ranging from 5 minutes to 90 minutes, preferably, from 10 minutes to 30 minutes. Alternatively, RTA is performed in a prescribed time period ranging from 1 second to 120 seconds, preferably, from 5 seconds to 30 seconds. In the following description, RTA is performed for 10 seconds at 850° C.

Since impurities implantation is already performed to form the LDD structure for a MOS transistor, variations may occur in the impurities density distribution due to high-temperature heat treatment or long-time heat treatment. This causes a disadvantage in that desired characteristics cannot be obtained with respect to the MOS transistor. The aforementioned BPSG for the first interlayer insulating film may flow easily at a low temperature; and this may cause unwanted deformation of the surface shape due to heat treatment. Hence, the heat treatment, which is performed after completion of the deposition of the second high-melting-point metal silicide film, needs close attention with respect to the temperature and time.

Because of the aforementioned reasons, it is preferable to employ RTA because the RTA completes the heat treatment within a short time and realizes precise management with regard to the temperature distribution. Of course, the heat treatment can be omitted in order to avoid the unexpected increase of the sheet resistance of the second polycide layer. In addition, it is possible to omit the impurities implantation for use in the formation of the LDD structure and the source and drain regions. In this case, the sheet resistance of polycide may be slightly increased due to the lack of the impurities implantation. This may require some adjustments with regard to the driving ability of transistors, pulse energy, and resistances of fuses, wherein fuses can each break down normally.

As shown in FIG. 26, a first fuse is formed by use of a first polycide film, which is formed simultaneously with the formation of a gate electrode of a MOS transistor; then, a second fuse is formed by use of a second polysilicon layer or a second polycide film formed on the first interlayer insulating film.

It is possible to form a capacitance between the first polycide film (or first polysilicon film) and the second polycide film (or second polysilicon film). When the second fuse is formed using polysilicon only, it is possible to form resistors in the same layer. Incidentally, fuses can be formed using an nth polysilicon layer containing resistance and capacitance, which is formed by way of a known manufacturing process used for various devices such as analog LSI devices and DRAMs, each of which uses plural polysilicon layers. In addition, it is possible to establish a polycide structure in which a silicide layer is formed on an nth polysilicon layer.

In the structure of FIG. 26, the second fuse is directly connected to a lower polysilicon layer via a contact plug formed close to the drain of a MOS transistor. This is not a restriction; hence, the second fuse can be connected to the drain of the MOS transistor via an upper via plug. Herein, a damascene method is used to form the second fuse; and a dual damascene method is performed to simultaneously form the upper via plug and wiring. Of course, the first and second fuses can be directly connected together, or the prescribed terminals thereof can be simply connected together. When the first and second fuses are designed to have different breakdown characteristics, they can be used as a memory into which binary information is written.

FIG. 27 shows a multilayered structure in which fuses are formed using multiple polysilicon layers or multiple polycide layer. This realizes the vertical formation of fuse arrays in which plural fuses are horizontally arrayed by use of plural layers by way of the aforementioned process regarding the formation of fuses in the second polysilicon layer or the second polycide layer shown in FIG. 26. Herein, the aforementioned STI (shallow trench isolation) is implemented so as to realize isolation of elements, wherein transistors are formed by way of the aforementioned silicide process.

Specifically, a first fuse array is produced using the same materials as the gate electrodes by way of the same silicide process. Similarly, a second fuse array and a third fuse array are each formed by way of the aforementioned process shown in FIG. 26 and are sequentially and vertically arrayed on the first fuse array. Of course, it is possible to form a prescribed number of fuse arrays, which can be freely determined.

### 3. Third Embodiment

The third embodiment is designed to avoid physical destruction of interlayer insulating films due to heat caused by applying pulses to fuses to break them down and to reduce thermal stress applied to interlayer insulating films (i.e., coating insulating films), whereby it is possible to suppress degasification in coating insulating films, and it is possible to prevent cracks from being formed in applied insulating films and to prevent coating insulating films from being deformed.

Before specifically describing the third embodiment, its operating principle will be briefly described in comparison with the operating principle of the second embodiment.

The second embodiment refers to the three methods (A), (B), and (C), whereas the third embodiment includes a supplemental explanation as follows:

As to the method (B), it can be said that the breakdown energy is divided so as to produce pulses each having very small energy, by which a fuse cannot break down within a limited time length. This may indicate a lower limit in the current A, which is denoted as Amin; hence, A′(1), A′(2), . . . , A′(n)>Amin, and A′(1)+A′(2)+ . . . +A(n)>n*Amin. This also indicates the relationships of E′(1)=E*A′(1)/A>E*Amin/A, E′(2)=E*A′(2)/A>E*Amin/A, . . . , and E′(n)=E*A′(n)/A>E*Amin/A.

In the method (C) in which the current is divided using m, it is required that the divided current be higher than the lower limit Amin.

In addition, the third embodiment also refers to the method (D) as follows:
(D) In the case of the combination of the methods (A) and (B) or the method (C) contributing to reduction of pulse widths, current, and voltage, the breakdown energy is not necessarily uniformly divided using n and m but can be divided in a series manner, wherein time intervals between pulses can be arbitrarily determined.

Incidentally, the fuse breakdown method applied to the third embodiment is identical to the fuse breakdown method applied to the second embodiment shown in FIGS. 16A and 16B; hence, a duplicate description is not given. In addition, the third embodiment also refers to Table 1, which is described before in conjunction with the first embodiment; hence, a duplicate description is not given.

With reference to FIG. 17 described before in conjunction with the second embodiment, as the fuse breakdown time is varied in a series manner, all fuses may not each break down with the voltage of 2.1 V and the current of 35 mA within the accumulated time of 2000 ms. This indicates that the fuse breakdown operation using pulses may not be completed within a finite limited time in prescribed conditions.

For this reason, it is necessary to introduce the aforementioned lower limit of current Amin, which may be set to 30 mA or so by way of the reliability assessment through the electrification testing performed on fuses composed of polysilicon, wherein resistors and wirings are also composed of polysilicon.

The third embodiment also refers to fuse breakdown circuits shown in FIGS. 18 and 22, which are described before in conjunction with the second embodiment; hence, a duplicate description is not given.

Next, a manufacturing method according to the third embodiment will be described in detail.

FIG. 28 is a plan view showing a CMOS integrated circuit, which includes an active region, a gate electrode G of a MOS transistor, a fuse F, contact holes, and wirings.

The manufacturing method of the third embodiment is basically similar to the manufacturing method of the second embodiment in conjunction with FIGS. 25A to 25D; hence, a duplicate description is not given. Of course, FIGS. 25A to 25D are cross-sectional views taken along line A-A in FIG. 28 in the third embodiment.

As to the illustration of FIG. 25B, the third embodiment differs from the second embodiment such that the deposition of the high-melting-point metal silicide layer is realized by use of the DC magnetron sputtering device under the following conditions.

Sputtering target: the composition factor x for WSix is set to 2.7.

Pressure: 8 mTorr.

Ar gas: 30 sccm.

Substrate temperature: 150° C.

Power: 2000 W.

It is possible to perform chemical mechanical polishing (CMP) as necessary in order to realize planation with respect to the surface of the interlayer insulating film. In this case, fuses formed on the planar surface of the interlayer insulating film are free from variations of breakdown characteristics, which may occur due to irregularities. In addition, the aforementioned planation is advantageous in terms of fine processing of contact holes, fuses, and wirings. Specifically, it may realize fine processing using thickness-reduced resists; it may increase margins for exposure; and it may reduce dispersions regarding etching.

It is preferable that the BPSG film subjected to CMP has a sufficiently large thickness in order to prevent the lower PSG film from being exposed to the surface. In addition, it is possible to prevent polycide, which may be formed on small projections of a LOCOS oxide film, from being exposed to the surface due to CMP; hence, it is possible to avoid short-circuiting between upper wiring layers and fuses; and it is possible to eliminate parasitic capacitance due to the small thickness of correlative films. Furthermore, it is possible to prevent the PSG film from being reduced in thickness irrespective of the differences between the polishing factors of the PSG and BPSG films in CMP and irrespective of the differences between the etching factors of the PSG and BPSG films in chemical cleaning for elimination of slurry after CMP.

It is necessary for CMP not to expose the BPSG film to the surface even when the thickness of the interlayer insulating film becomes substantially zero. For example, the polished thickness realized by CMP is set to 400 nm with respect to the PSG film of 100 nm thickness and the BPSG film of 900 nm thickness. Herein, the minimum thickness of the BPSG film depends upon the height differences of the wells and the projections of the LOCOS oxide film, wherein it preferably ranges from 100 nm to 200 nm.

Similar to the second embodiment, the adhesion layer is formed by sequentially depositing the Ti film and the TiN film. In the third embodiment, the Ti film is formed by way of sputtering in the following conditions.

Sputtering target: Ti.

Substrate temperature: 150° C.

Ar flow: 15 sccm.

Pressure: 4 mTorr.

Sputtering power: 1150 W.

As for the formation of the adhesion layer, it is possible to use other materials such as a high-melting-point metal alloy such as TiW, metal silicide such as TiSix, a combination of metal silicide and metal nitride such as TiNx (or nitrogen oxide), and a combination of a high-melting-point metal such as Ta/TaNx and nitride (or nitrogen oxide or boride).

It is possible to realize the deposition of the TiNx film or TiOxNy film by way of sputtering under the following conditions.

Sputtering target: Ti.

Substrate temperature: 150° C.

Ar/N₂ flow: 40/85 sccm.

Pressure: 4 mTorr.

Sputtering power: 1100 W.

It is possible to realize the deposition of the TiN film by way of collimate sputtering or long-slow sputtering, which allows the TiN (or TiON) film having a sufficiently large thickness to be formed in the bottoms of contact holes, thus realizing the formation of high-performance barrier films.

As for the formation of the TiON film, the aforementioned conditions are slightly changed to Ar/N₂/O₂ flow: 30/10/85 sccm. In addition, by changing the sputtering target from Ti to Ta, it is possible to form a high-melting-point metal film (composed of Ta) and its nitride film or nitrogen oxide film (e.g., TaNx, TaOxNy) in accordance with the aforementioned method.

As for materials of the conductive layer, it is possible to select metals having compounds of high evaporation pressure such as WF₆. For example, nucleation of tungsten (W) is realized under the following conditions.

Substrate temperature: 430° C.

Gas flow: WF₆/SiH₄ at 7-20/4 sccm.

Pressure: 4 Torr.

Time: 30-50 seconds.

In addition, the formation of a tungsten (W) layer is realized under the following conditions.

Substrate temperature: 450° C.

Gas flow: WF₆/H₂/Ar at 80/7/20 sccm.

Pressure: 50-80 Torr.

Formation speed: 0.3 μm to 0.5 μm per minute.

Subsequently, the conduction layer is subjected to anisotropic etching back, whereby it is left only on the contact holes. That is, dry etching is performed on the conduction layer under anisotropic etching conditions so as to expose the adhesion layer. Specifically, dry etching is performed using a magnetic microwave plasma etcher under the following conditions.

Gas flow: SF₆ at 140 sccm.

High-frequency bias power: 200 W.

Pressure: 270 Pa.

Substrate temperature: 30° C.

The completion of tungsten etching is detected by monitoring F⁺ light-emission intensity (at wavelength of 704 nm), wherein it is detected when F⁺ light-emission intensity becomes large (or a differentiation value thereof becomes large). The tungsten etching can be performed until the adhesion layer is moved from the interlayer insulating film, which is thus exposed to the surface.

The adhesion layer and wiring layer can be formed using other methods such as the damascene method and dual damascene method. In this case, the adhesion layer and contact plugs are formed by way of sputtering, the CVD method, or plating; then, unwanted portions of the adhesion layer and unwanted plug materials are removed by way of the CMP method; thus, it is possible to embed plugs into contact holes.

As for the materials of contact holes subjected to the damascene method, it is possible to use Al or an Al alloy such as Al—Si and Al—Si—Cu or to use Cu or a Cu alloy such as Cu—Cr, Cu—Zr, Cu—Ag, and Cu—Pd, instead of the high-melting-point metal such as W. It is possible to introduce pre-treatment prior to CMP as necessary, wherein the semiconductor substrate having the adhesion layer and contact plugs is subjected to heat treatment, reflow processing, and planation.

In the above, contact metals and barrier metals are formed in prescribed conditions similar to those for the formation of W plugs; thereafter, the aforementioned layers are formed by way of sputtering under the following conditions:

Sputtering target: Al—Si alloy.

Substrate temperature: 200° C.

Ar flow: 33 sccm.

Pressure: 2 mTorr.

Sputtering power: 900 W.

As described above, after completion of the formation of plug materials, the semiconductor substrate is subjected to heat treatment and reflow processing at a prescribed temperature ranging from 400° C. to 550° C. under vacuum conditions; thus, it is possible to complete embedding of contact holes.

As plug materials, it is possible to use Cu or a Cu alloy such as Cu—Cr, Cu—Zr, and Cu—Pd, wherein the sputtering target is changed to Cu or the Cu alloy. Of course, it is possible to perform plating on Cu or the Cu alloy.

Next, the formation and patterning of a second polysilicon layer and a second metal layer (composed of metal silicide) will be described in detail. The second polysilicon layer and second metal layer serving as fuses and wirings are formed and subjected to patterning on the aforementioned interlayer insulating film and contact plugs.

In the above, polysilicon deposition is realized by the aforementioned process shown in FIGS. 25B and 25C; hence, a duplicate description is not given.

At first, a description will be given with respect to the formation and structure of the second polysilicon layer and second metal layer (composed of metal silicide). Due to variations of fuses, it is possible to form either the second polysilicon layer or the second metal layer as the basis of fuses and wirings. When only the second polysilicon layer is formed, resistances of fuses and wirings may increase; however, it is possible to reduce the thickness of the second polysilicon layer. This is advantageous in that fuses can be formed in multiple layers.

When only the second metal layer is formed, it is possible to reduce the thickness of the second metal layer and to reduce resistances of fuses and wirings. Reducing resistances of fuses is advantageous in that driving abilities of transistors producing breakdown currents for fuses can be reduced; hence, it is possible to improve integration and to reduce electric power consumption.

In addition, the formation order can be changed; that is, it is possible to form the second polysilicon layer on the second metal layer. This reduces contact resistances with plugs embedded in lower contact holes; hence, it is possible to further reduce wiring resistances between the fuses and transistors.

It is possible to introduce a three-layered structure in which the second polysilicon layer is sandwiched between upper and lower metal layers (or metal silicide layers). In this case, the upper and lower metal layers are each reduced in thickness by a factor of ½ or so while the thickness of the second polysilicon layer is not changed. This is advantageous in that constant fuse resistances can be realized without increasing the overall thickness (or without forming unwanted step differences).

The above is advantageous because it is possible to reduce contact resistances with plugs embedded in lower contact holes; and it is possible to reduce contact resistances with plugs embedded in upper through holes.

Desired deposition thickness can be selected for each of the second polysilicon layer and the second metal layer (or second metal alloy layer or second high-melting-point metal silicide layer) in response to breakdown characteristics of fuses. For example, the thickness of the second polysilicon layer, which depends upon the relationships between the sheet resistances (i.e., resistances of fuses) and breakdown characteristics, ranges from 50 nm to 500 nm, preferably, from 100 nm to 300 nm.

The thickness of the second high-melting-point metal silicide layer (or the second metal layer or second metal alloy layer) ranges from 50 nm to 500 nm, preferably, from 100 nm to 300 nm. When it is permitted that fuse resistances be increased in light of driving abilities of transistors, it is preferable that the second high-melting-point metal silicide layer be reduced in thickness in comparison with the second polysilicon layer. This is because the second high-melting-point metal silicide layer has a very high melting point in comparison with the second polysilicon layer and is therefore very difficult to break down with thermal stress.

The second high-melting-point metal silicide layer is composed of prescribed materials such as high-melting point metal silicide (e.g., WSix, TiSix, TaSix, and MoSix) and transition metals (e.g., NiSix, CoSix, and CrSix) by way of sputtering or the CVD method.

In the above, sputtering is performed using a sputtering target of WSix (where the composition factor x is determined based on characteristics of metal silicide within a range of 1.5≦x≦3.5, preferably, 2.0≦x≦3.0. The following description is made by setting the composition factor x to 2.7 for WSi.

The aforementioned second high-melting-point metal silicide layer can be replaced with the second metal layer or the second metal alloy layer, wherein it is possible to use high-melting-point metals such as Mo, Ti, Ta, and W, transition metals such as Co, Cr, Hf, Ir, Nb, Pt, Z, and Ni, and alloys composed of the aforementioned metals. Incidentally, metal silicide can be formed upon reaction with the polysilicon layer by way of heat treatment, for example.

Heat treatment is performed after completion of the polysilicon formation. That is, heat treatment is performed before the formation of the interlayer insulating film and after the deposition of high-melting-point metal silicide, thus reducing resistances of fuses and polycide gate electrodes using high-melting-point metal silicide. The aforementioned heat treatment avoids the separation between metal silicide and polysilicon due to heat treatment applied to metal silicide, e.g., due to quenching heat treatment applied to the interlayer insulating film.

The aforementioned heat treatment can be performed using a diffusion furnace or by way of RTA. For example, RTA is performed for ten seconds at 950° C., 1000° C., 1050° C., 1100° C., and 1150° C. respectively so as to detect relationships between average initial resistances of fuses and breakdown characteristics (i.e., breakdown currents realizing complete breakdown of fuses). The results are shown in Table 2 showing relative assessment in which the average resistance and breakdown current measured at 950° C. are each represented as the reference value “100”.

TABLE 2

| | | | 1000 | 1050 | 1100 | 1150 |
|---|---|---|---|---|---|---|
| | 900° C. | 950° C. | ° C. | ° C. | ° C. | ° C. |
| Average | 112 | 100 | 90 | 80 | 64 | 62 |
| Resistance | | | | | | |
| Breakdown | 94 | 100 | 114 | 128 | 152 | 162 |
| Current | | | | | | |

The aforementioned results show that the average initial resistance of fuses using silicide thin films increase as the RTA temperature decreases. Through assessment regarding breakdown characteristics, which are measured by applying breakdown currents to fuses with MOS transistors driven at 5 V, small breakdown currents may realize fuse breakdown. Specifically, the average initial resistance of fuses linearly increases as the RTA temperature decreases from 1100° C. to 900° C. In contrast, the breakdown current decreases as the RTA temperature decreases from 1100° C. to 950° C., wherein the decreasing rate thereof becomes low in the range between 950° C. and 900° C., in which the breakdown current may slowly decrease as the RTA temperature decreases. It is estimated that the decreasing rate of the breakdown current becomes low at the RTA temperature of 900° C. or below.

Transistors may bear high loads as the average initial resistance of fuses increases; hence, they may not always be capable of producing breakdown currents required for causing fuse breakdown. In other words, it is beneficial that fuse resistances be reduced when MOS transistors having prescribed driving abilities (i.e., prescribed dimensions) are used for fuse breakdown circuits. This allows fuses to break down with relatively low breakdown currents produced by small-size transistors, which in turn improves integration and reduces the manufacturing cost.

Properties of transistors depend upon diffusion due to heat treatment; hence, it is preferable that heat treatment be performed at relatively low temperature. In particularly, heat treatment at 1000° C. or more may greatly change the impurities distribution in diffusion layers of transistors, which are formed before annealing of fuses; hence, it is difficult to maintain desired characteristics of transistors. Due to the aforementioned limitation derived from transistors, it is preferable that the RTA temperature be less than 950° C.

As described above, it is preferable that the RTA be performed at a prescribed temperature of 950° C. or less in light of the initial resistances of fuses, breakdown currents, and required conditions for transistors. In light of the effects of RTA applied to metal silicide, the temperature may preferably range from 600° C. to 950° C. In light of the effects of avoiding separation due to quenching heat treatment, the temperature may preferably range from 800° C. to 950° C. RTA is performed for 1 second to 120 seconds, preferably, for 5 seconds to 30 seconds. The following description is made by performing RTA for 10 seconds.

By using transition metals or their suicides, it is possible to further reduce the temperature. That is, it is preferable that RTA be performed for 1 second to 120 seconds, preferably, for 5 seconds to 30 seconds, at a prescribed temperature ranging from 400° C. to 800° C., preferably, from 450° C. to 600° C. When CoSi₂ is used, RTA can be performed for 10 seconds at 550° C.

Heat treatment can be performed using a diffusion furnace under conditions similar to those of RTA, wherein it is performed for 5 minutes to 90 minutes, preferably, for 15 minutes to 30 minutes, at a prescribed temperature ranging from 600° C. to 950° C., preferably, from 800° C. to 950° C. in light of anti-separation effects against quenching heat treatment. Using transition metals reduces the temperature; hence, heat treatment is performed for 5-30 minutes at 400-800° C., preferably, for 5-10 minutes at 450-600° C.

The aforementioned heat treatment can be performed after the patterning of gate electrodes, after the formation of oxide films for side wall spacers, or after the formation of side wall spacers.

Before or after the heat treatment, it is possible to form an anti-reflection film, which is necessary to process fuses having fine dimensions by way of patterning. Of course, it is not always necessary to form the anti-reflection film.

The anti-reflection film is formed by way of deposition of TiN or TiOxN (where the composition factor x for oxygen ranges from 5 atm % to 30 atm % with prescribed thickness ranging from 10 nm to 100 nm, preferably, from 30 nm to 60 nm. The deposition is realized by way of the reactive sputtering method using a sputtering gas (corresponding to a mixture of Ar, N₂, and O₂) by use of a DC magnetron sputtering device, for example.

Incidentally, after completion of the formation of a metal layer, it is possible to perform a silicide reaction by way of heat treatment applied to a TiO film or a TiON film.

The anti-reflection film decreases reflected light caused by silicide elements on the surfaces of fuses, whereby it is possible to perform photolithography realizing fine processing. The anti-reflection film can be removed by way of etching after the patterning of fuses. Upon the removal of the anti-reflection film, it is possible to stabilize the breakdown characteristics of fuses and to reduce breakdown currents as well.

Next, the formation of side wall spacers and a second interlayer insulating film will be described in detail.

First, insulating films serving as side wall spacers are formed to cover fuses; then, planar portions of the insulating films are removed by way of anisotropic etching; thus, it is possible to form side wall spacers having tapered shapes on the side walls of the fuses. The thickness of the side wall spacer determines the distance between a heating portion of a fuse and a SOG film, wherein the heat insulation effect becomes high as the thickness becomes large, which in turn increases the load in dry etching. For this reason, it is preferable that the thickness ranges from 150 nm to 700 nm, preferably, from 200 nm to 500 nm.

The insulating film realizing conformal coverage may be beneficial to increase the thickness of the side wall spacers, wherein an oxide film, a nitrogen film, or a nitrogen oxide film can be formed by way of a prescribed method adapted to LT-TEOS and PL-TEOS. In addition, it is possible to form a fluorine-contained insulating film (e.g., an oxide film and a nitrogen oxide film) and a bias CVD insulating film.

Various materials can be selected for the formation of side wall spacers. Prescribed materials, which are selected for the formation of side wall spacers and which differ from materials of insulating films formed on the surface of the interlayer insulating film, may improve the performability of etching.

For example, an LP-TEOS oxide film (where TEOS stands for tetra-ethyl-ortho-silicate, i.e., Si(OC₂H₅)₄) is formed under the following conditions.

Substrate temperature: 700° C.

Material gas: TEOS/O₂ at 60/0-5 sccm.

Reaction chamber pressure: 0.25 Torr.

Thickness: 350 nm.

A nitride film can be formed in a similar manner by use of material gas of SiH₂Ci₂/NH₃ (or NH₃+N₂) at 40/400 sccm.

A PL-TEOS film is formed in the following conditions.

Substrate temperature: 400° C.

Material gas: TEOS (supplied as liquid in 1.8 cc per minute) and O₂ (at 8000 sccm).

Reaction chamber pressure: 2.5 Torr.

Plasma power: 1000 W.

Thickness: 450 nm.

A nitrogen oxide film is formed in a similar manner by use of material gas of TEOS (supplied as liquid in 1.8 cc per minute) and O₂ or N₂ at (8000-x) sccm, where x ranges from 0 sccm to 5000 sccm.

The aforementioned insulating film is subjected to anisotropic etching so as to form side wall spacers on the side walls of the fuses by use of a parallel-plate-type plasma etcher under the following conditions.

Etching gas: CHF₃/O₂/He at 27/4/88 sccm.

Pressure: 2 Torr.

RF power: 450 W.

Etching is stopped upon completion of the formation of side wall spacers due to the oxide film, wherein substantially no oxide film remains on the planar surface.

No illustration is specifically provided, but it is preferable that the oxide film may partially remain on the planar surface irrespective of etching so as not to enlarge step differences due to over-etching of the insulating film.

The aforementioned nitride film is subjected to etching using a parallel-plate-type plasma etcher at a pressure of 0.1 Torr and RF power of 400 W. Herein, etching is stopped upon completion of the formation of side wall spacers, wherein the thickness of the planar portion becomes substantially zero. Alternatively, etching is stopped by partially leaving the insulating film on the planar surface.

Next, a first insulating layer (e.g., an oxide film, a nitrogen oxide film, or a fluorine-contained insulating film) is formed to cover the side wall spacers. The thickness of the first insulating film is improved in heat insulation by increasing the thickness thereof, which in turn defines the distance between a heating portion of a fuse and an SOG film. However, the first insulating film having a large thickness increases the load in processing and also increases the overall thickness of the interlayer insulating film, which in turn increases the depths of contact holes so as to increase the load in dry etching and to increase resistances of plugs. For this reason, it is preferable that the thickness ranges from 150 nm to 800 nm, preferably, from 250 nm to 500 nm.

Incidentally, the first insulating film can be realized by any one of the aforementioned LP-TEOS oxide film, nitride film, PL-TEOS oxide film, nitrogen oxide film, fluorine-contained insulating film, and bias CVD insulating film.

As the first insulating film, it is possible to form a silicon oxide film by way of the plasma CVD method under the following conditions:

Substrate temperature: 400° C.

Material gas: SiH₄/N₂O/N₂ at 240/5000/2800 sccm.

Reaction chamber pressure: 2.2 Torr.

Thickness: 300 nm.

Of course, it is possible to form the aforementioned LP-TOS oxide film, nitride film, PL-TEOS oxide film, and nitrogen oxide film.

In addition, it is possible to form a fluorine-contained oxide film in the following conditions.

Substrate temperature: 450° C.

Material gas: TEOS/O₂/C₂F₆ at 50/250/250 sccm.

Reaction chamber pressure: 3.0 Torr.

Plasma power: 600 W.

Next, another insulating film is applied to cover the aforementioned first insulating film. In order to improve heat insulation against heating of fuses to break down, it is preferable that the coating insulating film having a coverage structure be composed of inorganic SOG, organic SOG, HSQ, and RSQ. In particular, it is beneficial for the coating insulating film to include organic compounds because of low heat insulation, which in turn causes stress variations, degasification, and quality variations due to heating of fuses.

As the material for the coating insulating film, it is possible to use a HSQ resin, which is dissolved in MIBK and is then subjected to spin-coating so as to realize a prescribed coating thickness ranging from 300 nm to 700 nm, preferably, from 350 nm to 550 nm. The following description is made with respect to the thickness of 450 nm.

Then, the semiconductor substrate coated with the HQ resin is subjected to heat treatment in an inert gas at a relatively low temperature so as to remove solvent therefrom, so that the coated film is converted into a pre-ceramic silicon oxide film, wherein N₂ gas is used as the inert gas, and the heat treatment is performed for 1 minute to 60 minutes at a prescribed temperature ranging from 150° C. to 350° C. The heat treatment can be performed in a multi-step manner. For example, the semiconductor substrate is placed on a hot plate in a N₂ gas atmosphere and is then subjected to baking at 150° C. for one minute, at 200° C. for one minute, and at 300° C. for one minute.

Next, another heat treatment is performed for 5-120 minutes at a prescribed temperature ranging from 350° C. to 550° C. in the atmosphere using an inert gas (e.g., N₂), which can be replaced with oxide gas or a mixed gas of inert gas and oxide gas. For instance, the heat treatment is performed for 10 minutes at 400° C. in a N₂ gas atmosphere.

As the material of the coating insulating film, it is possible to use organic SOG, which is applied to the semiconductor substrate with a prescribed thickness of 300 nm, which is then subjected to baking using a hot plate in a N₂ gas atmosphere at 150° C. for one minute, at 200° C. for one minute, and at 250° C. for one minute, and which is then subjected to annealing for 30 minutes at 400° C. in a N₂ gas atmosphere. Alternatively, it is possible to use inorganic SOG, which is subjected to annealing in the same atmosphere in a similar manner.

The aforementioned coating insulating film is appropriately subjected to etching back, whereby substantially no coating insulating film remains on the fuses, or it slightly remains on the fuses so as not to degrade the reliability. Etching back is performed using a parallel-plate-type plasma etcher under the following conditions.

Dry etching gas: CHF₃ and CF₄ combined at 40 sccm, and He at 88 sccm.

Pressure: 2 Torr.

Power: 275 W.

Gas ratio for CHF₃/CH₄: 30-70%, preferably, 40-55%.

In the above, the dry etching is stopped in a prescribed etching time in which the coating insulating film is removed from the first insulating film only.

In addition, the same etching rate can be set to both of the first insulating film and coating insulating film. Alternatively, the etching rate can be set in such a way that etching back for the coating insulating film progresses slightly faster than etching of the first insulating film. Thus, it is possible to selectively remove the coating insulating film remaining on the first insulating film covering the fuses without degrading the planation of the surface of the coating insulating film.

Next, a second insulating film is formed on the coating insulating film coated onto the semiconductor substrate. Since the thickness of the second insulating film defines the distance between a heating portion of a fuse and an SOG film, it is preferable for the second insulating film to have a large thickness in light of heat insulation. However, if the second insulating film has a very large thickness, this may increase the load in formation thereof, the thickness of the interlayer insulating film, and the depths of the contact holes, which in turn increase etching load and plug resistances. For this reason, it is preferable that the thickness ranges form 150 nm to 800 nm, preferably, from 250 nm to 500 nm.

As the second insulating film, it is possible to selectively form any one of the aforementioned LP-TEOS oxide film, nitride film, PL-SiH₄ oxide film (or its nitrogen oxide film or its nitride film), PL-TEOS oxide film (or its nitrogen oxide film), and fluorine-containing insulating film.

As the second insulating film, it is possible to form an LP-TEOS insulating film of 500 nm thickness at a substrate temperature of 400° C. by use of TEOS at 2.5 slm, O₂ at 7.5 slm, O₃ at 85 g/Nm³, and N₂ at 18 slm.

In order to improve the planation by removing step differences remaining on the surface of the second insulating film, it is possible to perform CMP as necessary so as to realize the planar and smooth surface. In this case, it is preferable that the second insulating film may have a sufficiently large thickness in order not to expose the lower SOG film to the surface irrespective of CMP. This is because, although the SOG film is subjected to annealing and is thus converted into ceramic, it has relatively low chemical resistance, which in turn causes separation and formation of cracks due to contact with slurry used in CMP and local etching due to chemical cleaning for removing particles after CMP.

When CMP of 500 nm is performed on the second insulating film of 1000 nm thickness, substantially no second insulating film remains after CMP so that the SOG film is not exposed to the surface. Herein, the minimum thickness of the second insulating film depends upon shapes of step differences thereunder but may preferably range from 100 nm to 200 nm.

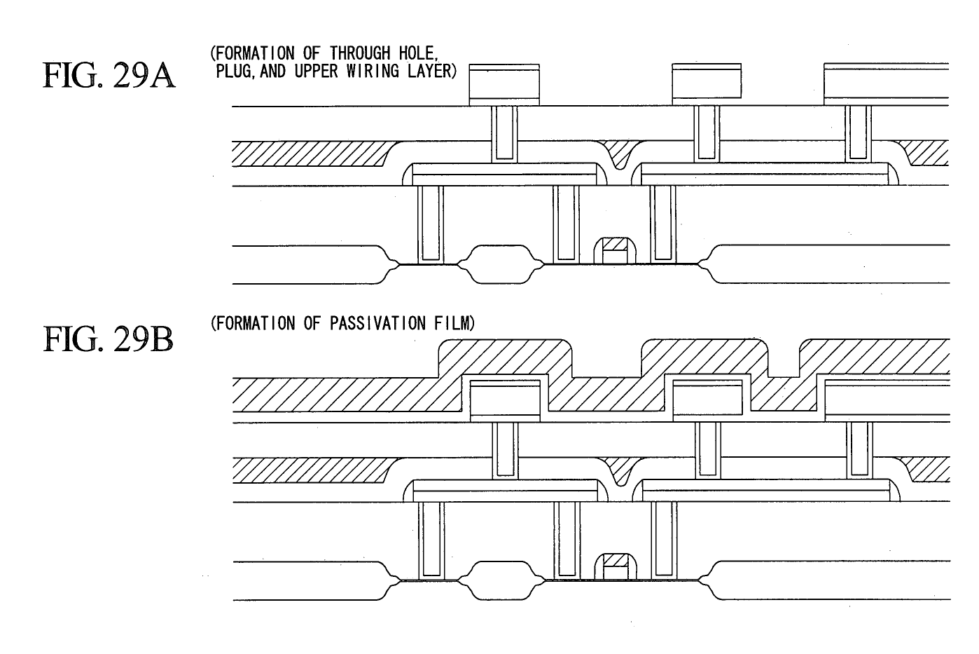

Next, the formation of through holes, embedded plugs, and wiring will be described with reference to FIG. 29A.

Specifically, through holes are formed in a second interlayer insulating film, W plugs are embedded therein, and a wiring film is formed and subjected to patterning. The wiring film is formed using conductive materials such as Al or an Al alloy (e.g., Al—Si, Al—Si—Cu), and Cu or a Cu alloy (e.g., Cu—Cr, Cu—Zr, Cu—Ag, and Cu—Pd) by way of sputtering. For example, sputtering is performed using a target of Al—Si—Cu under the following conditions.

Substrate temperature: 150° C.

Ar flow: 18 sccm.

Pressure: 8 mTorr.

Sputtering power: 1200 W.

It is possible to form a barrier film as necessary prior to the formation of the wiring film. The barrier film is composed of TiN or TiON, wherein it can be formed in a multi-layered structure composed of Ti/TiN(TiON) or Ti/TiN(TiON)/Ti. In addition, it is possible to form a cap film (or an anti-reflection film composed of Ti/TiN(TiON)) on the wiring film as necessary.

It is possible to accelerate planation of the wiring film by performing heat treatment and reflow processing under vacuum conditions. The wiring film is subjected to sputtering using a target of an Al—Si alloy under the following conditions.

Substrate temperature: 200° C.

Ar flow: 33 sccm.

Pressure: 2 mTorr.

Sputtering power: 900 W.

The wiring film, which forms material layers for plugs, is subjected to heat treatment and reflow processing at a prescribed temperature ranging from 400° C. to 550° C. under vacuum conditions.

Incidentally, it is possible to use the damascene method or the dual damascene method for the formation of the through holes, embedded plugs, and wiring film. Specifically, the aforementioned adhesion layer, contact plugs, and wiring are formed by way of sputtering, the CVD method, or plating; then, CMP is performed to remove unnecessary portions regarding the adhesion layer and plugs materials; thus, it is possible to form the plugs and wiring.

Next, the formation of a surface protection film and pads will be described with reference to FIG. 29B. That is, a passivation film is formed as the surface protection film so as to cover prescribed patterns formed on the surface of the semiconductor substrate; then, a Hall process is performed by way of photolithography and dry etching with respect to pads serving as external terminals and scribing lines for dividing chips.

By way of the CVD method, the passivation film whose thickness ranges from 0.8 μm to 1.4 μm and is preferably set to 1.1 μm is formed by sequentially depositing NSG or SiO₂ with the thickness ranging from 50 nm to 200 nm, preferably, with the thickness of 100 nm, and SiN or SiON with the thickness ranging from 600 nm to 1200 nm, preferably, with the thickness of 1000 nm. Thus, it is possible to finish producing an analog MOS integrated circuit whose cross-sectional structure is as shown in FIG. 29B.

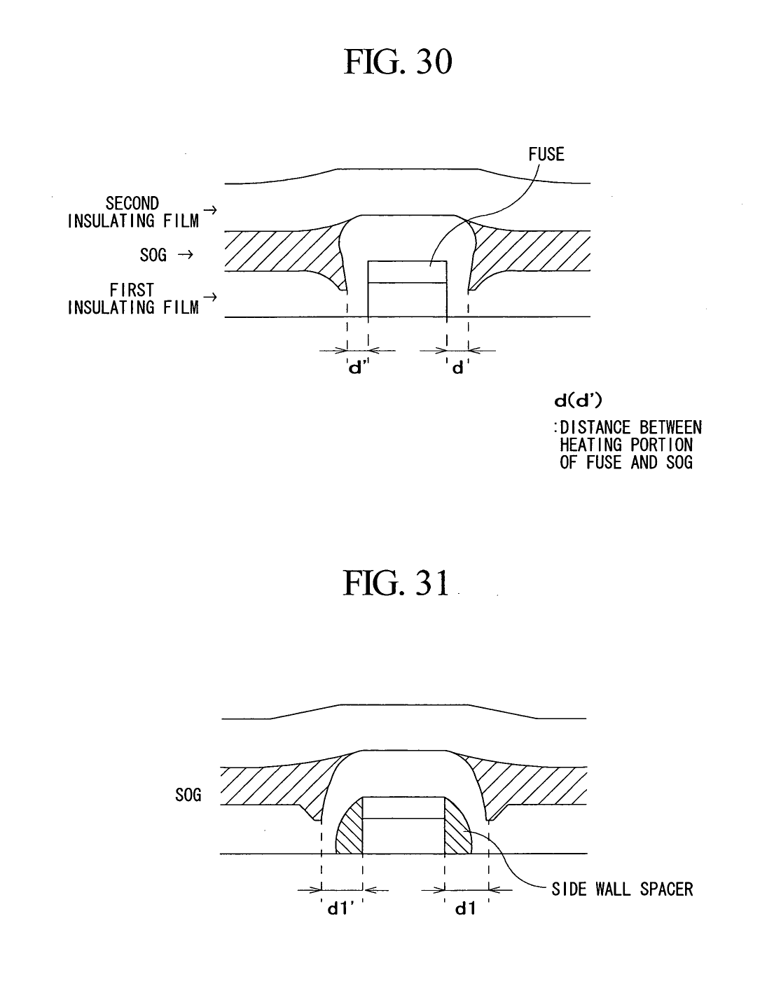

Next, various structures regarding side wall spacers formed in proximity to fuses will be described with reference to FIGS. 30-36, which show cross-sectional views taken along line B-B in FIG. 28.

FIG. 30 shows a basic structure in which a fuse is formed in connection with a three-layered structure consisting of a first insulating film, an SOG film, and a second insulating film. FIG. 31 shows a first example of a fuse structure in which side wall spacers are formed on the side walls of a fuse.

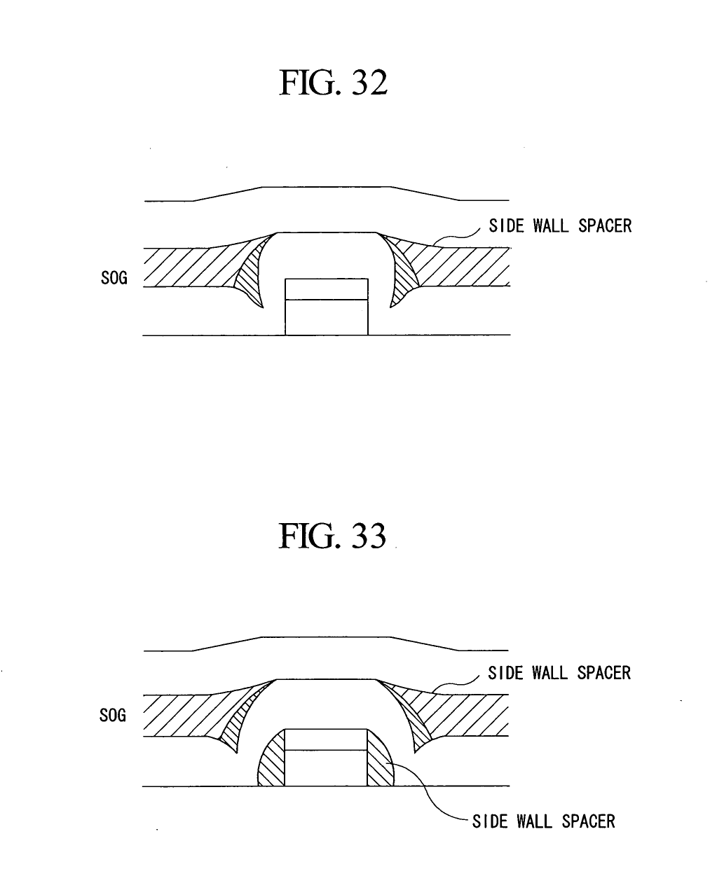

FIG. 32 shows a second example of a fuse structure in which side wall spacers are not immediately formed after the formation of a fuse but are formed after the formation of a first insulating film. This may effectively reduce dispersions of fuse characteristics because, due to reduced load in processing, the polycide surface would not be directly exposed to etching environments (e.g., plasma gas and ion impact) in the formation of side wall spacers. In addition, this is advantageous in that shapes of step differences in the first insulating film may be improved so as to realize planation of the SOG film with ease.

FIG. 33 shows a third example of a fuse structure in which side wall spacers are immediately formed after the formation of a fuse, then, other side wall spacers are formed after the formation of the first insulating film. This further increases the distance between the fuse and SOG film so as to further improve heat insulation against fuse breakdown; hence, it is possible to further reduce damage to the SOG film.

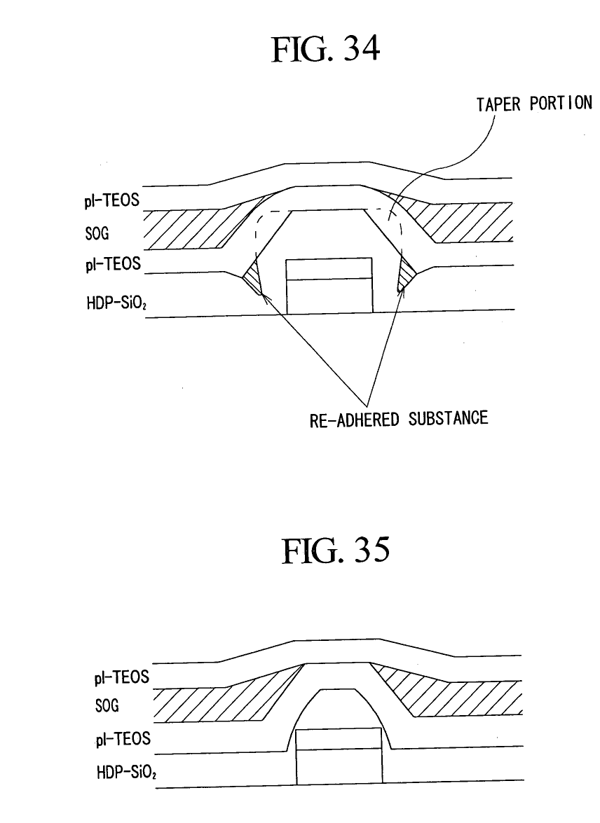

FIG. 34 shows a fourth example of a fuse structure in which tapered processing is performed with respect to the aforementioned fuse structure of FIG. 31 in which side wall spacers are formed after the formation of the first insulating film. This allows re-adhesion substances, which are produced by the tapered processing applied to insulating films, to be adhered to prescribed portions of the first insulating film whose coverage is reduced. Since the first insulating film is reduced in low coverage, it is possible not to substantially reduce the distance between the fuse and SOG film.

The aforementioned processing is realized by milling using an inert gas such as Ar gas or tapered etching using O₂ or Ar. The thickness of the first insulating film is carefully determined because the tapered etching is intensely performed on the prescribed portions of the first insulating film viewed from the upper end of the fuse with inclination angles of 45-60°. For example, it is preferable that the first insulating film be formed using a PL-TEOS oxide film whose thickness ranges from 300 nm to 1000 nm, preferably, from 500 nm to 800 nm.

In addition, Ar milling is performed under the following conditions.

Ar flow: 4 sccm.

Pressure: 2.0E-4 Torr.

Power: 500 V, 190 mA.

Chilled water temperature: 23° C. (where substrate temperature: 40-120° C.).

Milling angle: 45-80° (preferably, 60°).

Tapered angle: 60-45°.

Ar tapered etching is performed using an etching device of an anode-connection down-flow type under the following conditions.

Ar flow: 100 sccm.

Pressure: 0.1 Torr.

RF power: 800-1200 W.

Substrate temperature: 100° C.

Tapered angle: 60-45°.

O₂ tapered etching is performed using an ECR etching device under the following conditions.

O₂ flow: 100 sccm.

Pressure: 0.01 Torr.

Microwave power: 300 mV.

RF power: 150 W.

Substrate temperature: 40° C.

Tapered angle: 80-60°.

It is possible to apply SOG into the first insulating film having the aforementioned tapered shape. Alternatively, as shown in FIG. 34, it is possible to form a PL-TEOS oxide film whose thickness ranges from 100 nm to 500 nm, preferably, from 250 nm to 350 nm.

A fuse structure shown in FIG. 35 is characterized in that the first and second insulating films are formed twice above a fuse. That is, instead of performing the tapered processing on the first insulating film having relatively low coverage with respect to a fuse, it is possible to directly form an insulating film having a tapered shape by way of the formation of a bias CVD insulating film under the following conditions.

Substrate temperature: 400° C.

Material gas: SiH₄/O₂/Ar at 45/55/70 sccm.

Microwave power: 2000 W.

RF power: 1400 W at 13.56 MHz.

Reaction chamber pressure: 2 mTorr.

It is preferable that the thickness of the insulating film rages from 300 nm to 1000 nm, preferably, from 500 nm to 800 nm.

Thus, the first insulating film having the tapered shape is reduced in thickness in the prescribed portions thereof viewed with inclination angles of 45-60° from the upper end of a fuse. For this reason, another insulating film may be necessarily formed to cover the upper end of the fuse. It is preferable that the insulating film is formed by use of a PL-TEOS oxide film whose thickness ranges from 200 nm to 800 nm, preferably, from 350 nm to 600 nm.

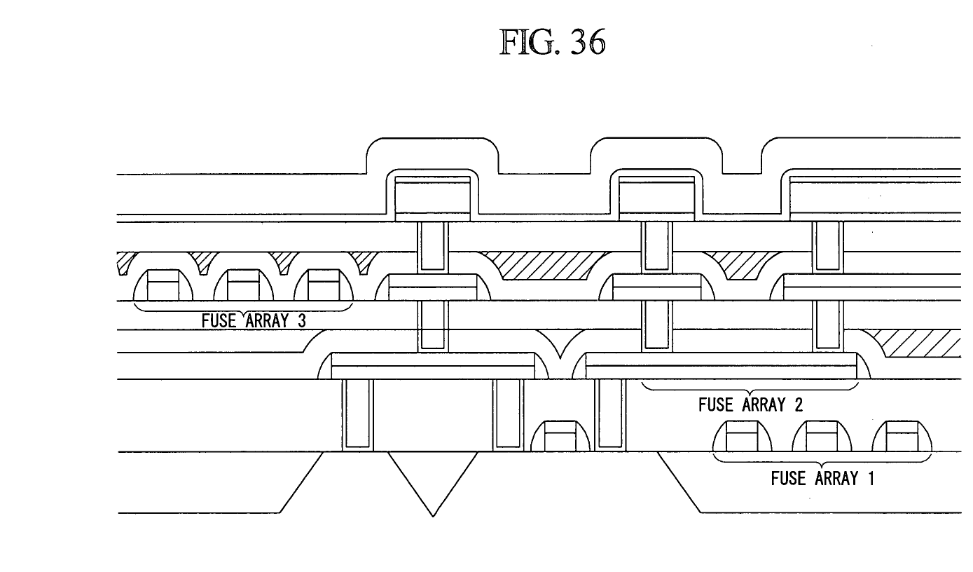

FIG. 36 shows a fuse structure in which fuses are formed using plural polysilicon layers or plural polycide layers. In the aforementioned examples (see FIG. 28, FIGS. 25A-25D, and FIGS. 29A-29B), at least one fuse is formed between the first and second interlayer insulating films, whereas the fuse structure of FIG. 36 is designed to form fuses among plural interlayer insulating films.

As described heretofore, the third embodiment improves the reliability of semiconductor integrated circuits because thermal stress is reduced with respect to the SOG film used as the interlayer insulating film, degasification of the coating insulating film is suppressed, and the coating insulating film is made free from the deformation and the formation of cracks. Hence, the aforementioned manufacturing process using polysilicon layers and polycide layers is repeatedly performed so as to produce plural fuse arrays including fuses in connection with plural layers.

The present embodiment is advantageous in that lower step differences are reduced so as to remarkably reduce step differences in laminated interlayer insulating films by way of the LOCOS method and the STI method, wherein transistors and diffusion layers are reduced in resistance and thickness by way of the aforementioned silicide process.

Specifically, a first fuse array formed on the STI structure is formed by way of the silicide process using the same materials and steps adapted to the formation of gate electrodes; and a second fuse array is formed above transistors; and a third fuse array is further formed thereabove.

The aforementioned laminated structure is preferably adapted to information readout circuits using plural fuses. It reduces the overall area of a silicon substrate having numerous fuses; it improves integration; and it reduces the manufacturing cost.

In addition, tapered shapes are applied to side walls of fuses or insulating films covering fuses; hence, it is possible to increase the distance between fuses and coating insulating films. As a result, it is possible to reduce thermal stress applied to coating insulating films; it is possible to suppress degasification from coating insulating films; it is possible to prevent coating insulating films from being unexpectedly deformed; it is possible to avoid the formation of cracks in coating insulating films; and thus, it is possible to improve the reliability of semiconductor integrated circuits. In addition, side wall spacers are formed on side walls of fuses; and side wall spacers can be further formed on insulating films covering fuses; thus, it is possible to further increase the distance between fuses and interlayer insulating films.

Ar etching or O₂ etching is performed on insulating films covering fuses so as to realize tapered shapes. Alternatively, milling is performed on insulating films covering fuses. Thus, it is possible to reduce thermal stress applied to coating insulating films by increasing the distance between fuses and coating insulating films.

When fuses break down with pulses applied thereto, the present embodiment further reduces physical and thermal damage applied to fuses. Specifically, heat treatment is performed on fuses at a prescribed temperature ranging from 400° C. to 900° C.; hence, it is possible to reduce thermal damage to transistors and to improve breakdown characteristics of fuses.

### 4. Fourth Embodiment

It is generally known that electro-migration occurs in constituent atoms or molecules when high current flows through a conductor. It takes a relatively long time to realize wiring breakdown by way of electro-migration; however, it is expected that electro-migration may be accelerated when high current flows through heated wiring, and thermal stress due to Joule heat may further accelerate electro-migration.

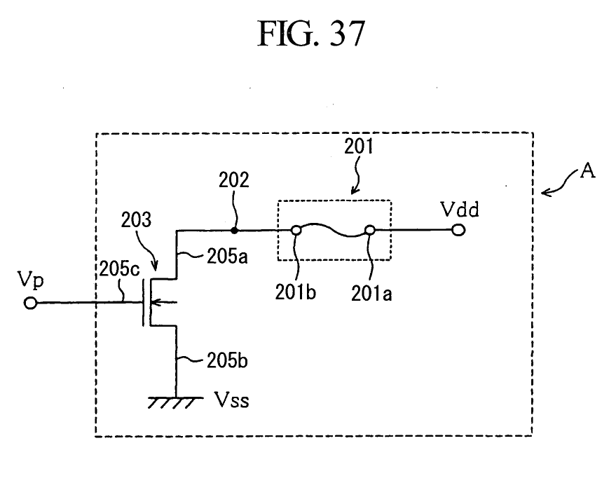

FIG. 37 shows an example of a fuse breakdown circuit in which a fuse 201 is connected in series to an n-channel MOS transistor (i.e., a MOSFET) 203. A terminal 201a of the fuse 201 is supplied with a drive voltage Vdd, and another terminal 201b is connected to a drain 205a of the transistor 203. A source 205b of the transistor 203 is grounded (at Vss). A pulse signal Vp is applied to a gate 205c of the transistor 203. When the gate 205c is high, the transistor 203 is turned on so as to make a current flow through the fuse 201. When a very high current flows through the fuse 201, the temperature of the fuse 201 increases due to Joule heat so that the fuse 201 breaks down due to meltdown and evaporation.

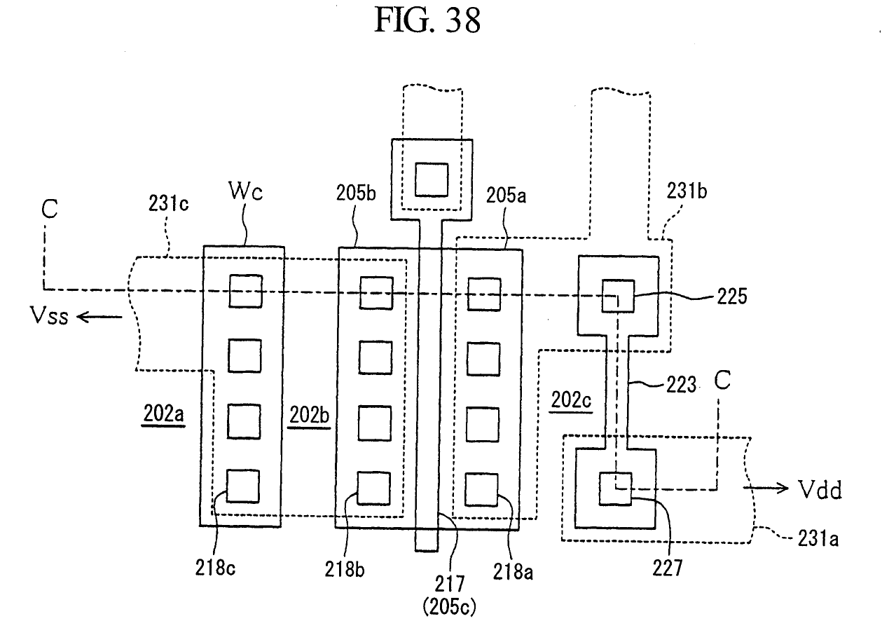

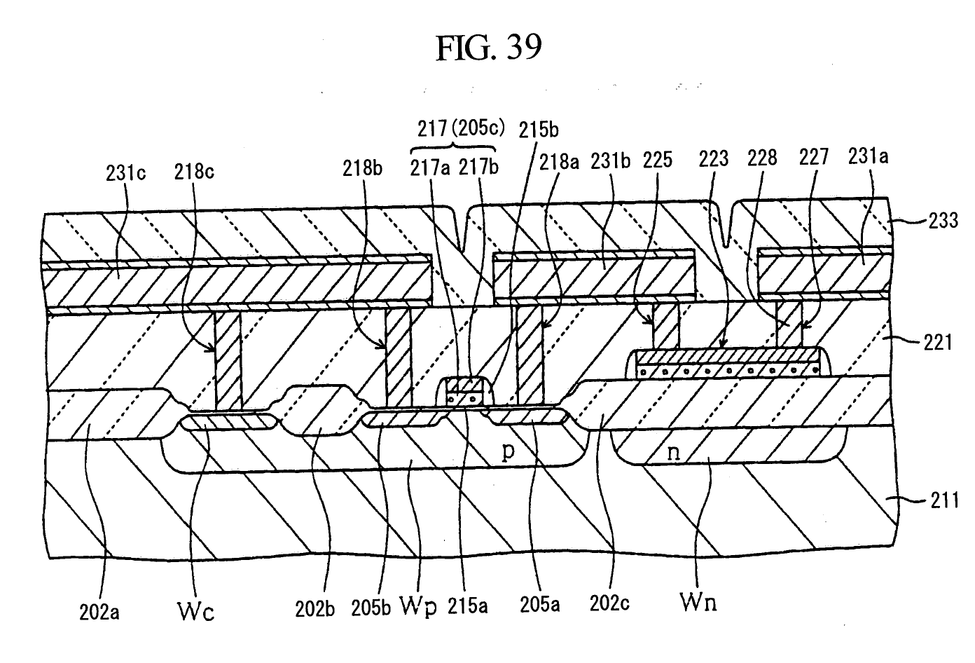

FIG. 38 is a plan view showing a semiconductor device including the fuse breakdown circuit of FIG. 37. FIG. 39 is a cross-sectional view taken along line C-C in FIG. 38.

As shown in FIGS. 38 and 39, separation regions 202a, 202b, and 202c are formed on a p-type semiconductor substrate 211 by way of the LOCOS (i.e., local oxidation of silicon) method, which can be replaced with the STI (i.e., shallow trench isolation) method. An active region used for the formation of a transistor is defined by the separation regions 202a, 202b, and 202c. A p-well Wp is formed in the active region in order to form an n-channel transistor. An n-well Wn is formed beneath the separation region 202c (i.e., a LOCOS oxide film) so as to avoid the occurrence of short-circuiting irrespective of cracks formed in the LOCOS oxide film 202c upon fuse breakdown. In addition, a p-well contact region Wc is formed in connection with a p-well Wp.

A gate insulating film 215a composed of silicon oxide is formed on the active region by way of the thermal oxidation method. A polycide gate electrode 217 consisting of a polysilicon layer 217a and a tungsten silicide layer 217b is formed on the gate insulating film 215a. Herein, n-type impurities whose density is about 10²⁰ cm⁻³ are doped into polysilicon. Incidentally, polycide may be substantially equivalent to salicide (or silicide); therefore, the gate electrode 217 can be formed using polysilicon only.

A polycide layer (or a polycrystal silicon layer) 223 used for the formation of a fuse 223 is formed on the separation region 202c simultaneously with the formation of the separation region 202c.

It is possible to form side wall spacers 215b (i.e., insulating films) on the side walls of the gate electrode 217 as well as on the side walls of the fuse 223. Before the formation of side wall spacers 215b, LDD (lightly doped drain) ion implantation is performed so as to form an LDD structure whose n-type impurities density ranges from 10¹⁷ cm⁻³ to 10¹⁸ cm⁻³.

After completion of the formation of side wall spacers 215b, high-density n-type impurities (whose density ranges from 10²⁰ cm⁻³ to 10²¹ cm⁻³) are introduced into both sides of the gate electrode 217 on the p-type semiconductor substrate 211. A source region 205a and a drain region 205b are formed in the p-well Wp on both sides of the gate electrode 217. In addition, impurities are introduced into the gate electrode 217 and the fuse 223 so as to reduce resistances thereof.

An interlayer insulating film 221 composed of silicon oxide, PSG, or BPSG is formed to cover the gate electrode 217 and the polycide layer 223 on the semiconductor substrate 211. Openings 218a, 218b, and 218c are formed in the interlayer insulating film 221 to reach the source region 205a, drain region 205b, and well contact region Wc with respect to the gate electrode 217. In addition, openings 225 and 227 are formed in the interlayer insulating film 221 to reach both ends on the upper surface of the polycide layer 223.

Adhesion layers composed of Ti, TiN, or TiON are formed and embedded in the openings 218a, 218b, 218c, 225, and 227 by way of sputtering; then, tungsten layers are deposited by way of the CVD method; thus, it is possible to form conductive plugs 228. Unnecessary portions of conduction layers are removed by way of CMP; thereafter, wirings realized by lamination of layers composed of TiN/Ti/Al/Ti (or TiN) are deposited on the interlayer insulating film 221 and are then subjected to patterning, thus forming wiring layers 231a, 231b, and 231c.

The wiring layer 231a is brought into contact with one terminal of the upper surface of a fuse 223 by way of the conductive plug 228. The wiring layer 231b connects the other terminal of the fuse 223 and the drain 205b of the transistor 203. The wiring layer 231c is brought into contact with the drain 205b of the transistor 203 and the well contact region Wc by way of the openings 218b and 218c respectively. Another wiring layer (not shown) is formed and brought into contact with the gate electrode 217. A passivation film 233 composed of silicon oxide or silicon nitride is formed to cover the wiring layers 231a-231c.

Thus, it is possible to produce the fuse breakdown circuit including the fuse 201 (corresponding to the fuse 223) and the transistor 203 (i.e., MOSFET).

Fuse breakdown characteristics and experimental results are already described in conjunction with FIG. 1, FIG. 2A (or FIG. 14), FIG. 3, FIG. 17, and Table 1; hence, a duplicate description is not given.

The fuse breakdown method applicable to the fourth embodiment is already described in conjunction with FIGS. 16A and 16B except for minor changes as follows:

In step S27, a decision is made as to whether or not the number of pulses (i.e., m) reaches “14”, or a decision is made as to whether or not the total time reaches 2000 ms. In step S28, a decision is made as to whether or not the resistance is equal to or higher than 1 MΩ. In step S30, a decision is made as to whether or not the fuse number (i.e., n) reaches the maximal fuse number (i.e., n_{MAX}).

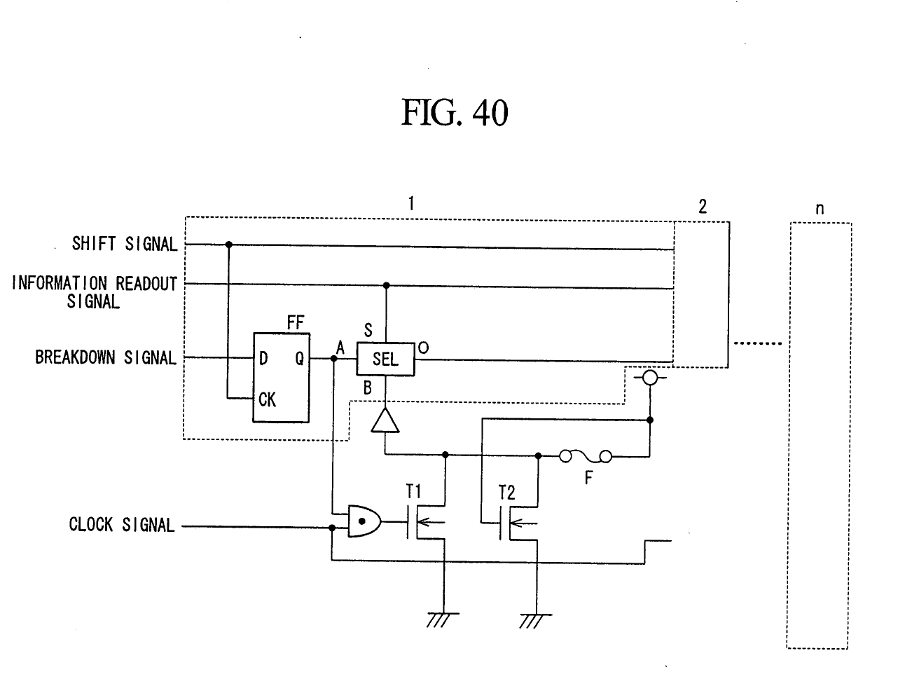

FIG. 40 shows a memory circuit including “n” stages, each of which includes a fuse F and a transistor T1 connected in series between a power line and a ground line. A transistor T2 is also connected in series to the fuse F so as to make a weak current flow through the fuse F.

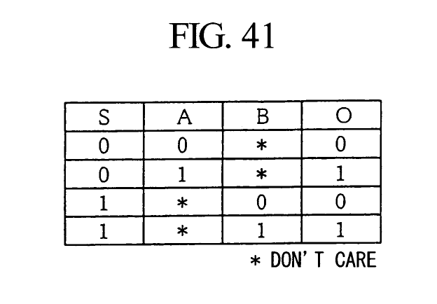

FIG. 41 shows a truth table showing the operation of a selector SEL, in which when input S is zero, input A appears at output O, and when input S is “1”, input B appears at output O. When an information readout signal is low and is applied to the input S of the selector SEL, the output of a flip-flop FF is transmitted to the next stage in response to a shift signal; hence, n stages cooperate together to realize an n-bit shift register. This allows information representing fuse resistance to be transmitted n times based on a breakdown signal in synchronization with the shift signal.

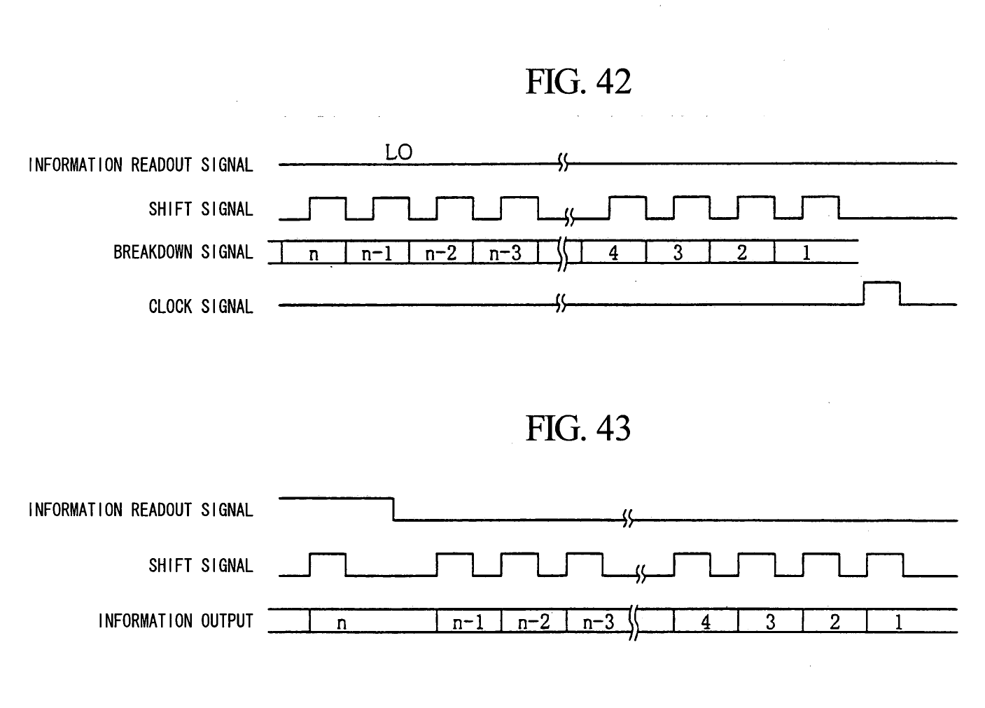

FIG. 42 shows time charts of signals with respect to a fuse breakdown operation. Herein, a shift signal includes “n” pulses so that information regarding fuse breakdown/non-breakdown stages appears at output Q of the flip-flop FF in each stage. Based on the information, it is possible to make each fuse break down by driving the transistor T1 with a clock signal having a pulse. By repeating the aforementioned operation “m” times, it is possible to realize fuse breakdown with m pulses. Pulse energy can be adjusted by appropriately selecting characteristics for the transistor T2. In addition, it is possible to control a pulse width relative to a time length of the clock signal.

FIG. 43 shows time charts for signals with respect to determination of fuse breakdown/non-breakdown states. Herein, an information readout signal is initially set in a high-level period, in which by applying a single pulse, information regarding fuse breakdown/non-breakdown states is shifted from one stage to another. Thereafter, the information readout signal is set in a low-level period, which in turn realizes a shift resistor connection using plural stages. Thus, information regarding fuse breakdown/non-breakdown states is sequentially output in synchronization with a clock signal having (n−1) pulses

Lastly, the present invention is not necessarily limited to the aforementioned embodiments, which are illustrative and not restrictive; hence, all changes and variations within the scope of the invention are intended to be embraced by the present invention.

What is claimed is:

1. A fuse breakdown method for consecutively applying a plurality of pulses to a fuse formed on a semiconductor substrate, thus making the fuse break down.

2. The fuse breakdown method according to claim 1, wherein a number of pulses applied to the fuse is determined in advance, and a pulse width is determined in advance.

3. The fuse breakdown method according to claim 1, wherein a number of pulses applied to the fuse is determined in advance, and energy per each pulse is determined in advance.

4. The fuse breakdown method according to claim 1 further comprising the steps of:
detecting whether or not the fuse breaks down with a previously applied pulse; and
stopping application of a next pulse to the fuse when fuse breakdown is detected.

5. A fuse breakdown assessment method comprising the steps of:
consecutively applying a plurality of pulses to a subject fuse until the subject fuse breaks down;
calculating total energy applied to the subject fuse until the subject fuse breaks down;
determining a breakdown threshold substantially identical to the total energy calculated with respect to the subject fuse; and
determining a number of pulses and a pulse width as well as either voltage or current adapted to each pulse in such a way that the total energy applied to the subject fuse to break down becomes equal to or higher than the breakdown threshold.

6. A semiconductor device comprising:
a first insulating layer formed on a semiconductor substrate;
a first fuse formed on the first insulating layer;
a second insulating layer that is formed to cover the first insulating layer and the first fuse; and
a second fuse formed on the second insulating layer.

7. The semiconductor device according to claim 6, wherein the first fuse and the second fuse partially overlap each other when the semiconductor substrate is viewed in a vertical direction.

8. The semiconductor device according to claim 6, wherein the first insulating layer defines at least one active region, so that the second fuse partially overlaps with the active region when the semiconductor substrate is viewed in a vertical direction.

9. A fuse formed on a semiconductor substrate, comprising:
a pair of terminals, which are formed apart from each other; and
an interconnection portion for interconnecting the terminals, wherein the interconnection portion is reduced in width compared with the terminals.

10. The fuse according to claim 9, wherein the interconnection portion is narrowly constricted with a triangular recess in the middle.

11. The fuse according to claim 9, wherein the interconnection portion has at least one bent portion.

12. The fuse according to claim 9, wherein the interconnection portion has a spiral shape.

13. A semiconductor device in which a plurality of fuses formed on a surface of a semiconductor substrate each break down with a prescribed number of pulses, which are generated by a pulse generator with a prescribed time interval therebetween.

14. The semiconductor device according to claim 13, wherein each of the pulses has relatively low energy lower than a minimum required energy of a single pulse reliably causing fuse breakdown.

15. The semiconductor device according to claim 13 further comprising:
a transistor for applying the pulses to the fuse; and
a breakdown detection circuit for detecting whether or not the fuse breaks down.

16. The semiconductor device according to claim 15, wherein the pulse generator stops applying pulses to the transistor when the breakdown detection circuit detects that the fuse completely breaks down.

17. A semiconductor device in which a plurality of fuses formed on a surface of a semiconductor substrate each break down with a prescribed number of pulses, wherein a memory is configured based on breakdown states and non-breakdown states of the fuses.

18. A semiconductor device comprising:
a semiconductor substrate;
at least one fuse formed on a surface of the semiconductor substrate; and
at least one transistor for consecutively applying a plurality of pulses to the fuse to break down.

19. The semiconductor device according to claim 18 including a plurality of fuses, which are arrayed in a prescribed layer formed on the semiconductor substrate.

20. The semiconductor device according to claim 18 including a plurality of fuses, which are respectively arrayed in different layers formed on the semiconductor substrate.

21. A fuse breakdown method adapted to a semiconductor device including at least one fuse and at least one transistor, comprising the steps of:
consecutively applying a plurality of pulses to the fuse with a prescribed time interval therebetween by way of the transistor; and
inhibiting the pulses from being applied to the fuse upon detection of fuse breakdown.

22. A semiconductor device comprising:
a semiconductor substrate; and
at least one fuse having tapered side walls formed on the semiconductor substrate.

23. A semiconductor device comprising:
a semiconductor substrate;
at least one fuse formed on the semiconductor substrate; and
at least one insulating film covering the fuse,
wherein the insulating film is subjected to anisotropic etching so that a planar portion thereof is removed so as to provide side wall spacers having tapered shapes on side walls of the fuse.

24. A semiconductor device comprising:
a semiconductor substrate;
at least one fuse formed on the semiconductor substrate; and
at least one insulating film covering the fuse,
wherein the insulating film is subjected to etching using Ar or O₂ gas so as to realize tapered shapes therein.

25. A semiconductor device comprising:
a semiconductor substrate;
at least one fuse formed on the semiconductor substrate; and
at least one insulating film covering the fuse,
wherein the insulating film is subjected to milling so as to realize tapered shapes therein.

26. A manufacturing method for a semiconductor device, comprising the steps of:
forming an insulating film covering a fuse formed on a semiconductor substrate; and
performing anisotropic etching so as to remove a planar portion of the insulating film, thus forming side wall spacers having tapered shapes on side walls of the fuse.

27. A fuse breakdown method in which a pulse whose energy is lower than a breakdown energy but is sufficient to cause solid phase migration is repeatedly applied to a fuse, composed of a conductive material, which is thus increased in resistance.

28. A fuse breakdown method according to claim 27, wherein a time interval between pulses is determined so as not to cause meltdown of the fuse.
